(19) United States
(12) Patent Application Publication
(10) Pub. No.: US 2025/0368565 A1
(43) Pub. Date: Dec. 4, 2025

(54) FOLDABLE SUBSTRATES AND METHODS OF MAKING

(71) Applicant: CORNING INCORPORATED, CORNING, NY (US)

(72) Inventors: CHUANCHE WANG, HORSEHEADS, NY (US); TINGGE XU, SAN JOSE, CA (US)

(21) Appl. No.: 18/874,858

(22) PCT Filed: Jun. 12, 2023
(86) PCT No.: PCT/US2023/025015

§ 371 Date: Dec. 13, 2024

Related U.S. Application Data
(60) Provisional application No. 63/353,993, filed on Jun. 21, 2022.
(60) Provisional application No. 63/436,948, filed on Jan. 4, 2023.

(51) Int. Cl. C03C 15/00; C03C 21/00; H04M 1/02; H10K 59/80

(52) U.S. Cl. CPC C03C 15/00; C03C 21/002; H04M 1/0203; H10K 59/873

(57) ABSTRACT

Foldable substrates comprise a first portion, a second portion, and a central portion positioned therebetween. The first portion comprises a substrate thickness and a first depth of compression. The central portion comprises a central thickness and a first central depth of compression. In aspects, a ratio of the first depth of compression to the substrate thickness is greater than a ratio of the first central depth of compression to the central thickness. In aspects, a ratio of a first depth of layer associated with the first depth of compression to the substrate thickness is greater than a ratio of a first central depth of layer associated with the first central compressive stress region to the central thickness. Methods comprise chemically strengthening a foldable substrate, etching a portion of the first major surface to form a first central surface area, and further chemically strengthening the foldable substrate.

### CROSS-REFERENCE TO RELATED APPLICATIONS

This application claims the benefit of priority under 35 U.S.C. § 119 of U.S. Provisional Application Ser. No. 63/436,948 filed on Jan. 4, 2023 and U.S. Provisional Application Ser. No. 63/353,993 filed on Jun. 21, 2022, the contents of each of which are relied upon and incorporated herein by reference in their entireties.

### FIELD

The present disclosure relates generally to foldable substrates and methods of making and, more particularly, to foldable substrates comprising a first central surface area recessed from a first major surface and methods of making foldable substrates comprising etching.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus that have low minimum bend radii and good impact and puncture resistance.

### SUMMARY

There are set forth herein foldable apparatus comprising foldable substrates, foldable substrates, and methods of making foldable apparatus and foldable substrates comprising foldable substrates that comprise a first portion, a second portion, and central portion positioned therebetween. The substrate and/or the portions can comprise glass-based and/or ceramic-based portions, which can provide good dimensional stability, reduced incidence of mechanical instabilities, good impact resistance, and/or good puncture resistance. The portions can comprise glass-based and/or ceramic-based portions comprising one or more compressive stress regions, which can further provide increased impact resistance and/or increased puncture resistance. By providing a substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 50 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters or less) based on the reduced thickness in the central portion, which can enable the foldability and/or rollability of the foldable substrate and/or foldable apparatus.

In aspects, the foldable apparatus and/or foldable substrates can comprise one or more recesses, for example, a first central surface area recessed from a first major surface by a first distance and/or a second central surface area recessed from a second major surface by a second distance. Providing a first recess opposite a second recess can provide the central thickness that is less than a substrate thickness. Further, providing a first recess opposite a second recess can reduce a maximum bend-induced strain of the foldable apparatus, for example, between a central portion and a first portion and/or second portion since the central portion comprising the central thickness can be closer to a neutral axis of the foldable apparatus and/or foldable substrates than if only a single recess was provided. Additionally, providing the first distance substantially equal to the second distance can reduce the incidence of mechanical instabilities in the central portion, for example, because the foldable substrate is symmetric about a plane comprising a midpoint in the substrate thickness and the central thickness. Moreover, providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials can be positioned in the first recess, which can improve impact resistance, puncture resistance, abrasion resistance, and/or scratch resistance of the foldable apparatus. Additionally, controlling properties of a first material positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure.

In aspects, the foldable apparatus and/or foldable substrates can comprise a first transition region attaching the central portion to the first portion and/or a second transition region attaching the central portion to the second portion. Providing transition regions with smoothly and/or monotonically decreasing (e.g., continuously decreasing) thicknesses can reduce stress concentration in the transition regions and/or avoid optical distortions. Providing a sufficient length of the transition region(s) (e.g., about 0.15 mm or more or about 0.3 mm or more) can avoid optical distortions that may otherwise exist from a sharp change in thickness of the foldable substrate. Providing an average transition angle of a first transition surface area of the first transition region relative to the first central surface area that is sufficiently large (e.g., about 1670 or more or about 170° or more) can avoid optical distortions and/or reduce visibility of the transition region. Providing a sufficiently small average transition angle (e.g., about 179° or less or about 176° or less) can reduce the amount of the foldable apparatus and/or the foldable substrates having an intermediate thickness that may have reduced impact resistance and/or reduced puncture resistance.

As discussed below, it was unexpectedly discovered that providing a ratio of the first depth of compression to the substrate thickness greater than a ratio of the first central depth of compression to the central thickness (even when differing by more than 0.01) can reduce an incidence of buckling whereas the same is not true for the opposite relationship (i.e., the relationship in which the ratio of the first central depth of compression to the central thickness is larger than the ratio of the first depth of compression to the substrate thickness). Unexpectedly, as described below, it has been determined that providing a ratio of the first depth of layer to the substrate thickness greater than a ratio of the first central depth of layer to the central thickness (even when differing by more than 0.001) can reduce an incidence of buckling whereas the same is not true for the opposite relationship (i.e., the relationship in which the ratio of the first central depth of layer to the central thickness is larger than the ratio of the first depth of layer to the substrate thickness). These configurations can exert a stabilizing force on the central portion that suppresses fluctuations in a surface profile that could otherwise lead to the onset of mechanical instabilities (e.g., buckling), which can enable the central portion to withstand a critical buckling strain, where the critical buckling strain is calculated for samples comprising the material of the substrate with a uniform thickness. This is unexpected since, by definition, exceeding the critical buckling strain would be expected to lead to the onset of mechanical instabilities (e.g., buckling). Further, providing the configurations can increase a manufacturing yield since a larger portion of the foldable substrates will be free of mechanical instabilities (e.g., buckling) (e.g., compared to where a ratio of the first depth of compression or the first depth of layer to the substrate thickness is less than or equal to a ratio of the first central depth of compression or the first central depth of layer to the central thickness).

The foldable substrate can function as a rollable substrate with a central width greater than a second width. Providing a second width of the second portion of about 15 mm or less (e.g., from about 2 mm to about 6 mm) and/or about 15% or less (e.g., from about 2% to about 6%) of the length of the foldable substrate can provide sufficient width to handling the ends of the foldable substrate during processing, to secure the foldable substrate and/or foldable apparatus as part of an electronic device, and/or to maximize an amount of the foldable substrate and/or foldable apparatus that can be part of a display portion visible to the user. Providing a central portion from about 15% to about 50% (e.g., from about 40% to about 48%) of the length of the foldable substrate can enable a display portion of the foldable apparatus to be adjust as a portion of the rollable substrate is moved into and/or out of view of a user without unnecessarily expanding a size of the corresponding apparatus when in a fully rolled configuration. Providing a first width of the first portion of about 35% or more (e.g., from about 40% to about 70%) of the length of the foldable substrate can provide a large display portion visible to the user while ensuring that substantially all of the rest of the foldable substrate (e.g., central portion and second portion) can be within a footprint of the first portion.

Methods of the aspects of the disclosure can make foldable substrates and/or foldable apparatus comprising a central thickness less than a substrate thickness (e.g., by about 10 μm or more) using an etch mask and an etchant. In aspects, using a barrier layer when initially chemically strengthening the foldable substrate before etching the foldable substrate to form the first recess can enable a ratio of the first depth of compression or the first depth of layer to the substrate thickness greater than a ratio of the first central depth of compression or the first depth of layer to the central thickness. In aspects, initially chemically strengthening the foldable substrate before etching the foldable substrate to form the first recess and the second recess can enable a ratio of the first depth of compression or the first depth of layer to the substrate thickness greater than a ratio of the first central depth of compression or the first depth of layer to the central thickness. In aspects, the design of an etch mask can tune a first transition width and/or a second transition width. Placing the etch masking in the vacuum can dissipate air bubbles between the barrier layers and the foldable substrate and/or increase an adhesion between the barrier layers and the foldable substrate to increase, which can increase a uniformity of the resulting foldable substrate.

Some example aspects of the disclosure are described below with the understanding that any of the features of the various aspects may be used alone or in combination with one another.

Aspect 1. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein the foldable substrate comprises a glass-based material or a ceramic based material, the first central surface area is recessed from the first major surface by a first distance, and a ratio of the first depth of compression to the substrate thickness is greater than a ratio of the first central depth of compression to the central thickness.

Aspect 2. The foldable substrate of aspect 1, the ratio of the first depth of compression to the substrate thickness is greater than the ratio of the first central depth of compression to the central thickness by from about 0.01 to about 0.2.

Aspect 3. The foldable substrate of any one of aspects 1-2, wherein the ratio of the first depth of compression to the substrate thickness is greater than the ratio of the first central depth of compression to the central thickness by from about 0.015 to about 0.15.

Aspect 4. The foldable substrate of any one of aspects 1-3, wherein the ratio of the first depth of compression to the substrate thickness is greater than the ratio of the first central depth of compression to the central thickness by from about 0.02 to about 0.12.

Aspect 5. The foldable substrate of any one of aspects 1-4, wherein a ratio of the second depth of compression to the substrate thickness is greater than a ratio of the second central depth of compression to the central thickness by from about 0.01 to about 0.2.

Aspect 6. The foldable substrate of aspect 5, wherein the ratio of the second depth of compression to the substrate thickness is greater than the ratio of the second central depth of compression to the central thickness by from about 0.015 to about 0.15.

Aspect 7. The foldable substrate of any one of aspects 5-6, wherein the ratio of the second depth of compression to the substrate thickness is greater than the ratio of the second central depth of compression by from about 0.02 to about 0.12.

Aspect 8. The foldable substrate of any one of aspects 1-7, wherein the first depth of compression is substantially equal to the third depth of compression.

Aspect 9. The foldable substrate of any one of aspects 1-8, wherein the second depth of compression is substantially equal to the fourth depth of compression.

Aspect 10. The foldable substrate of any one of aspects 1-9, wherein the first central depth of compression is substantially equal to the second central depth of compression.

Aspect 11. The foldable substrate of any one of aspects 1-10, wherein:
the first portion further comprises: a first depth of layer of one or more alkali metal ions associated with the first depth of compression, and a second depth of layer of one or more alkali metal ions associated with the second depth of compression;
the second portion further comprises: a third depth of layer of one or more alkali metal ions associated with the third depth of compression, and a fourth depth of layer of one or more alkali metal ions associated with the fourth depth of compression,
the central portion further comprises: a first central depth of layer of one or more alkali metal ions associated with the first central depth of compression, a second central depth of layer of the one or more alkali metal ions associated with the second central depth of compression, and
a ratio of the first depth of layer to the substrate thickness is greater than a ratio of the first central depth of layer to the central thickness.

Aspect 12. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface, a first depth of layer of one or more alkali metal ions associated with the first depth of compression, and a second depth of layer of one or more alkali metal ions associated with the second depth of compression;
a second portion comprising the substrate thickness, a third compressive stress region extending to a third depth of compression from the first major surface, a fourth compressive stress region extending to a fourth depth of compression from the second major surface, a third depth of layer of one or more alkali metal ions associated with the third depth of compression, and a fourth depth of layer of one or more alkali metal ions associated with the fourth depth of compression; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, a first central depth of layer of one or more alkali metal ions associated with the first central depth of compression, a second central depth of layer of the one or more alkali metal ions associated with the second central depth of compression, and the central thickness is less than the substrate thickness,
wherein the foldable substrate comprises a glass-based material or a ceramic based material, the first central surface area is recessed from the first major surface by a first distance, the foldable substrate comprises a ratio of the first depth of compression to the substrate thickness, and a ratio of the first depth of layer to the substrate thickness is greater than a ratio of the first central depth of layer to the central thickness.

Aspect 13. The foldable substrate of any one of aspects 11-12, the ratio of the first depth of layer to the substrate thickness is greater than the ratio of the first central depth of layer to the central thickness by from about 0.001 to about 0.2.

Aspect 14. The foldable substrate of any one of aspects 11-13, wherein the ratio of the first depth of layer to the substrate thickness is greater than the ratio of the first central depth of layer to the central thickness by from about 0.01 to about 0.15.

Aspect 15. The foldable substrate of any one of aspects 11-14, wherein the ratio of the first depth of layer to the substrate thickness is greater than the ratio of the first central depth of layer to the central thickness by from about 0.02 to about 0.12.

Aspect 16. The foldable substrate of any one of aspects 11-15, wherein a ratio of the second depth of layer to the substrate thickness is greater than a ratio of the second central depth of layer to the central thickness by from about 0.001 to about 0.2.

Aspect 17. The foldable substrate of aspect 16, wherein the ratio of the second depth of layer to the substrate thickness is greater than the ratio of the second central depth of layer to the central thickness by from about 0.01 to about 0.15.

Aspect 18. The foldable substrate of any one of aspects 16-17, wherein the ratio of the second depth of layer to the substrate thickness is greater than the ratio of the second central depth of layer by from about 0.02 to about 0.12.

Aspect 19. The foldable substrate of any one of aspects 11-18, wherein the first depth of layer is substantially equal to the third depth of layer.

Aspect 20. The foldable substrate of any one of aspects 11-19, wherein the second depth of layer is substantially equal to the fourth depth of layer.

Aspect 21. The foldable substrate of any one of aspects 11-20, wherein the first central depth of layer is substantially equal to the second central depth of layer.

Aspect 22. The foldable substrate of any one of aspects 11-21, wherein the ratio of the first depth of layer to the substrate thickness is in a range from about 0.10 to about 0.22.

Aspect 23. The foldable substrate of aspect 22, wherein the ratio of the first depth of layer to the substrate thickness is in a range from about 0.12 to about 0.17.

Aspect 24. The foldable substrate of any one of aspects 11-23, wherein the one or more alkali metal ions comprise potassium ions.

Aspect 25. The foldable substrate of any one of aspects 1-24, wherein the ratio of the first depth of compression to the substrate thickness is in a range from about 0.10 to about 0.22.

Aspect 26. The foldable substrate of any one of aspects 1-25, wherein the ratio of the first depth of compression to the substrate thickness is in a range from about 0.12 to about 0.17.

Aspect 27. The foldable substrate of any one of aspects 1-26, wherein a width of the second portion is about 15 millimeters or less, a width of the first portion is greater than a width of the central portion, a width of the central portion is greater than the width of the second portion, and a sum of the width of the first portion, the width of the central portion, and the width of the second portion corresponds to a dimension of the foldable substrate.

Aspect 28. The foldable substrate of aspect 27, wherein the width of the second portion is from about 2 millimeters to about 6 millimeters.

Aspect 29. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein the foldable substrate comprises a glass-based material or a ceramic based material, the first central surface area is recessed from the first major surface by a first distance, and a width of the first portion, a width of the central portion, and a width of the second portion are measured in a direction corresponding to a dimension of the foldable substrate, the width of the second portion as a percentage of the dimension of the foldable substrate is less than 15%, and the width of the first portion as a percentage of the dimension of the foldable substrate is about 35% or more.

Aspect 30. The foldable substrate of any one of aspects 1-28, wherein a width of the first portion, a width of the central portion, and a width of the second portion are measured in a direction corresponding to a dimension of the foldable substrate, the width of the second portion as a percentage of the dimension of the foldable substrate is less than 15%, and the width of the first portion as a percentage of the dimension of the foldable substrate is about 35% or more.

Aspect 31. The foldable substrate of any one of aspects 29-30, wherein the width of the second portion as a percentage of the dimension of the foldable substrate is from about 2% to about 6%.

Aspect 32. The foldable substrate of any one of aspects 29-31, wherein the width of the first portion as a percentage of the foldable substrate is from about 40% to about 70%.

Aspect 33. The foldable substrate of any one of aspects 29-32, wherein the width of the central portion as a percentage of the foldable substrate is from about 15% to about 50%.

Aspect 34. The foldable substrate of aspect 33, wherein the width of the central portion as a percentage of the foldable substrate is from about 40% to about 48%.

Aspect 35. The foldable substrate of any one of aspects 1-34, wherein a deflectometer profile of the first central surface area taken along a centerline of the central portion equally spaced from the first portion and the second portion comprises a substantially parabolic shape.

Aspect 36. The foldable substrate of any one of aspects 1-35, wherein the second central surface area is recessed from the second major surface by a second distance.

Aspect 37. The foldable substrate of aspect 36, wherein the second distance is from about 5% to about 20% of the substrate thickness.

Aspect 38. The foldable substrate of any one of aspects 36-37, wherein the first distance is substantially equal to the second distance.

Aspect 39. The foldable substrate of any one of aspects 1-38, wherein the second major surface comprises the second central surface area.

Aspect 40. The foldable substrate of any one of aspects 1-39, wherein the first distance is about 20% to about 45% of the substrate thickness.

Aspect 41. The foldable substrate of any one of aspects 1-40, wherein the central portion further comprises:
a first transition portion comprising a first transition surface area and a second transition surface area opposite the first transition surface area, the first transition surface area attaching the first central surface area to the first portion, a thickness of the first transition portion smoothly and monotonically decreases between the substrate thickness of the first portion and the central thickness of the central portion; and
a second transition portion comprising a third transition surface area and a fourth transition surface area opposite the third transition surface area, the third transition surface area attaching the first central surface area to the second portion, a thickness of the second transition portion smoothly and monotonically decreases between the substrate thickness of the second portion and the central thickness of the central portion.

Aspect 42. The foldable substrate of aspect 41, wherein the first transition surface area extends at a first average angle relative to the first central surface area from about 167° to about 179°.

Aspect 43. The foldable substrate of aspect 42, wherein the first average angle is in a range from about 170° to about 176°.

Aspect 44. The foldable substrate of any one of aspects 41-43, wherein a first transition width of the first transition region is in a range from about 150 micrometers to about 700 micrometers.

Aspect 45. The foldable substrate of aspect 44, wherein the first transition width is in a range from about 200 micrometers to about 500 micrometers.

Aspect 46. The foldable substrate of any one of aspects 1-45, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, the fourth compressive stress region comprises a fourth maximum compressive stress, the first central compressive stress region comprises a first central maximum compressive stress of about 400 MegaPascals or more, and the second central compressive stress region comprises a second central maximum compressive stress.

Aspect 47. The foldable substrate of aspect 46, wherein the second maximum compressive stress is about 400 MegaPascals or more, the fourth maximum compressive stress is about 400 MegaPascals or more, and the second central maximum compressive stress is about 400 MegaPascals or more.

Aspect 48. The foldable substrate of any one of aspects 1-47, wherein the substrate thickness is in a range from about 50 micrometers to about 2 millimeters.

Aspect 49. The foldable substrate of any one of aspects 1-48, wherein the substrate thickness is in a range from about 100 micrometers to about 200 micrometers.

Aspect 50. The foldable substrate of any one of aspects 1-49, wherein the central thickness in a range from about 25 micrometers to about 120 micrometers,

Aspect 51. The foldable substrate of any one of aspects 1-50, wherein the central thickness is in a range from about 25 micrometers to about 60 micrometers.

Aspect 52. The foldable substrate of any one of aspects 1-51, wherein the foldable substrate comprises a glass-based substrate.

Aspect 53. The foldable substrate of any one of aspects 1-51, wherein the foldable substrate comprises a ceramic-based substrate.

Aspect 54. The foldable substrate of any one of aspects 1-53, wherein the foldable substrate achieves a parallel plate distance from 1 millimeter to 10 millimeters.

Aspect 55. The foldable substrate of any one of aspects 1-54, wherein the foldable substrate achieves a parallel plate distance of 5 millimeters.

Aspect 56. A consumer electronic product, comprising:
a housing comprising a front surface, a back surface, and side surfaces;
electrical components at least partially within the housing, the electrical components comprising a controller, a memory, and a display, the display at or adjacent the front surface of the housing; and
a cover substrate disposed over the display,
wherein at least one of a portion of the housing or the cover substrate comprises the foldable substrate of any one of claims 1-55.

Aspect 57. A method of making a foldable substrate comprising a substrate thickness defined between a first major surface and a second major surface opposite the first major surface, the method comprising:
chemically strengthening the foldable substrate for a first period of time; then
etching a portion of the first major surface to form a first central surface area;
etching a portion of the second major surface to form a second central surface area; and then
further chemically strengthening the foldable substrate for a second period of time,
wherein a central portion comprises a central thickness defined between the first central surface area and the second central surface area, the central portion is positioned between a first portion and a second portion, the first central surface area is recessed from the first major surface by a first distance, the second central surface area is recessed from the second major surface by a second distance, and after the further chemically strengthening, the foldable substrate comprising:
   a first compressive stress region of the first portion extending to a first depth of compression from the first major surface;
   a second compressive stress region of the third portion extending to a second depth of compression from the second major surface;
   a third compressive stress region of the second portion extending to a third depth of compression from the first major surface;
   a fourth compressive stress region of the fourth portion extending to a fourth depth of compression from the second major surface;
   a first central compressive stress region of the central portion extending to a first central depth of compression from the first central surface area;
   a second central compressive stress region of the central portion extending to a second central depth of compression from the second central surface area; and
   a ratio of the first depth of compression to the substrate thickness is greater than a ratio of the first central depth of compression to the central thickness, and the foldable substrate comprises a glass-based material or a ceramic based material.

Aspect 58. A method of making a foldable substrate comprising a substrate thickness defined between a first major surface and a second major surface opposite the first major surface, the method comprising:
masking an existing second central surface area, the existing second central surface area is coplanar with the second major surface; then
chemically strengthening the foldable substrate for a first period of time;
etching an existing first central surface area to form a first central surface area, the existing first central surface area is coplanar with the first major surface;
removing the mask from the existing second central surface area; and
further chemically strengthening the foldable substrate for a second period of time,
wherein a central portion comprises a central thickness defined between the first central surface area and the second central surface area, the central portion is positioned between a first portion and a second portion, the first central surface area is recessed from the first major surface by a first distance, and after the further chemically strengthening, the foldable substrate comprising:
   a first compressive stress region of the first portion extending to a first depth of compression from the first major surface;
   a second compressive stress region of the third portion extending to a second depth of compression from the second major surface;
   a third compressive stress region of the second portion extending to a third depth of compression from the first major surface;
   a fourth compressive stress region of the fourth portion extending to a fourth depth of compression from the second major surface;
   a first central compressive stress region of the central portion extending to a first central depth of compression from the first central surface area;
   a second central compressive stress region of the central portion extending to a second central depth of compression from the second central surface area; and
   a ratio of the first depth of compression to the substrate thickness is greater than a ratio of the first central depth of compression to the central thickness, and the foldable substrate comprises a glass-based material or a ceramic based material.

Aspect 59. The method of any one of aspects 57-58, further comprising, after the further chemically strengthening, etching from about 0.1 micrometers to about 5 micrometers substantially uniformly from the foldable substrate.

Aspect 60. The method of aspect 59, wherein the etching removes from about 0.2 micrometers to about 1 micrometer substantially uniformly from the foldable substrate.

Aspect 61. The method of any one of aspects 57-60, wherein the ratio of the first depth of compression to the substrate thickness is greater than the ratio of the first central depth of compression to the central thickness by from about 0.01 to about 0.2.

Aspect 62. The method of any one of aspects 57-61, wherein the ratio of the first depth of compression to the substrate thickness is greater than the ratio of the first central depth of compression to the central thickness by from about 0.015 to about 0.15.

Aspect 63. The method of any one of aspects 57-62, wherein the ratio of the first depth of compression to the substrate thickness is greater than the ratio of the first central depth of compression to the central thickness by from about 0.02 to about 0.12.

Aspect 64. The method of any one of aspects 57-63, wherein a ratio of the second depth of compression to the substrate thickness is greater than a ratio of the second central depth of compression to the central thickness by from about 0.01 to about 0.2.

Aspect 65. The method of aspect 64, wherein the ratio of the second depth of compression to the substrate thickness is greater than the ratio of the second central depth of compression to the central thickness by from about 0.015 to about 0.15.

Aspect 66. The method of any one of aspects 64-65, wherein the ratio of the second depth of compression to the substrate thickness is greater than the ratio of the second central depth of compression by from about 0.02 to about 0.12.

Aspect 67. The method of any one of aspects 57-66, wherein a width of the second portion is about 15 millimeters or less, a width of the first portion is greater than a width of the central portion, a width of the central portion is greater than the width of the second portion, and a sum of the width of the first portion, the width of the central portion, and the width of the second portion corresponds to a dimension of the foldable substrate.

Aspect 68. The method of aspect 67, wherein the width of the second portion is from about 2 millimeters to about 6 millimeters.

Aspect 69. The method of any one of aspect 57-66, wherein a width of the first portion, a width of the central portion, and a width of the second portion are measured in a direction corresponding to a dimension of the foldable substrate, the width of the second portion as a percentage of the dimension of the foldable substrate is less than 15%, and the width of the first portion as a percentage of the dimension of the foldable substrate is about 35% or more.

Aspect 70. The method of aspect 69, wherein the width of the second portion as a percentage of the dimension of the foldable substrate is from about 2% to about 6%.

Aspect 71. The method of any one of aspects 69-70, wherein the width of the first portion as a percentage of the foldable substrate is from about 40% to about 70%.

Aspect 72. The method of any one of aspects 69-71, wherein the width of the central portion as a percentage of the foldable substrate is from about 15% to about 50%.

Aspect 73. The method of aspect 72, wherein the width of the central portion as a percentage of the foldable substrate is from about 40% to about 48%.

Aspect 74. The method of any one of aspects 57-73, wherein the first depth of compression is substantially equal to the third depth of compression.

Aspect 75. The method of any one of aspects 57-74, wherein the second depth of compression is substantially equal to the fourth depth of compression.

Aspect 76. The method of any one of aspects 57-75, wherein the first central depth of compression is substantially equal to the second central depth of compression.

Aspect 77. The method of any one of aspects 57-76, wherein a square root of a ratio of the second period of time to the first period of time is less than the central thickness divided by the difference between the substrate thickness and the central thickness.

Aspect 78. The method of any one of aspects 57-77, wherein the second period of time is from about 1 minute to about 10 minutes.

Aspect 79. The method of any one of aspects 57-77, wherein the first period of time is from about 45 minutes to about 8 hours.

Aspect 80. The method of any one of aspects 57-79, wherein the second period of time is from about 2% to about 20% of the first period of time.

Aspect 81. The method of any one of aspects 57-80, wherein, after the chemically strengthening but before the further chemically strengthening, the first portion comprises a first intermediate compressive stress region extending to a first intermediate depth of compression, and the first intermediate depth of compression divided by the substrate thickness is in a range from about 10% to about 20%.

Aspect 82. The method of any one of aspects 57-81, wherein at least one of the chemically strengthening or the further chemically strengthening comprises contacting the foldable substrate with potassium ions.

Aspect 83. The method of any one of aspects 57-82, further comprising, before the etching:
disposing an etch mask over the first major surface of the foldable substrate; and
deairing the etch mask in a vacuum.

Aspect 84. The method of any one of claims 57-82, further comprising, before the etching:
disposing an etch mask over the first major surface of the foldable substrate, the etch mask comprising:
a first portion comprising a first barrier layer at least partially adhered to the first major surface, a first polymer layer positioned between the first barrier layer and the first major surface at a first peripheral portion of the first portion, the first polymer layer comprising a first width, a first contact surface of the first polymer layer adhered to the first barrier layer, and a second contact surface of the first polymer layer facing the first major surface; and
a second portion comprising a second barrier layer at least partially adhered to the first major surface, a second polymer layer positioned between the second barrier layer and the first major surface at a second peripheral portion of the second portion, the second polymer layer comprising a second width, a third contact surface of the second polymer layer adhered to the second barrier layer, and a fourth contact surface of the second polymer layer facing the first major surface, and a minimum distance between the first peripheral portion and the second peripheral portion is in a range from about 1 millimeter to about 50 millimeters; and
deairing the etch mask in a vacuum.

Aspect 85. The method of any one of aspects 83-84, wherein the deairing the etch mask in the vacuum occurs for from 1 minute to 15 minutes.

Aspect 86. The method of any one of aspects 83-85, wherein a first transition width of the first transition region is greater than or equal to a first width of the first polymer layer, a second transition width of the second transition region is greater than or equal to a second width of the second polymer layer, the central portion comprising the first transition region, the central region, and the second transition region, and the first width is in a range from about 100 micrometers to about 3 millimeters, and the second width is in a range from about 100 micrometers to about 3 millimeters.

Aspect 87. The method of any one of aspects 83-86, wherein a thickness of the first transition region smoothly and monotonically decreases between the substrate thickness of the first portion and a central thickness of the central portion.

Aspect 88. The method of any one of aspects 83-87, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, the fourth compressive stress region comprises a fourth maximum compressive stress, the first central compressive stress region comprises a first central maximum compressive stress of about 400 MegaPascals or more, and the second central compressive stress region comprises a second central maximum compressive stress.

Aspect 89. The method of aspect 88, wherein the second maximum compressive stress is about 400 MegaPascals or more, the fourth maximum compressive stress is about 400 MegaPascals or more, and the second central maximum compressive stress is about 400 MegaPascals or more.

Aspect 90. The method of any one of aspects 57-89, wherein the substrate thickness is in a range from about 50 micrometers to about 2 millimeters.

Aspect 91. The method of any one of aspects 57-90, wherein the substrate thickness is in a range from about 100 micrometers to about 200 micrometers.

Aspect 92. The method of any one of aspects 57-91, wherein the central thickness in a range from about 25 micrometers to about 120 micrometers.

Aspect 93. The method of any one of aspects 57-92, wherein the central thickness is in a range from about 25 micrometers to about 60 micrometers.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example foldable apparatus in a flat configuration according to aspects, wherein a schematic view of the folded configuration may appear as shown in FIG. 5;

FIGS. 2-4 are cross-sectional views of the foldable apparatus along line 2-2 of FIG. 1 including a foldable substrate according to aspects;

FIG. 5 is a schematic view of example foldable apparatus of aspects of the disclosure in a folded configuration wherein a schematic view of the flat configuration may appear as shown in FIG. 1;

FIG. 6 is a cross-sectional view of a testing apparatus to determine the minimum parallel plate distance of an example foldable substrate along line 7-7 of FIG. 5;

FIG. 7 is a cross-sectional views of another testing apparatus to determine the minimum parallel plate distance of an example modified foldable apparatus along line 7-7 of FIG. 5;

FIG. 8 is a cross-sectional view of a testing apparatus to determine the minimum parallel plate distance of an example foldable substrate along line 7-7 of FIG. 5;

FIG. 9 is a cross-sectional views of another testing apparatus to determine the minimum parallel plate distance of an example modified foldable apparatus along line 7-7 of FIG. 5;

FIG. 10 is a schematic plan view of an example consumer electronic device according to aspects;

FIG. 11 is a schematic perspective view of the example consumer electronic device of FIG. 10;

FIGS. 12-13 are flow charts illustrating example methods making foldable substrates and/or foldable apparatus in accordance with aspects of the disclosure;

FIGS. 14-15 schematically illustrate steps in methods of making a foldable substrate and/or foldable apparatus;

FIG. 16 is a cross-sectional view of a foldable substrate after the step shown in FIG. 15 or 17 and/or before the step shown in FIG. 18;

FIGS. 17-18 schematically illustrate steps in methods of making a foldable substrate and/or foldable apparatus;

FIG. 19 is a cross-sectional view of a foldable substrate after the step shown in FIG. 18 and/or before the step shown in FIG. 20;

FIG. 20 schematically illustrates a step in methods of making a foldable substrate and/or foldable apparatus;

FIG. 21 is a cross-sectional view of a foldable substrate after the step shown in FIG. 20 and/or before the step shown in FIG. 22;

FIGS. 22-26 schematically illustrates a step in methods of making a foldable substrate and/or foldable apparatus;

FIG. 27 is a cross-sectional view of a foldable substrate after the step shown in FIG. 26 and/or before the step shown in FIG. 28;

FIGS. 28-30 schematically illustrates a step in methods of making a foldable substrate and/or foldable apparatus;

FIG. 31 is a cross-sectional view of a foldable substrate after the step shown in FIG. 30 and/or before the step shown in FIG. 32;

FIGS. 32-35 schematically illustrates a step in methods of making a foldable substrate and/or foldable apparatus;

FIG. 36 illustrates surface profiles;

FIG. 37 schematically illustrates a plan view of a foldable substrate; and

FIGS. 38-39 schematically illustrates a cross-section view of a foldable apparatus including a foldable substrate that is rollable.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

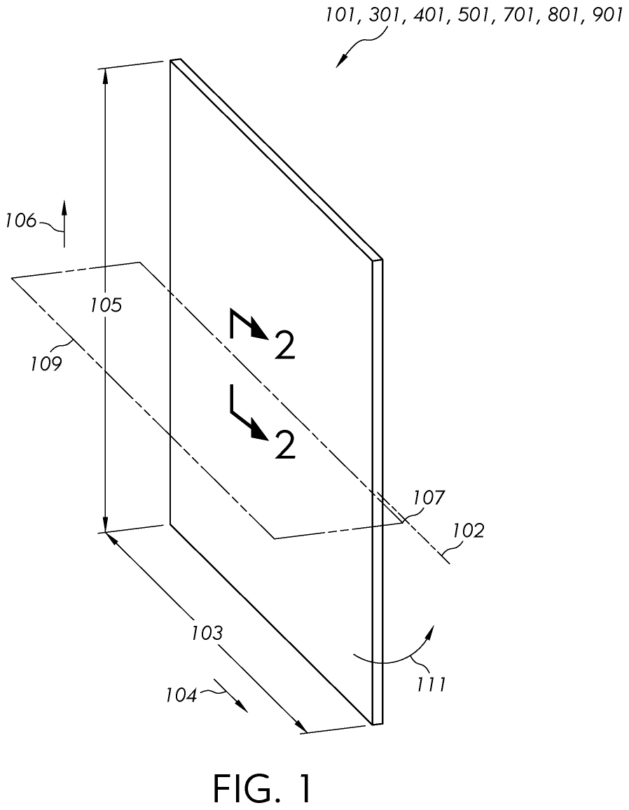

FIGS. 1-4, 6-9, and 38-39 illustrate views of foldable apparatus 101, 301, 401, 501, 701, 801, 901, 3801, and 3901 comprising a foldable substrate 201 in accordance with aspects of the disclosure. Unless otherwise noted, a discussion of features of aspects of one foldable apparatus can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

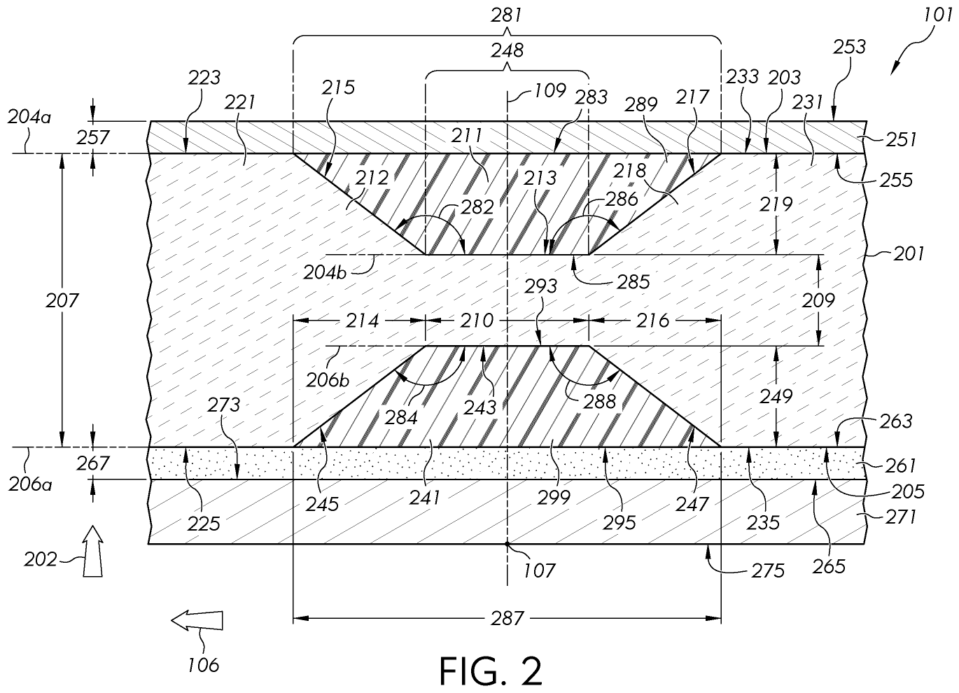

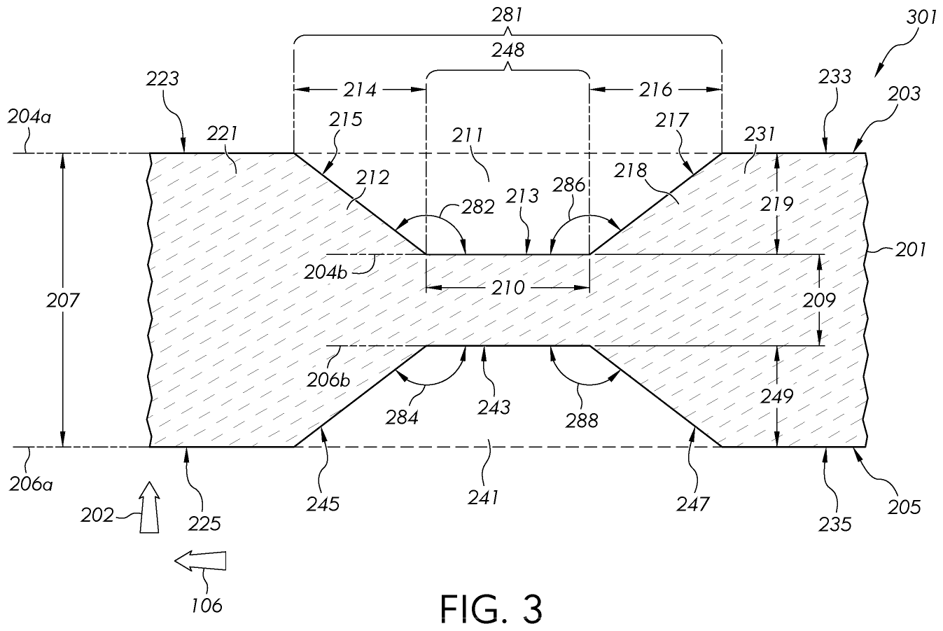

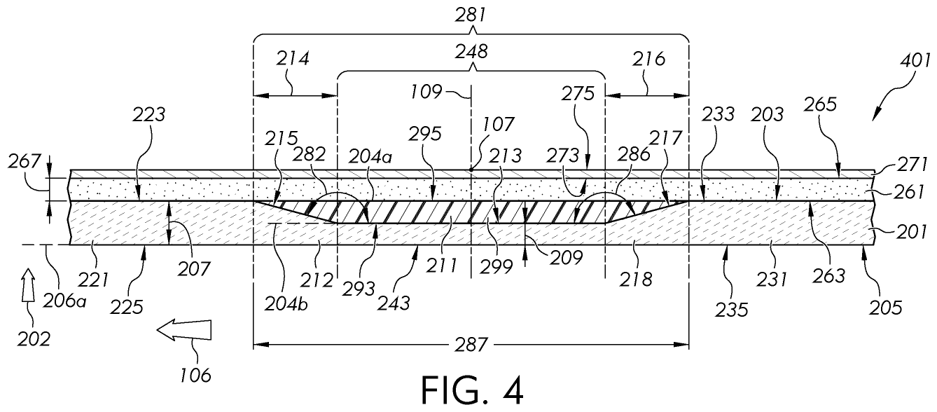

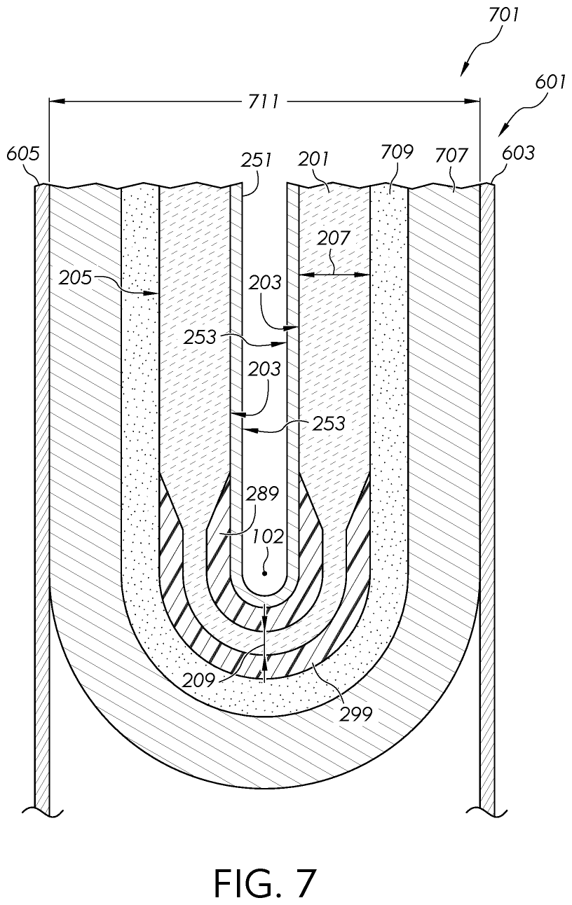

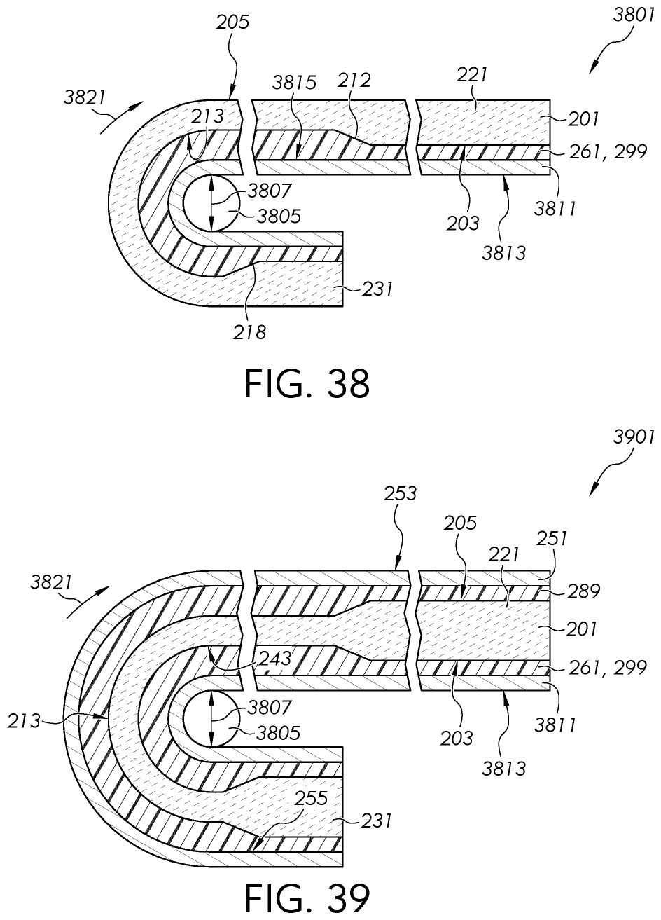

FIGS. 2-4 schematically illustrate example aspects of foldable apparatus 101, 301, and 401 comprising the foldable substrate 201 in accordance with aspects of the disclosure in an unfolded (e.g., flat) configuration while FIGS. 6-9 illustrates an example aspect of a foldable apparatus 501, 701, 801, and 901 comprising the foldable substrate 201 in accordance with aspects of the disclosure in a folded configuration. FIG. 3 schematically illustrate example aspects of foldable apparatus 301 consisting of the foldable substrate 201 in accordance with aspects of the disclosure in an unfolded (e.g., flat) configuration. FIGS. 38-39 schematically illustrate example aspects of foldable apparatus 3801 and 3901 comprising the foldable substrate 201 as a rollable substrate and rollable apparatus. The foldable apparatus 101, 301, and 401 and the foldable substrate 201 comprise a first portion 221, a second portion 231, and a central portion 281 positioned between the first portion 221 and the second portion 231. In aspects, as shown in FIGS. 2 and 4, the foldable apparatus 101 and 401 can comprise a release liner 271 although other substrates (e.g., a glass-based substrate and/or a ceramic-based substrate discussed throughout the application) may be used in further aspects rather than with the illustrated release liner 271. In aspects, as shown in FIGS. 2 and 7, the foldable apparatus 101 and 701 can comprise a coating 251. In aspects, as shown in FIGS. 2 and 4, the foldable apparatus 101 can comprise an adhesive layer 261. In aspects, as shown in FIGS. 2 and 7, foldable apparatus 101 and 701 can comprise a polymer-based portion 289 and/or 299. As shown in FIGS. 2-4, the foldable substrate 201 can comprise a first recess 211. In aspects, as shown in FIGS. 2-3, the foldable substrate 201 can further comprise a second recess 241. It is to be understood that any of the foldable apparatus of the disclosure can comprise a second substrate (e.g., a glass-based substrate and/or a ceramic-based substrate), a release liner 271, a display device, a coating 251, an adhesive layer 261, and/or a polymer-based portion 289 and/or 299.

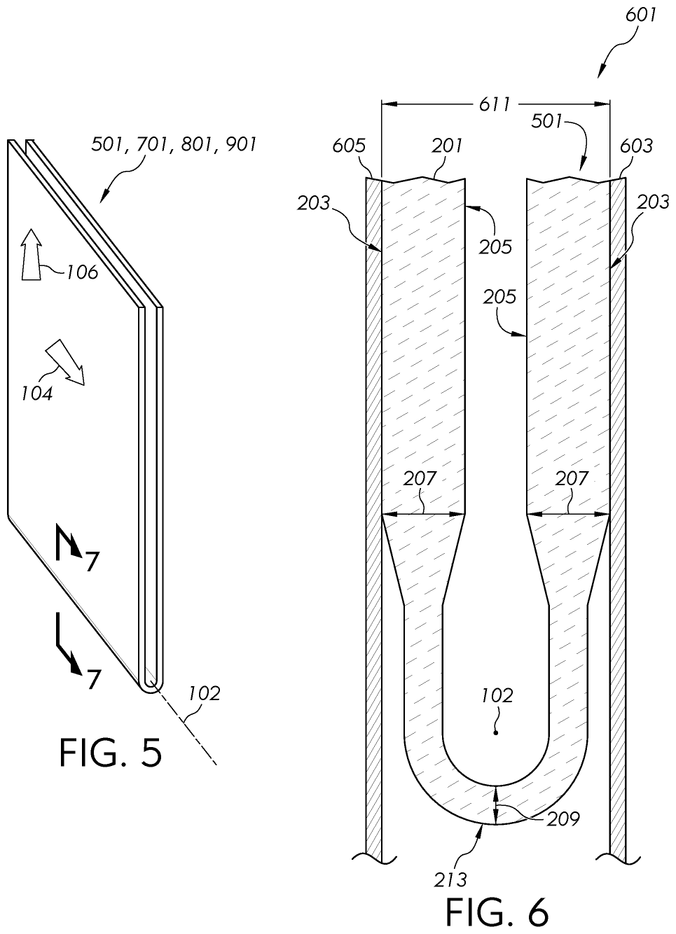

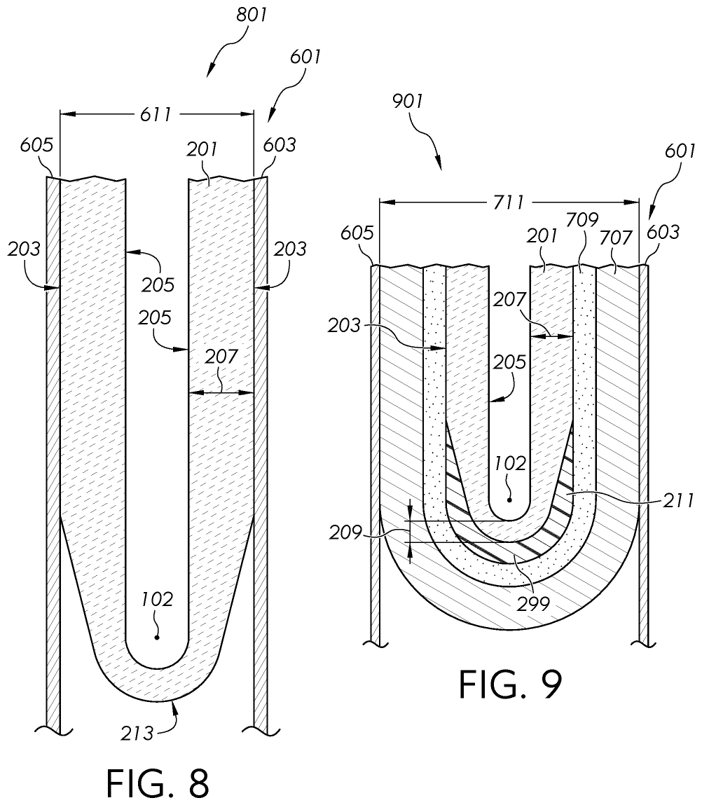

Throughout the disclosure, with reference to FIG. 1, the width 103 of the foldable apparatus 101, 301, 401, 501, 701, 801, 901, 3801, and/or 3901 is considered the dimension of the foldable apparatus taken between opposed edges of the foldable apparatus in a direction 104 of a fold axis 102 of the foldable apparatus, wherein the direction 104 also comprises the direction of the width 103. Furthermore, throughout the disclosure, the length 105 of the foldable apparatus 101, 301, 401, 501, 701, 801, 901, 3801, and/or 3901 is considered the dimension of the foldable apparatus 101, 301, 401, 501, 701, 801, 901, 3801, and/or 3901 taken between opposed edges of the foldable apparatus 101, 301, 401, 501, 701, 801, 901, 3801, and/or 3901 in a direction 106 perpendicular to the fold axis 102 of the foldable apparatus 101, 301, 401, 501, 701, 801, 901, 3801, and/or 3901. It is to be understood that the direction 104 of the width 103 and/or the direction 106 of the length 105 can correspond to corresponding directions in the foldable substrate 201. In aspects, as shown in FIGS. 1-2, the foldable apparatus of any aspects of the disclosure can comprise a fold plane 109 that includes the fold axis 102 when the foldable apparatus is in the flat configuration (e.g., see FIG. 2). In further aspects, as shown in FIG. 2, the fold plane 109 can extend along the fold axis 102 and in a direction of the substrate thickness 207 when the foldable apparatus is in the flat configuration (e.g., see FIG. 2). The fold plane 109 may comprise a central axis 107 of the foldable apparatus. In aspects, the foldable apparatus can be folded in a direction 111 (e.g., see FIG. 1) about the fold axis 102 extending in the direction 104 of the width 103 to form a folded configuration (e.g., see FIGS. 5, 7, and 9). Likewise, folding the foldable substrate 201 (e.g., see FIG. 3) about the fold axis can form a folded configuration (e.g., see FIGS. 6 and 8). As shown, the foldable apparatus and/or the foldable substrate may include a single fold axis to allow the foldable apparatus and/or the foldable substrate to comprise a bifold wherein, for example, the foldable apparatus and/or the foldable substrate may be folded in half. In further aspects, the foldable apparatus and/or the foldable substrate may include two or more fold axes with each fold axis including a corresponding central portion similar or identical to the central portion 281 discussed herein. For example, providing two fold axes can allow the foldable apparatus and/or the foldable substrate to comprise a trifold wherein, for example, the foldable apparatus and/or the foldable substrate may be folded with the first portion 221, the second portion 231, and a third portion similar or identical to the first portion or second portion with the central portion 281 and another central portion similar to or identical to the central portion positioned between the first portion and the second portion and between the second portion and the third portion, respectively.

The foldable substrate 201 can comprise a glass-based substrate and/or a ceramic-based substrate having a pencil hardness of 8H or more, for example, 9H or more. As used herein, pencil hardness is measured using ASTM D 3363-20 with standard lead graded pencils. Providing a glass-based foldable substrate and/or a ceramic-based foldable substrate can enhance puncture resistance and/or impact resistance.

In aspects, the foldable substrate 201 can comprise a glass-based substrate. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In aspects, glass-based material can comprise an alkali-containing glass or an alkali-free glass, either of which may be free of lithia or not. In aspects, the glass material can be alkali-free and/or comprise a low content of alkali metals (e.g., R₂O of about 10 mol % or less, wherein R₂O comprises Li₂O Na₂O, K₂O, or the more expansive list provided below). In one or more aspects, a glass-based material may comprise, in mole percent (mol %): SiO₂ in a range from about 40 mol % to about 80%, Al₂O₃ in a range from about 5 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali-metal oxide, for example, Li₂O, Na₂O, K₂O, Rb₂O, and Cs₂O. As used herein, RO can refer to MgO, CaO, SrO, BaO, and ZnO. In aspects, a glass-based substrate may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, Mn₂O₇. “Glass-ceramics” include materials produced through controlled crystallization of glass. In aspects, glass-ceramics have about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes. In one or more aspects, MAS-System glass-ceramic substrates may be strengthened in Li₂SO₄ molten salt, whereby an exchange of 2Li⁺ for Mg²⁺ can occur.

In aspects, the foldable substrate 201 can comprise a ceramic-based substrate. As used herein, “ceramic-based” includes both ceramics and glass-ceramics, wherein glass-ceramics have one or more crystalline phases and an amorphous, residual glass phase. Ceramic-based materials may be strengthened (e.g., chemically strengthened). In aspects, a ceramic-based material can be formed by heating a glass-based material to form ceramic (e.g., crystalline) portions. In further aspects, ceramic-based materials may comprise one or more nucleating agents that can facilitate the formation of crystalline phase(s). In aspects, ceramic-based materials can comprise one or more oxides, nitrides, oxynitrides, carbides, borides, and/or silicides. Example aspects of ceramic oxides include zirconia (ZrO₂), zircon (ZrSiO₄), an alkali-metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlO₁₊ₙN₂₋ₙ, where m, n, and the resulting subscripts are all non-negative integers). Example aspects of carbides and carbon-containing ceramics include silicon carbide (SiC), tungsten carbide (WC), an iron carbide, boron carbide (B₄C), alkali-metal carbides (e.g., lithium carbide (Li₄C₃)), alkali earth metal carbides (e.g., magnesium carbide (Mg₂C₃)), and graphite. Example aspects of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example aspects of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali-metal silicide (e.g., magnesium silicide (Mg₂Si)), hafnium disilicide (HfSi₂), and platinum silicide (PtSi).

Throughout the disclosure, an elastic modulus (e.g., Young's modulus) and/or a Poisson's ratio is measured using ISO 527-1:2019. In aspects, the foldable substrate 201 can comprise an elastic modulus in a range from about 10 GPa to about 100 GPa, from about 40 GPa to about 100 GPa, from about 60 GPa to about 100 GPa, from about 60 GPa to about 80 GPa, from about 80 GPa to about 100 GPa, or any range or subrange therebetween.

In aspects, the foldable substrate 201 can be optically transparent. As used herein, “optically transparent” or “optically clear” means an average transmittance of 70% or more in the wavelength range of 400 nm to 700 nm through a 1.0 mm thick piece of a material. In aspects, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

As shown in FIGS. 2-4, the foldable apparatus 101, 301, and 401 comprise the foldable substrate 201 comprising a first major surface 203 and a second major surface 205 opposite the first major surface 203. As shown in FIGS. 2-4, the first major surface 203 can extend along a first plane 204a. The second major surface 205 can extend along a second plane 206a. In aspects, as shown, the second plane 206a can be parallel to the first plane 204a. As used herein, a substrate thickness 207 can be defined between the first major surface 203 and the second major surface 205 as a distance between the first plane 204a and the second plane 206a. In aspects, the substrate thickness 207 can be about 10 micrometers (μm) or more, about 25 μm or more, about 40 μm or more, about 50 μm or more, about 60 μm or more, about 70 μm or more, about 80 μm or more, about 90 μm or more, about 100 μm or more, about 125 μm or more, about 150 μm or more, about 200 μm or more, about 300 μm or more, about 2 millimeters (mm) or less, about 1 mm or less, about 800 μm or less, about 500 μm or less, about 300 μm or less, about 200 μm or less, about 180 μm or less, or about 160 μm or less. In aspects, the substrate thickness 207 can be in a range from about 10 μm to about 2 mm, from about 25 μm to about 2 mm, from about 40 μm to about 2 mm, from about 50 μm to about 2 mm, from about 60 μm to about 2 mm, from about 70 μm to about 2 mm, from about 70 μm to about 1 mm, from about 70 μm to about 800 μm, from about 80 μm to about 500 μm, from about 90 μm 500 μm, from about 100 μm to about 200 μm, from about 125 μm to about 200 μm, from about 150 μm to about 200 μm, from about 150 μm to about 160 μm, or any range or subrange therebetween.

As shown in FIGS. 2-4, the first portion 221 of the foldable substrate 201 can comprise a first surface area 223 and a second surface area 225 opposite the first surface area 223. The first portion 221 will now be described with reference to the foldable apparatus 101 of FIG. 2 with the understanding that such description of the first portion 221, unless otherwise stated, can also apply to any aspects of the disclosure, for example, the foldable apparatus 301, 401, 501, 701, 801, 901, 3801, and/or 3901 illustrated in FIGS. 3-4, 6-9, and 38-39. In aspects, as shown, the first surface area 223 can comprise a planar surface, and/or the second surface area 225 of the first portion 221 can comprise a planar surface. In further aspects, as shown, the second surface area 225 can be parallel to the first surface area 223. In aspects, as shown, the first major surface 203 can comprise the first surface area 223 and the second major surface 205 can comprise the second surface area 225. In further aspects, the first surface area 223 can extend along the first plane 204a. In further aspects, the second surface area 225 can extend along the second plane 206a. In aspects, the substrate thickness 207 can correspond to the distance between the first surface area 223 of the first portion 221 and the second surface area 225 of the first portion 221. In aspects, the substrate thickness 207 can be substantially uniform across the first surface area 223. In aspects, a first thickness defined between the first surface area 223 and the second surface area 225 can be within one or more of the ranges discussed above with regards to the substrate thickness 207. In further aspects, the first thickness can comprise the substrate thickness 207. In further aspects, the first thickness of the first portion 221 may be substantially uniform between the first surface area 223 and the second surface area 225 across its corresponding length (i.e., in the direction 106 of the length 105 of the foldable apparatus) and/or its corresponding width (i.e., in the direction 104 of the width 103 of the foldable apparatus).

As shown in FIGS. 2-4, the second portion 231 of the foldable substrate 201 can comprise a third surface area 233 and a fourth surface area 235 opposite the third surface area 233. The second portion 231 will now be described with reference to the foldable apparatus 101 of FIG. 2 with the understanding that such description of the second portion 231, unless otherwise stated, can also apply to any aspects of the disclosure, for example, the foldable apparatus 301, 401, 501, 701, 801, 901, 3801, and/or 3901 illustrated in FIGS. 3-4, 6-9, and 38-39. In aspects, as shown, the third surface area 233 of the second portion 231 can comprise a planar surface, and/or the fourth surface area 235 of the second portion 231 can comprise a planar surface. In further aspects, the third surface area 233 of the second portion 231 can be in a common plane with the first surface area 223 of the first portion 221. In further aspects, as shown, the fourth surface area 235 can be parallel to the third surface area 233. In further aspects, the fourth surface area 235 of the second portion 231 can be in a common plane with the second surface area 225 of the first portion 221. A second thickness can be defined between the third surface area 233 of the second portion 231 and the fourth surface area 235 of the second portion 231. In aspects, the second thickness can be within the range discussed above with regards to the substrate thickness 207. In further aspects, the second thickness can comprise the substrate thickness 207. In further aspects, as shown, the second thickness can be substantially equal to the substrate thickness 207 (e.g., first thickness). In aspects, the second thickness of the second portion 231 may be substantially uniform between the third surface area 233 and the fourth surface area 235.

As shown in FIGS. 2-4, the foldable substrate 201 can comprise a central portion 281 positioned between the first portion 221 and the second portion 231. In aspects, the central portion 281 can comprise a first central surface area 213 and a second central surface area 243 opposite the first central surface area 213. As shown, the first central surface area 213 of the central portion 281 can be positioned between the first surface area 223 and the third surface area 233. In further aspects, the first central surface area 213 can correspond to a central region 248 of the central portion 281. In further aspects, as shown, the first central surface area 213 can extend along a third plane 204b when the foldable apparatus 101, 301, and/or 401 is in a flat configuration. A first recess 211 can be defined between the first central surface area 213 (e.g., third plane 204b) and the first plane 204a.

In aspects, the third plane 204b can be substantially parallel to the first plane 204a and/or the second plane 206a. In further aspects, as shown in FIGS. 2-3, the first central surface area 213 can be recessed from the first major surface 203 by a first distance 219. In further aspects, the first distance 219 that the first central surface area 213 is recessed from the first plane 204a can be about 1 μm or more, about 5 μm or more, about 10 μm or more, about 25 μm or more, about 40 μm or more, about 80 μm or more, about 100 μm or more, about 125 μm or more, about 150 μm or more, about 1 mm or less, about 800 μm or less, about 500 μm or less, about 300 μm or less, about 200 μm or less, about 180 μm or less, or about 160 μm or less. In further aspects, the first distance 219 can be in a range from about 1 μm to about 1 mm, from about 1 μm to about 800 μm, from about 5 μm to about 800 μm, from about 5 μm to about 500 μm, from about 10 μm to about 500 μm, from about 10 μm to about 300 μm, from about 25 μm to about 300 μm, from about 25 μm to about 200 μm, from about 40 μm to about 200 μm, from about 80 μm to about 200 μm, from about 80 μm to about 200 μm, from about 100 μm to about 200 μm, from about 125 μm to about 200 μm, from about 125 μm to about 180 μm, from about 125 μm to about 160 μm, from about 125 μm to about 150 μm, or any range or subrange therebetween. In further aspects, the first distance 219 that the first central surface area 213 is recessed from the first plane 204a as a percentage of the substrate thickness 207 can be about 1% or more, about 5% or more, about 10% or more, about 15% or more, about 20% or more, about 25% or more, about 75% or less, about 60% or less, about 50% or less, about 40% or less, about 35% or less, or about 30% or less. In further aspects, the first distance 219 as a percentage of the substrate thickness 207 can be in a range from about 1% to about 75%, from about 1% to about 60%, from about 5% to about 60%, from about 5% to about 50%, from about 10% to about 50%, from about 10% to about 45%, from about 15% to about 45%, from about 20% to about 45%, from about 20% to about 35%, from about 20% to about 30%, from about 25% to about 30%, or any range or subrange therebetween.

As shown in FIGS. 2-4, the second central surface area 243 of the central portion 281 can be positioned between the second surface area 225 and the fourth surface area 235. In further aspects, as shown in FIGS. 2-3, the second central surface area 243 can extend along a fourth plane 206b when the foldable apparatus 101 and/or 301 is in a flat configuration. In further aspects, as shown in FIGS. 2-3, a second recess 241 can be defined between the second central surface area 243 (e.g., fourth plane 206b) and the second plane 206a. In aspects, as shown in FIG. 4, the second central surface area 243 can extend along the second plane 206a.

In aspects, as shown in FIGS. 2-3, the second central surface area 243 can be recessed from the second major surface 205 by a second distance 249. In further aspects, the second distance 249 can be within one or more of the ranges discussed above for the first distance 219. In further aspects, the first distance can be greater than the second distance. In even further aspects, the second distance 249 that the second central surface area 243 is recessed from the second plane 206a as a percentage of the substrate thickness 207 can be about 1% or more, about 2% or more, about 5% or more, about 10% or more, about 12% or more, about 30% or less, about 25% or less, about 20% or less, about 18% or less, or about 15% or less. In even further aspects, the second distance 249 as a percentage of the substrate thickness 207 can be in a range from about 1% to about 30%, from about 1% to about 25%, from about 2% to about 25%, from about 5% to about 25%, from about 5% to about 20%, from about 10% to about 20%, from about 10% to about 18%, from about 12% to about 18%, from about 12% to about 15%, or any range or subrange therebetween. In further aspects, as shown in FIG. 2, the first distance 219 can be substantially equal to the second distance 249. Providing the first distance substantially equal to the second distance can further reduce the incidence of mechanical instabilities in the central portion, for example, because the foldable substrate is symmetric about a plane comprising a midpoint in the substrate thickness and the central thickness. In further aspects, as shown in FIG. 4, the second central surface area 243 can be coplanar with the second surface area 225 and/or the fourth surface area 235, for example, forming a planar second major surface 205 extending along the second plane 206a.

A central thickness 209 can be defined between the first central surface area 213 and the second central surface area 243, which can be measured as the distance between the third plane 204b and the fourth plane 206b. In aspects, the central thickness 209 can be about 1 μm or more, about 5 μm or more, about 10 μm or more, about 25 μm or more, about 40 μm or more, about 120 μm or less, about 100 μm or less, about 80 μm or less, about 60 μm or less, or about 50 μm or less. In aspects, the central thickness 209 can be in a range from about 1 μm to about 120 μm, from about 5 μm to about 120 μm, from about 10 μm to about 120 μm, from about 10 μm to about 120 μm, from about 25 μm to about 120 μm, from about 25 μm to about 100 μm, from about 25 μm to about 80 μm, from about 25 μm to about 60 μm, from about 40 μm to about 60 μm, or any range or subrange therebetween. In aspects, the central thickness 209 can be less than the substrate thickness 207 by about 10 μm or more, about 20 μm or more, about 30 μm or more, about 40 μm or more, about 50 μm or more, or about 60 μm or more. In aspects, the central thickness 209 as a percentage of the substrate thickness 207 can be about 0.5% or more, about 1% or more, about 2% or more, about 5% or more, about 6% or more, about 40% or less, about 30% or less, about 20% or less, about 13% or less, about 10% or less, or about 8% or less. In aspects, the central thickness 209 as a percentage of the substrate thickness 207 can be in a range from about 0.5% to about 40%, from about 0.5% to about 30%, from about 0.5% to about 20%, from about 0.5% to about 13%, from about 1% to about 13%, from about 1% to about 10%, from about 2% to about 10%, from about 2% to about 8%, from about 5% to about 8%, from about 6% to about 8%, or any range or subrange therebetween. In aspects, the central region 248 of the central portion 281 can correspond to a region comprising the central thickness 209. By providing the first central surface area 213 of the central portion 281 extending along the third plane 204b parallel to the second central surface area 243 of the central portion 281 extending along the fourth plane 206b, a uniform central thickness 209 may extend across the central portion 281 that can provide enhanced folding performance at a predetermined thickness for the central thickness 209. A uniform central thickness 209 across the central portion 281 can improve folding performance by preventing stress concentrations that would occur if a portion of the central portion 281 was thinner than the rest of the central portion 281.

In aspects, as shown in FIGS. 2-4, the central portion 281 of the foldable substrate 201 can comprise a first transition region 212 comprising a first transition surface area 215 extending between the first surface area 223 and the first central surface area 213. In further aspects, as shown, a width (e.g., first transition width 214) of the first transition region 212 can be measured as the minimum distance in a direction 106 of the length 105 (see FIG. 1) between a portion of the first central surface area 213 extending along the third plane 204b and a portion of the first surface area 223. In even further aspects, the first transition width 214 of the first transition region 212 can be about 0.15 mm or more, about 0.2 mm or more, about 0.3 mm or more, about 0.4 mm or more, about 0.5 mm or more, about 0.6 mm or more, about 0.7 mm or more, about 0.8 mm or more, about 0.9 mm or more, about 2 mm or less, about 1.8 mm or less, about 1.5 mm or less, about 1.2 mm or less, about 1 mm or less, about 0.8 mm or less, about 0.7 mm or less, or about 0.5 mm or less. In even further aspects, the first transition width 214 of the first transition region 212 can be in a range from about 0.15 mm to about 2 mm, from about 0.2 mm to about 2 mm, from about 0.3 mm to about 2 mm, from about 0.4 mm to about 2 mm, about 0.5 mm to about 2 mm, from about 0.5 mm to about 1.8 mm, from about 0.6 mm to about 1.8 mm, from about 0.6 mm to about 1.5 mm, from about 0.7 mm to about 1.5 mm, from about 0.7 mm to about 1.2 mm, from about 0.8 mm to about 1.2 mm, from about 0.8 mm to about 1 mm, from about 0.9 mm to about 1 mm, or any range or subrange therebetween. In even further aspects, the first transition width 214 of the first transition region 212 can be in a range from about 0.5 mm to about 1.8 mm, from about 0.5 mm to about 1.5 mm, from about 0.5 mm to about 1.2 mm, from about 0.5 mm to about 1 mm, from about 0.6 mm to about 1 mm, from about 0.7 mm to about 1 mm, or any range or subrange therebetween. In even further aspects, the first transition width 214 of the first transition region 212 can be in a range from about 0.15 mm to about 1.8 mm, from about 0.15 mm to about 1.5 mm, from about 0.15 mm to about 1.2 mm, from about 0.15 mm to about 1 mm, from about 0.15 mm to about 0.7 mm, from about 0.15 mm to about 0.7 mm, from about 0.2 mm to about 0.5 mm, from about 0.3 mm to about 0.5 mm, from about 0.4 mm to about 0.5 mm, or any range or subrange therebetween. Reducing a width of the first transition region and/or the second transition region can reduce a total chemical strengthening induced stress exerted on the central portion by the corresponding transition regions such that a strain of the first central surface area and/or the second central surface area is less than a critical buckling strain (e.g., onset of mechanical instabilities).

In aspects, as shown in FIGS. 2-3, the first transition region 212 can comprise a second transition surface area 245 extending between the second surface area 225 and the second central surface area 243. In further aspects, a width of the second transition surface area 245 can be measured as the minimum distance in a direction 106 of the length 105 (see FIG. 1) between a portion of the second central surface area 243 extending along the fourth plane 206b and a portion of the second surface area 225. In even further aspects, the width of the second transition surface area 245 can be substantially equal to (e.g., equal to) the first transition width 214 of the first transition region 212. In aspects, as shown in FIG. 4, the portion of the first transition region 212 extending between the second surface area 225 and the second central surface area 243 can be coplanar with one or both surface areas.

In aspects, as shown in FIGS. 2-4, a thickness of the first transition region 212 can decrease between the substrate thickness 207 of the first portion 221 and the central thickness 209 of the central portion 281. In further aspects, as shown, a thickness of the first transition region 212 can smoothly decrease, monotonically decrease, and/or smoothly and monotonically decrease between the substrate thickness 207 of the first portion 221 and the central thickness 209 of the central portion 281. As used herein, a thickness decreases smoothly if changes in the cross-sectional area are smooth (e.g., gradual) rather than abrupt (e.g., step) changes in thickness. As used herein, a thickness decreases monotonically in a direction if the thickness decreases for a portion and for the rest of the time either stays the same, decreases, or a combination thereof (i.e., the thickness decreases but never increases in the direction). Providing a smooth shape of the first transition region and/or the second transition region can reduce optical distortions. Providing a monotonically decreasing thickness of the first transition region and/or the second transition region can reduce an incidence of mechanical instabilities and/or decrease a visibility of the transition region.

In aspects, as shown in FIGS. 2-4, the first transition surface area 215 can comprise a linearly inclined surface extending between the first central surface area 213 and the first surface area 223. In aspects, although not shown, the first transition surface area can comprise a concave up shape, for example, with a local slope of the first transition surface area smoothly transitioning to a slope of the first central surface area 213 while a local slope of the first transition surface area is substantially different from a slope of the first surface area 223. In aspects, although not shown, the first transition surface area can comprise a sigmoid shape. In aspects, although not shown, a local slope of the first transition surface area can be greater at a midpoint of the first transition surface area than where the first transition surface area meets the first central surface area 213 and where the first transition surface area meets the first surface area 223. In aspects, although not shown, the first transition surface area can comprise a convex up shape, for example, with a local slope of the first transition surface area smoothly transitioning to a slope of the first surface area 223 while a local slope of the first transition surface area is substantially different from a slope of the first central surface area 213. In aspects, the second transition surface area can comprise one of the shapes or properties discussed above in this paragraph for the first transition surface area. For example, as shown in FIG. 2, the second transition surface area 245 can comprise a linearly inclined surface extending between the second central surface area 243 and the second surface area 225.

In aspects, as shown in FIGS. 2-4, a thickness of the first transition region 212 can decrease at a constant rate (e.g., linearly change) from the substrate thickness 207 to the central thickness 209. In aspects, although not shown, a thickness of the first transition region can decrease slower where the first transition surface area meets the first central surface area 213 than at a midpoint of the first transition region and/or than where the first transition surface area meets the first surface area 223 (e.g., first portion 221). In aspects, although not shown, a thickness of the first transition region can decrease faster where the first transition surface area meets the first central surface area 213 than at a midpoint of the first transition region and/or than where the first transition surface area meets the first surface area 223. Providing a non-uniform slope of a surface area of the first transition region and/or the second transition region can reduce an amount of the corresponding transition region comprising intermediate thicknesses, for example, comprising a chemical strengthening induced expansion strain less than a portion of the corresponding transition region closer to the first central surface area and/or the second central surface area and/or than the first central surface area and/or the second central surface area.

Throughout the disclosure, an average angle of a transition surface area relative to a central surface area is measured as an angle between a transition surface area and a central surface area. An angle is calculated for a location on the corresponding transition surface area relative to the corresponding central surface area with the location of the corresponding central surface area approximated as a plane fitted from measurements at 20 locations evenly spaced over the corresponding central surface area in the direction 106 of the length 105. The angle measured is an external angle for the foldable substrate, meaning that it extends from the plane fitted to the corresponding central surface area to the location on the corresponding transition surface area without passing through the material of the foldable substrate other than an incidental amount at the endpoints. The average angle is calculated from 10 locations on the corresponding transition surface area that are located in a region comprising 80% of a distance that the corresponding central surface area is recessed from the corresponding major surface with the region centered at the midpoint between the corresponding central surface area and the corresponding major surface in the direction 202 of the thickness (e.g., substrate thickness 207, central thickness 209).

In aspects, as shown in FIGS. 2-4, the first transition surface area 215 of the first transition region 212 extends between the first surface area 223 and the first central surface area 213 with a first average angle 282 relative to the first central surface area 213. As described above, the first average angle 282 is an external angle because it does not pass through the material of the foldable substrate 201 other than an incidental amount at the endpoints. In further aspects, the first average angle 282 can be about 167° or more, about 170° or more, about 171° or more, about 172° or more, about 179° or less, about 176° or less, about 175° or less, about 174° or less, or about 173° or less. In further aspects, the first average angle 282 can be in a range from about 167° to about 179°, from about 167° to about 176°, from about 170° to about 176°, from about 170° to about 175°, from about 171° to about 175°, from about 171° to about 174°, from about 172° to about 174°, from about 172° to about 173°, or any range or subrange therebetween. For example, a first transition surface comprising a linear (e.g., planar) surface area with a first transition width of 500 μm and height (i.e., a difference between the first central surface area 213 and the first major surface 203 corresponding to the first distance 219) of 30 μm corresponds to a first average angle of about 176.6°.

In aspects, as shown in FIGS. 2-4, the third transition surface area 217 of the second transition region 218 extends between the third surface area 233 and the first central surface area 213 with a third average angle 286 relative to the first central surface area 213. In further aspects, the third average angle 286 can be within one or more of the ranges discussed above for the first average angle 282. In further aspects, the first average angle 282 can be substantially equal to the third average angle 286.

In aspects, as shown in FIGS. 2-4, the central portion 281 of the foldable substrate 201 can comprise a second transition region 218 comprising a third transition surface area 217 extending between the third surface area 233 and the first central surface area 213. In further aspects, as shown, a width (e.g., second transition width 216) of the second transition region 218 can be measured as the minimum distance in a direction 106 of the length 105 (see FIG. 1) between a portion of the first central surface area 213 extending along the third plane 204b and a portion of the third surface area 233. In even further aspects, the second transition width 216 of the second transition region 218 can be within one or more of the ranges discussed above for the first transition width 214. In still further aspects, the second transition width 216 of the second transition region 218 can be substantially equal to (e.g., equal to) the first transition width 214.

In aspects, as shown in FIGS. 2-3, the second transition region 218 can comprise a fourth transition surface area 247 extending between the fourth surface area 235 and the second central surface area 243. In further aspects, a width of the fourth transition surface area 247 can be measured as the minimum distance in a direction 106 of the length 105 (see FIG. 1) between a portion of the second central surface area 243 extending along the fourth plane 206b and a portion of the fourth surface area 235. In even further aspects, the width of the fourth transition surface area 247 can be substantially equal to (e.g., equal to) the second transition width 216. In aspects, as shown in FIGS. 2-3, a thickness of the second transition region 218 can decrease between the substrate thickness 207 of the second portion 231 and the central thickness 209 of the central portion 281. In further aspects, as shown, a thickness of the first transition region 212 can smoothly decrease, monotonically decrease, or smoothly and monotonically decrease between the substrate thickness 207 of the second portion 231 and the central thickness 209 of the central portion 281. In aspects, as shown in FIG. 4, the portion of the second transition region 218 extending between the fourth surface area 235 and the second central surface area 243 can be coplanar with one or both surface areas.

In aspects, as shown in FIGS. 2-4, the third transition surface area 217 can comprise a linearly inclined surface extending between the first central surface area 213 and the third surface area 233. In aspects, the third transition surface area 217 and/or the fourth transition surface area 247 can comprise one of the shapes or properties discussed above with reference to the first transition surface area. In aspects, the fourth transition surface area 247 can comprise one of the shapes or properties discussed above in this paragraph for the first transition surface area. For example, as shown in FIGS. 2-4, the fourth transition surface area 247 can comprise a linearly inclined surface extending between the second central surface area 243 and the fourth surface area 235. In aspects, as shown in FIGS. 2-4, a thickness of the second transition region 218 can decrease at a constant rate (e.g., linearly change) from the substrate thickness 207 to the central thickness 209. In aspects, although not shown, a thickness of the second transition region can decrease slower where the third transition surface area meets the first central surface area 213 than at a midpoint of the second transition region and/or than where the third transition surface area meets the third surface area 233 (e.g., first portion 221). In aspects, although not shown, a thickness of the second transition region can decrease faster where the third transition surface area meets the first central surface area 213 than at a midpoint of the second transition region and/or than where the third transition surface area meets the third surface area 233.

In aspects, as shown in FIGS. 2-3, the second transition surface area 245 of the first transition region 212 extends between the second surface area 225 and the second central surface area 243 with a second average angle 284 relative to the second central surface area 243. In further aspects, the second average angle 284 can be about 167° or more, about 170° or more, about 171° or more, about 172° or more, about 179° or less, about 176° or less, about 175° or less, about 174° or less, or about 173° or less. In further aspects, the second average angle 284 can be in a range from about 167° to about 179°, from about 167° to about 176°, from about 170° to about 176°, from about 170° to about 175°, from about 171° to about 175°, from about 171° to about 174°, from about 172° to about 174°, from about 172° to about 173°, or any range or subrange therebetween. In further aspects, the first average angle 282 can be substantially equal to the second average angle 284. Providing an average angle within one of the above-mentioned ranges can provide reduced visibility of the transition region.

In aspects, as shown in FIGS. 2-3, the fourth transition surface area 247 of the second transition region 218 extends between the fourth surface area 235 and the second central surface area 243 with a fourth average angle 288 relative to the second central surface area 243. In further aspects, the fourth average angle 288 can be within one or more of the ranges discussed above for the second average angle 284. In further aspects, the second average angle 284 can be substantially equal to the fourth average angle 288. In further aspects, the first average angle 282 and/or the third average angle 286 can be substantially equal to the fourth average angle 288.

As used herein, if a first layer and/or component is described as “disposed over” a second layer and/or component, other layers may or may not be present between the first layer and/or component and the second layer and/or component. Furthermore, as used herein, “disposed over” does not refer to a relative position with reference to gravity. For example, a first layer and/or component can be considered “disposed over” a second layer and/or component, for example, when the first layer and/or component is positioned underneath, above, or to one side of a second layer and/or component. As used herein, a first layer and/or component described as “bonded to” a second layer and/or component means that the layers and/or components are bonded to each other, either by direct contact and/or bonding between the two layers and/or components or via an adhesive layer. As used herein, a first layer and/or component described as “contacting” or “in contact with” a second layer and/or components refers to direct contact and includes the situations where the layers and/or components are bonded to each other.

As shown in FIGS. 2 and 4, the foldable apparatus 101 can comprise an adhesive layer 261. As shown, the adhesive layer 261 can comprise a first contact surface 263 and a second contact surface 265 that can be opposite the first contact surface 263. In aspects, as shown in FIGS. 2 and 4, the second contact surface 265 of the adhesive layer 261 can comprise a planar surface. In aspects, as shown in FIGS. 2 and 4, the first contact surface 263 of the adhesive layer 261 can comprise a planar surface. An adhesive thickness 267 of the adhesive layer 261 can be defined as a minimum distance between the first contact surface 263 and the second contact surface 265. In aspects, the adhesive thickness 267 of the adhesive layer 261 can be about 1 μm or more, about 5 μm or more, about 10 μm or more, about 100 μm or less, about 60 μm or less, about 30 μm or less, or about 20 μm or less. In aspects, the adhesive thickness 267 of the adhesive layer 261 can be in a range from about 1 μm to about 100 μm, from about 5 μm to about 100 μm, from about 5 μm to about 60 μm, from about 5 μm to about 30 μm, from about 10 μm to about 30 μm, from about 10 μm to about 20 μm, or any range or subrange therebetween.

In aspects, as shown in FIGS. 2 and 4, the second contact surface 265 of the adhesive layer 261 can face and/or contact the first major surface 273 of a release liner 271 (described below). In aspects, as shown in FIG. 2, the first contact surface 263 of the adhesive layer 261 can face and/or contact the second surface area 225 of the first portion 221. In aspects, as shown in FIG. 2, the first contact surface 263 of the adhesive layer 261 can face and/or contact the fourth surface area 235 of the second portion 231. In aspects, as shown in FIG. 2, the first contact surface 263 of the adhesive layer 261 can face the second central surface area 243 of the central portion 281. In aspects, as shown in FIG. 4, the first contact surface 263 of the adhesive layer 261 can face and/or contact the first surface area 223 of the first portion 221. In aspects, as shown in FIG. 4, the first contact surface 263 of the adhesive layer 261 can face and/or contact the third surface area 233 of the second portion 231. In aspects, as shown in FIG. 4, the first contact surface 263 of the adhesive layer 261 can face the first central surface area 213 of the central portion 281. In aspects, as shown in FIG. 2, the first contact surface 263 of the adhesive layer 261 can face the second central surface area 243 of the central portion 281. In further aspects, although not shown, the first contact surface 263 of the adhesive layer 261 can contact the second central surface area 243 of the central portion 281, for example by filling the region (e.g., second recess 241) indicated as occupied by the second polymer-based portion 299 in FIG. 2. In aspects, although not shown, the second recess may not be totally filled, for example, to leave room for electronic devices and/or mechanical devices. In aspects, although not shown, the foldable substrate 201 of FIG. 4 can be configured with the adhesive layer 261 contacting the second major surface 205 rather than the first major surface 203 while the polymer-based portion 299 or a coating 251 in place of the polymer-based portion 299 can be positioned at least partially in the first recess 211.

In aspects, the adhesive layer 261 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene). In further aspects, the adhesive layer 261 can comprise an optically clear adhesive. In even further aspects, the optically clear adhesive can comprise one or more optically transparent polymers: an acrylic (e.g., polymethylmethacrylate (PMMA)), an epoxy, silicone, and/or a polyurethane. Examples of epoxies include bisphenol-based epoxy resins, novolac-based epoxies, cycloaliphatic-based epoxies, and glycidylamine-based epoxies. In even further aspects, the optically clear adhesive can comprise, but is not limited to, acrylic adhesives, for example, 3M 8212 adhesive, or an optically transparent liquid adhesive, for example, a LOCTITE optically transparent liquid adhesive. Exemplary aspects of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel.

Throughout the disclosure, a tensile strength, ultimate elongation (e.g., strain at failure), and yield point of a polymeric material (e.g., adhesive, polymer-based portion) is determined using ASTM D638 using a tensile testing machine, for example, an Instron 3400 or Instron 6800, at 23° C. and 50% relative humidity with a type I dogbone shaped sample. In aspects, the adhesive layer 261 can comprise an elastic modulus of about 0.001 MegaPascals (MPa) or more, about 0.01 MPa or more, about 0.1 MPa or more, about 1 MPa or less, about 0.5 MPa or less, about 0.1 MPa or less, or about 0.05 MPa or less. In aspects, the adhesive layer 261 can comprise an elastic modulus in a range from about 0.001 MPa to about 1 MPa, from about 0.01 MPa to about 1 MPa, from about 0.01 MPa to about 0.5 MPa, from about 0.05 MPa to about 0.5 MPa, from about 0.1 MPa to about 0.5 MPa, from about 0.001 MPa to about 0.5 MPa, from about 0.001 MPa to about 0.01 MPa, or any range or subrange therebetween. In aspects, the adhesive layer can comprise an elastic modulus within one or more of the ranges discussed below for the elastic modulus of the polymer-based portions 289 and/or 299.

As shown in FIGS. 2 and 4, the polymer-based portion 289 and/or 299 of the foldable apparatus 101 can be positioned between the first portion 221 and the second portion 231. In aspects, as shown, the polymer-based portion can comprise a first polymer-based portion 289 at least partially positioned in and/or filling the first recess 211. In aspects, as shown in FIG. 2, the polymer-based portion can comprise a second polymer-based portion 299 at least partially positioned in and/or filling the second recess 241. In aspects, as shown in FIG. 4, the polymer-based portion can comprise a second polymer-based portion 299 at least partially positioned in and/or filling the first recess 211. In aspects, although not shown, the second recess may not be totally filled, for example, to leave room for electronic devices and/or mechanical devices.

As shown in FIG. 2, the first polymer-based portion 289 can comprise a fourth contact surface 285 opposite the third contact surface 283. In aspects, as shown, the third contact surface 283 can comprise a planar surface, for example, substantially coplanar (e.g., extend along a common plane, first plane 204a) with the first surface area 223 and the third surface area 233. In aspects, as shown in FIG. 2, the fourth major surface 255 of the coating 251 can face and/or contact the third contact surface 283 of the polymer-based portion 289. In aspects, the fourth contact surface 285 can comprise a planar surface, for example, substantially coplanar (e.g., extend along a common plane, third plane 204b) with the first central surface area 213. In further aspects, the fourth contact surface 285 can contact the first central surface area 213, the first transition surface area 215, and/or the third transition surface area 217.

As shown in FIGS. 2 and 4, the second polymer-based portion 299 can comprise a fourth contact surface 295 opposite the third contact surface 293. In further aspects, as shown in FIG. 2, the third contact surface 293 can contact the second central surface area 243, the second transition surface area 245, and/or the fourth transition surface area 247. In aspects, as shown in FIG. 2, the third contact surface 293 can comprise a planar surface, for example, being substantially coplanar (e.g., extend along a common plane with the fourth plane 206b) with the second central surface area 243. In aspects, as shown in FIG. 2, the fourth contact surface 295 can comprise a planar surface, for example, being substantially coplanar (e.g., extend along a common plane with the second plane 206a) with the second surface area 225 and the fourth surface area 235.

In aspects, as shown in FIG. 4, the third contact surface 293 can contact the first central surface area 213, the first transition surface area 215, and/or the third transition surface area 217. In aspects, as shown in FIG. 4, the third contact surface 293 can comprise a planar surface, for example, being substantially coplanar (e.g., extend along a common plane with the third plane 204b) with the first central surface area 213. In aspects, as shown, the third contact surface 293 can comprise a planar surface, for example, substantially coplanar (e.g., extend along a common plane with the third plane 204b) with the first central surface area 213. In aspects, as shown in FIG. 4, the fourth contact surface 295 can be coplanar (e.g., extend along a common plane with the first plane 204a) with the first surface area 223 and the third surface area 233. In aspects, as shown in FIGS. 2 and 4, the first contact surface 263 of the adhesive layer 261 can face and/or contact the fourth contact surface 295 of the polymer-based portion 299.

In aspects, the polymer-based portion 289 and/or 299 comprises a polymer (e.g., optically transparent polymer). In further aspects, the polymer-based portion 289 and/or 299 can comprise one or more of an optically transparent: an acrylic (e.g., polymethylmethacrylate (PMMA)), an epoxy, a silicone, and/or a polyurethane. Examples of epoxies include bisphenol-based epoxy resins, novolac-based epoxies, cycloaliphatic-based epoxies, and glycidylamine-based epoxies. In further aspects, the polymer-based portion 289 and/or 299 comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene), for example, comprising one or more of polystyrene, polydichlorophosphazene, and poly(5-ethylidene-2-norbornene). In aspects, the polymer-based portion can comprise a sol-gel material. Example aspects of polyurethanes comprise thermoset polyurethanes, for example, Dispurez 102 available from Incorez and thermoplastic polyurethanes, for example, KrystalFlex PE505 available from Huntsman. In even further aspects, the second portion can comprise an ethylene acid copolymer. An exemplary aspect of an ethylene acid copolymer includes SURLYN available from Dow (e.g., Surlyn PC-2000, Surlyn 8940, Surlyn 8150). An additional exemplary aspect for the second portion comprises Eleglass w802-GL044 available from Axalta with from 1 wt % to 2 wt % cross-linker. In aspects, the polymer-based portion 289 and/or 299 can further comprise nanoparticles, for example, carbon black, carbon nanotubes, silica nanoparticles, or nanoparticles comprising a polymer. In aspects, the polymer-based portion can further comprise fibers to form a polymer-fiber composite.

In aspects, the polymer-based portion 289 and/or 299 can comprise a coefficient of thermal expansion (CTE). As used herein, a coefficient of thermal expansion is measured in accordance with ASTM E289-17 using a Picoscale Michelson Interferometer between −20° C. and 40° C. In aspects, the polymer-based portion 289 and/or 299 can comprise particles of one or more of copper oxide, beta-quartz, a tungstate, a vanadate, a pyrophosphate, and/or a nickel-titanium alloy. In aspects, the polymer-based portion 289 and/or 299 can comprise a CTE of about −20×10⁻⁷ 1/° C. or more, about −10×10⁻⁷ 1/° C. or more, about −5×10⁻⁷ 1/° C. or more, about −2×10⁻⁷ 1/° C. or more, about 10×10⁻⁷ 1/° C. or less, about 5×10⁻⁷ 1/° C. or less, about 2×10⁻⁷ 1/° C. or less, about 1×10⁻⁷ 1/° C. or less, or 0 1/° C. or less. In aspects, the polymer-based portion 289 and/or 299 can comprise a CTE in a range from about −20×10⁻⁷ 1/° C. to about 10×10⁻⁷ 1/° C., from about −20×10⁻⁷ 1/° C. to about 5×10⁻⁷ 1/° C., from about −10×10⁻⁷ 1/° C. to about −5×10⁻⁷ 1/° C., from about −10×10⁻⁷ 1/° C. to about 2×10⁻⁷ 1/° C., from about −10×10⁻⁷ 1/° C. to 0 1/° C., from about −5×10⁻⁷ 1/° C. to 0 1/° C., from about −2×10⁻⁷ 1/° C. to about 0 1/° C., or any range or subrange therebetween. By providing a polymer-based portion comprising a low (e.g., negative) coefficient of thermal expansion, warp caused by volume changes during curing of the polymer-based portion can be mitigated.

In aspects, the polymer-based portion 289 and/or 299 can comprise an elastic modulus of about 0.001 MegaPascals (MPa) or more, about 0.001 MP or more, about 1 MPa or more, about 10 MPa or more, about 20 MPa or more, about 100 MPa or more, about 200 MPa or more, about 1,000 MPa or more, about 5,000 MPa or less, about 3,000 MPa or less, about 1,000 MPa or less, about 500 MPa or less, or about 200 MPa or less. In aspects, the polymer-based portion 289 and/or 299 can comprise an elastic modulus in a range from about 0.001 MPa to about 5,000 MPa, from about 0.01 MPa to about 3,000 MPa, from about 0.01 MPa to about 1,000 MPa, from about 0.01 MPa to about 500 MPa, from about 0.01 MPa to about 200 MPa, from about 1 MPa to about 200 MPa, from about 10 MPa to about 200 MPa, from about 100 MPa to about 200 MPa, or any range or subrange therebetween. In aspects, the polymer-based portion 289 and/or 299 can comprise an elastic modulus in a range from about 1 MPa to about 5,000 MPa, from about 10 MPa to about 5,000 MPa, from about 10 MPa to about 1,000 MPa, from about 20 MPa to about 1,000 MPa, from about 20 MPa to about 200 MPa, or any range or subrange therebetween. In aspects, the elastic modulus of the polymer-based portion 289 and/or 299 can be in a range from about 1 GPa to about 20 GPa, from about 1 GPa to about 18 GPa, from about 1 GPa to about 10 GPa, from about 1 GPa to about 5 GPa, from about 1 GPa to about 3 GPa, or any range or subrange therebetween. By providing a polymer-based portion 289 and/or 299 with an elastic modulus in a range from about 0.001 MPa to about 5,000 MPa (e.g., in a range from about 10 MPa to about 3 GPa), folding of the foldable apparatus without failure can be facilitated. In aspects, the adhesive layer 261 comprises an elastic modulus greater than the elastic modulus of the polymer-based portion 289 and/or 299, which arrangement provides improved performance in puncture resistance. In aspects, the elastic modulus of the polymer-based portion 289 and/or 299 can be less than the elastic modulus of the foldable substrate 201. In aspects, the adhesive layer 261 may comprise an elastic modulus within the ranges listed above in this paragraph. In further aspects, the adhesive layer 261 may comprise substantially the same elastic modulus as the elastic modulus of the polymer-based portion 289 and/or 299. In further aspects, the elastic modulus of the adhesive layer 261 can be in a range from about 1 GPa to about 20 GPa, from about 1 GPa to about 18 GPa, from about 1 GPa to about 10 GPa, from about 1 GPa to about 5 GPa, from about 1 GPa to about 3 GPa, or any range or subrange therebetween. In aspects, the elastic modulus of the polymer-based portion 289 and/or 299 can be less than the elastic modulus of the foldable substrate 201.

In aspects, as shown in FIG. 2, a coating 251 can be disposed over the first major surface 203 of the foldable substrate 201. In further aspects, the coating 251 can be disposed over the first portion 221, the second portion 231, and the central portion 281. In aspects, the coating 251 can comprise a third major surface 253 and a fourth major surface 255 opposite the third major surface 253. In further aspects, the coating 251 (e.g., fourth major surface 255) can contact the foldable substrate 201 (e.g., first major surface 203). In further aspects, at least a part of the coating 251 can be positioned in the first recess 211. In even further aspects, the coating 251 can fill the first recess 211. In further aspects, the coating 251 can comprise a coating thickness 257 defined between the third major surface 253 and the fourth major surface 255. In further aspects, the coating thickness 257 can be about 0.1 μm or more, about 1 μm or more, about 5 μm or more, about 10 μm or more, about 15 μm or more, about 20 μm or more, about 25 μm or more, about 40 μm or more, about 50 μm or more, about 60 μm or more, about 70 μm or more, about 80 μm or more, about 90 μm or more, about 200 μm or less, about 100 μm or less, or about 50 μm or less, about 30 μm or less, about 25 μm or less, about 20 μm or less, about 20 μm or less, about 15 μm or less, or about 10 μm or less. In aspects, the coating thickness 257 can be in a range from about 0.1 μm to about 200 μm, from about 1 μm to about 200 μm, from about 10 μm to about 200 μm, from about 50 μm to about 200 μm, from about 0.1 μm to about 100 μm, from about 1 μm to about 100 μm, from about 10 μm to about 100 μm, from about 20 μm to about 100 μm, from about 30 μm to about 100 μm, from about 40 μm to about 100 μm, from about 50 μm to about 100 μm, from about 60 μm to about 100 μm, from about 70 μm to about 100 μm, from about 80 μm to about 100 μm, from about 90 μm to about 100 μm, from about 0.1 μm to about 50 μm, from about 1 μm to about 50 μm, from about 10 μm to about 50 μm, or any range or subrange therebetween. In further aspects, the coating thickness 257 can be in a range from about 0.1 μm to about 50 μm, from about 0.1 μm to about 30 μm, from about 0.1 μm to about 25 μm, from about 0.1 μm to about 20 μm, from about 0.1 μm to about 15 μm, from about 0.1 μm to about 10 μm, from about 1 μm to about 30 μm, from about 1 μm to about 25 μm, from about 1 μm to about 20 μm, from about 1 μm to about 15 μm, from about 1 μm to about 10 μm, from about 5 μm to about 30 μm, from about 5 μm to about 25 μm, from about 5 μm to about 20 μm, from about 5 μm to about 15 μm, from about 5 μm to about 10 μm, from about 10 μm to about 30 μm, from about 10 μm to about 25 μm, from about 10 μm to about 20 μm, from about 10 μm to about 15 μm, from about 15 μm to about 30 μm, from about 15 μm to about 25 μm, from about 15 μm to about 20 μm, from about 20 μm to about 30 μm, from about 20 μm to about 25 μm, or any range or subrange therebetween.

In aspects, the coating 251 can comprise a polymeric hard coating. In further aspects, the polymeric hard coating can comprise one or more of an ethylene-acid copolymer, a polyurethane-based polymer, an acrylate resin, and a mercapto-ester resin. Example aspects of ethylene-acid copolymers include ethylene-acrylic acid copolymers, ethylene-methacrylic acid copolymers, and ethylene-acrylic-methacrylic acid terpolymers (e.g., Nucrel, manufactured by DuPont), ionomers of ethylene acid copolymers (e.g., Surlyn, manufactured by DuPont), and ethylene-acrylic acid copolymer amine dispersions (e.g., Aquacer, manufactured by BYK). Example aspects of polyurethane-based polymers include aqueous modified polyurethane dispersions (e.g., Eleglas®, manufactured by Axalta). Example aspects of acrylate resins that can be UV curable include acrylate resins (e.g., Uvekol® resin, manufactured by Allinex), cyanoacrylate adhesives (e.g., Permabond® UV620, manufactured by Krayden), and UV radical acrylic resins (e.g., Ultrabond windshield repair resin, for example, Ultrabond (45CPS)). Example aspects of mercapto-ester resins include mercapto-ester triallyl isocyanurates (e.g., Norland optical adhesive NOA 61). In further aspects, the polymeric hard coating can comprise ethylene-acrylic acid copolymers and ethylene-methacrylic acid copolymers, which may be ionomerized to form ionomer resins through neutralization of the carboxylic acid residue with typically alkali-metal ions, for example, sodium and potassium, and also zinc. Such ethylene-acrylic acid and ethylene-methacrylic acid ionomers may be dispersed in water and coated onto the substrate to form an ionomer coating. Alternatively, such acid copolymers may be neutralized with ammonia which, after coating and drying liberates the ammonia to reform the acid copolymer as the coating. By providing a coating comprising a polymeric coating, the foldable apparatus can comprise low energy fracture.

In aspects, the coating can comprise a polymeric hard coating comprising an optically transparent polymeric hard-coat layer. Suitable materials for an optically transparent polymeric hard-coat layer include but are not limited to a cured acrylate resin material, an inorganic-organic hybrid polymeric material, an aliphatic or aromatic hexafunctional urethane acrylate, a siloxane-based hybrid material, and a nanocomposite material, for example, an epoxy and urethane material with nanosilicate. In aspects, an optically transparent polymeric hard-coat layer may consist essentially of one or more of these materials. In aspects, an optically transparent polymeric hard-coat layer may consist of one or more of these materials. As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. More specifically, suitable materials for an optically transparent polymeric (OTP) hard-coat layer include, but are not limited to, a polyimide, a polyethylene terephthalate (PET), a polycarbonate (PC), a poly methyl methacrylate (PMMA), organic polymer materials, inorganic-organic hybrid polymeric materials, and aliphatic or aromatic hexafunctional urethane acrylates. In aspects, an OTP hard-coat layer may consist essentially of an organic polymer material, an inorganic-organic hybrid polymeric material, or aliphatic or aromatic hexafunctional urethane acrylate. In aspects, an OTP hard-coat layer may consist of a polyimide, an organic polymer material, an inorganic-organic hybrid polymeric material, or aliphatic or aromatic hexafunctional urethane acrylate. In aspects, an OTP hard-coat layer may include a nanocomposite material. In aspects, an OTP hard-coat layer may include a nano-silicate at least one of epoxy and urethane materials. Suitable compositions for such an OTP hard-coat layer are described in U.S. Pat. Pub. No. 2015/0110990, which is hereby incorporated by reference in its entirety by reference thereto. As used herein, “organic polymer material” means a polymeric material comprising monomers with only organic components. In aspects, an OTP hard-coat layer may comprise an organic polymer material manufactured by Gunze Limited and having a hardness of 9H, for example Gunze's “Highly Durable Transparent Film.” As used herein, “inorganic-organic hybrid polymeric material” means a polymeric material comprising monomers with inorganic and organic components. An inorganic-organic hybrid polymer is obtained by a polymerization reaction between monomers having an inorganic group and an organic group. An inorganic-organic hybrid polymer is not a nanocomposite material comprising separate inorganic and organic constituents or phases, for example, inorganic particulates dispersed within an organic matrix. In aspects, the inorganic-organic hybrid polymeric material may include polymerized monomers comprising an inorganic silicon-based group, for example, a silsesquioxane polymer. A silsesquioxane polymer may be, for example, an alkyl-silsesquioxane, an aryl-silsesquioxane, or an aryl alkyl-silsesquioxane having the following chemical structure: (RSiO_{1.5})ₙ, where R is an organic group for example, but not limited to, methyl or phenyl. In aspects, an OTP hard-coat layer may comprise a silsesquioxane polymer combined with an organic matrix, for example, SILPLUS manufactured by Nippon Steel Chemical Co., Ltd. In aspects, an OTP hard-coat layer may comprise 90 wt % to 95 wt % aromatic hexafunctional urethane acrylate (e.g., PU662NT (Aromatic hexafunctional urethane acrylate) manufactured by Miwon Specialty Chemical Co.) and 10 wt % to 5 wt % photo-initiator (e.g., Darocur 1173 manufactured by Ciba Specialty Chemicals Corporation) with a hardness of 8H or more. In aspects, an OTP hard-coat layer composed of an aliphatic or aromatic hexafunctional urethane acrylate may be formed as a stand-alone layer by spin-coating the layer on a polyethylene terephthalate (PET) substrate, curing the urethane acrylate, and removing the urethane acrylate layer from the PET substrate. In aspects, an OTP hard-coat layer may be an aliphatic or aromatic hexafunctional urethane acrylate material layer having a thickness within one or more of the thickness ranges discussed above for the coating thickness 257.

In aspects, the coating 251, if provided, may also comprise one or more of an easy-to-clean coating, a low-friction coating, an oleophobic coating, a diamond-like coating, a scratch-resistant coating, or an abrasion-resistant coating. A scratch-resistant coating may comprise an oxynitride, for example, aluminum oxynitride or silicon oxynitride with a thickness of about 500 micrometers or more. In such aspects, the abrasion-resistant layer may comprise the same material as the scratch-resistant layer. In aspects, a low friction coating may comprise a highly fluorinated silane coupling agent, for example, an alkyl fluorosilane with oxymethyl groups pendant on the silicon atom. In such aspects, an easy-to-clean coating may comprise the same material as the low friction coating. In other aspects, the easy-to-clean coating may comprise a protonatable group, for example an amine, for example, an alkyl aminosilane with oxymethyl groups pendant on the silicon atom. In such aspects, the oleophobic coating may comprise the same material as the easy-to-clean coating. In aspects, a diamond-like coating comprises carbon and may be created by applying a high voltage potential in the presence of a hydrocarbon plasma.

Providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials (e.g., coating 251, first polymer-based portion 289) can be positioned in the first recess, which can improve impact resistance, puncture resistance, abrasion resistance, and/or scratch resistance of the foldable apparatus. Additionally, controlling properties of a first material (e.g., coating 251, first polymer-based portion 289) positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure. Providing a first recess opposite a second recess can reduce the strain encountered by the polymer-based portion or other material (e.g., adhesive layer) in the recess (e.g., from 0% to 50% reduction). Consequently, requirements for a strain at yield of the polymer-based portion can be relaxed. In aspects, a strain at yield of the polymer-based portion and/or adhesive layer can be about 3% or more, about 4% or more, about 5% or more, about 6% or more, about 7% or more, about 500% or less, about 100% or less, about 50% or less, about 20% or less, about 15% or less, about 10% or less, about 9% or less, or about 8% or less. In aspects, the strain at yield of the polymer-based portion and/or adhesive layer can be in a range from about 1% to about 500%, from about 1% to about 100%, from about 2% to about 100%, from about 2% to about 50%, from about 3% to about 50%, from about 3% to about 20%, from about 4% to about 20%, from about 4% to about 15%, from about 5% to about 15%, from about 5% to about 10%, from about 5% to about 9%, from about 6% to about 9%, from about 6% to about 8%, from about 7% to about 8% or any range or subrange therebetween.

In aspects, as shown in FIGS. 2 and 4, the foldable apparatus 101 can comprise the release liner 271 although other substrates (e.g., glass-based substrate and/or ceramic-based substrate discussed throughout the application) may be used in further aspects rather than the illustrated release liner 271. In further aspects, as shown, the release liner 271, or another substrate, can be disposed over the adhesive layer 261. In even further aspects, as shown, the release liner 271, or another substrate, can directly contact the second contact surface 265 of the adhesive layer 261. The release liner 271, or another substrate, can comprise a first major surface 273 and a second major surface 275 opposite the first major surface 273. As shown, the release liner 271, or another substrate, can be disposed on the adhesive layer 261 by attaching the second contact surface 265 of the adhesive layer 261 to the first major surface 273 of the release liner 271, or another substrate. In aspects, as shown, the first major surface 273 of the release liner 271, or another substrate, can comprise a planar surface. In aspects, as shown, the second major surface 275 of the release liner 271, or another substrate, can comprise a planar surface. A substrate comprising the release liner 271 can comprise a paper and/or a polymer. Exemplary aspects of paper comprise kraft paper, machine-finished paper, poly-coated paper (e.g., polymer-coated, glassine paper, siliconized paper), or clay-coated paper. Exemplary aspects of polymers comprise polyesters (e.g., polyethylene terephthalate (PET)) and polyolefins (e.g., low-density polyethylene (LDPE), high-density polyethylene (HDPE), polypropylene (PP)).

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of a portion of the housing or the cover substrate comprises the foldable apparatus discussed throughout the disclosure. The consumer electronic product can comprise a portable electronic device, for example, a smartphone, a tablet, a wearable device, or a laptop.

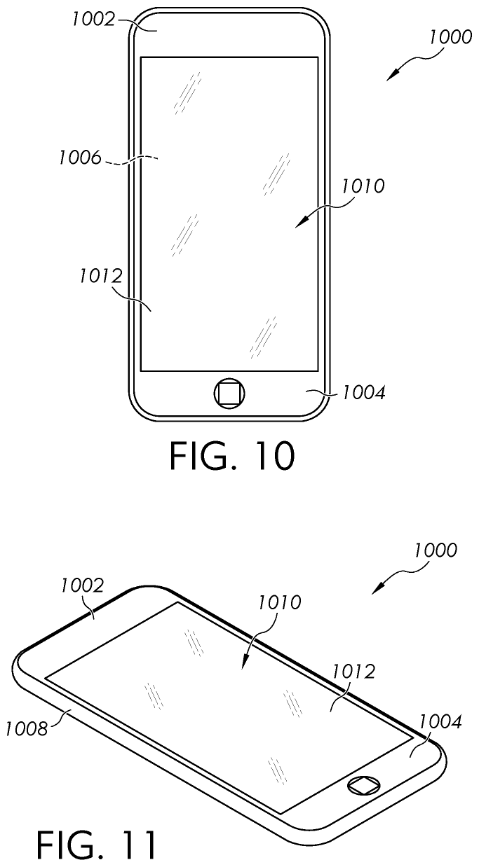

The foldable apparatus disclosed herein may be incorporated into another article, for example, an article with a display (or display articles) (e.g., consumer electronics, including mobile phones, tablets, computers, navigation systems, wearable devices (e.g., watches), and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the foldable apparatus disclosed herein is shown in FIGS. 10-11. Specifically, FIGS. 10-11 show a consumer electronic device 1000 including a housing 1002 having front 1004, back 1006, and side surfaces 1008. Although not shown, the consumer electronic device can comprise electrical components that are at least partially inside or entirely within the housing. For example, electrical components include at least a controller, a memory, and a display. As shown in FIGS. 10-11, the display 1010 can be at or adjacent to the front surface of the housing 1002. The consumer electronic device can comprise a cover substrate 1012 at or over the front surface of the housing 1002 such that it is over the display 1010. In aspects, at least one of the cover substrate 1012 or a portion of housing 1002 may include any of the foldable apparatus disclosed herein, for example, the foldable substrate.

In aspects, the foldable substrate 201 comprising a glass-based substrate and/or a ceramic-based substrate, and the first portion 221, the second portion 231, and/or the central portion 281 can comprise one or more compressive stress regions. In aspects, a compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first portion 221, the second portion 231, and/or the central portion 281 can enable good impact and/or puncture resistance (e.g., resists failure for a pen drop height of about 15 centimeters (cm) or more, about 20 cm or more, about 50 cm or more). Without wishing to be bound by theory, chemically strengthening the first portion 221, the second portion 231, and/or the central portion 281 can enable small (e.g., smaller than about 10 mm or less) bend radii because the compressive stress from the chemical strengthening can counteract the bend-induced tensile stress on the outermost surface of the substrate. A compressive stress region may extend into a portion of the first portion and/or the second portion for a depth called the depth of compression (DOC). As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate and/or portion (e.g., sodium, potassium). Throughout the disclosure, DOL is measured in accordance with ASTM C-1422. Without wishing to be bound by theory, a DOL is usually greater than or equal to the corresponding DOC. Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the first portion 221 comprising the glass-based portion and/or ceramic-based portion may comprise a first compressive stress region at the first surface area 223 that can extend to a first depth of compression from the first surface area 223. In aspects, the first portion 221 comprising a first glass-based and/or ceramic-based portion may comprise a second compressive stress region at the second surface area 225 that can extend to a second depth of compression from the second surface area 225. In aspects, the first depth of compression and/or the second depth of compression as a percentage of the substrate thickness 207 can be about 5% or more, about 10% or more, about 12% or more, about 15% or more, about 30% or less, about 25% or less, about 22% or less, about 20% or less, about 17% or less, or about 15% or less. In aspects, the first depth of compression and/or the second depth of compression as a percentage of the substrate thickness 207 can be in a range from about 5% to about 30%, from about 10% to about 25%, from about 10% to about 22%, from about 12% to about 20%, from about 12% to about 17%, from about 15% to about 17%, or any range or subrange therebetween. In aspects, the first depth of compression and/or the second depth of compression can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of compression and/or the second depth of compression can be in a range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween. By providing a first portion comprising a first glass-based and/or ceramic-based portion comprising a first depth of compression and/or a second depth of compression in a range from about 1% to about 30% of the first thickness, good impact and/or puncture resistance can be enabled.

In aspects, the first compressive stress region can comprise a maximum first compressive stress. In aspects, the second compressive stress region can comprise a maximum second compressive stress. In further aspects, the maximum first compressive stress and/or the maximum second compressive stress can be about 100 MegaPascals (MPa) or more, about 300 MPa or more, 400 MPa or more, about 500 MPa or more, about 600 MPa or more, about 700 MPa or more, about 1,500 MPa or less, about 1,200 MPa or less, about 1,000 MPa or less, or about 800 MPa or less. In further aspects, the maximum first compressive stress and/or the maximum second compressive stress can be in a range from about 100 MPa to about 1,500 MPa, from about 100 MPa to about 1,200 MPa, from about 300 MPa to about 1,200 MPa, from about 300 MPa to about 1,000 MPa, from about 400 MPa to about 1,000 MPa, from about 500 MPa to about 1,000 MPa, from about 600 MPa to about 900 MPa, from about 700 MPa to about 800 MPa, or any range or subrange therebetween. By providing a maximum first compressive stress and/or a maximum second compressive stress in a range from about 100 MPa to about 1,500 MPa, good impact and/or puncture resistance can be enabled.

In aspects, the first portion 221 can comprise a first depth of layer of one or more alkali-metal ions associated with the first compressive stress region. In aspects, the first portion 221 can comprise a second depth of layer of one or more alkali-metal ions associated with the second compressive stress region and the second depth of compression. As used herein, the one or more alkali-metal ions of a depth of layer of one or more alkali-metal ions can include sodium, potassium, rubidium, cesium, and/or francium. In aspects, the one or more alkali ions of the first depth of layer of the one or more alkali ions and/or the second depth of layer of the one or more alkali ions comprises potassium. In aspects, the first depth of layer and/or the second depth of layer as a percentage of the substrate thickness 207 can be about 5% or more, about 10% or more, about 12% or more, about 15% or more, about 30% or less, about 25% or less, about 22% or less, about 20% or less, about 17% or less, or about 15% or less. In aspects, the first depth of layer and/or the second depth of layer as a percentage of the substrate thickness 207 can be in a range from about 5% to about 30%, from about 10% to about 25%, from about 10% to about 22%, from about 12% to about 20%, from about 12% to about 17%, from about 15% to about 17%, or any range or subrange therebetween. In aspects, the first depth of layer of the one or more alkali-metal ions and/or the second depth of layer of the one or more alkali-metal ions can be about 1 μm or more, about 10 μm or more, about 15 μm or more, about 20 μm or more, about 25 μm or more, about 30 μm or more, about 200 μm or less, about 150 μm or less, about 100 μm or less, about 60 μm or less, about 45 μm or less, about 30 μm or less, or about 20 μm or less. In aspects, the first depth of layer of the one or more alkali-metal ions and/or the second depth of layer of the one or more alkali-metal ions can be in a range from about 1 μm to about 200 μm, from about 1 μm to about 150 μm, from about 10 μm to about 100 μm, from about 15 μm to about 600 μm, from about 20 μm to about 45 μm, from about 20 μm to about 30 μm, or any range or subrange therebetween.

In aspects, the first portion 221 may comprise a first tensile stress region. In aspects, the first tensile stress region can be positioned between the first compressive stress region and the second compressive stress region. In aspects, the first tensile stress region can comprise a maximum first tensile stress. In further aspects, the maximum first tensile stress can be about 10 MPa or more, about 20 MPa or more, about 30 MPa or more, about 100 MPa or less, about 80 MPa or less, or about 60 MPa or less. In further aspects, the maximum first tensile stress can be in a range from about 10 MPa to about 100 MPa, from about 10 MPa to about 80 MPa, from about 10 MPa to about 60 MPa, from about 20 MPa to about 100 MPa, from about 20 MPa to about 80 MPa, from about 20 MPa to about 60 MPa, from about 30 MPa to about 100 MPa, from about 30 MPa to about 80 MPa, from about 30 MPa to about 60 MPa, or any range or subrange therebetween. Providing a maximum first tensile stress in a range from about 10 MPa to about 100 MPa can enable good impact and/or puncture resistance while providing low energy fractures, as discussed below.

In aspects, the second portion 231 comprising a second glass-based and/or ceramic-based portion may comprise a third compressive stress region at the third surface area 233 that can extend to a third depth of compression from the third surface area 233. In aspects, the second portion 231 comprising a second glass-based and/or ceramic-based portion may comprise a fourth compressive stress region at the fourth surface area 235 that can extend to a fourth depth of compression from the fourth surface area 235. In aspects, the third depth of compression and/or the fourth depth of compression as a percentage of the substrate thickness 207 can be within one or more of the ranges discussed above for the first depth of compression and/or the second depth of compression. In further aspects, the third depth of compression can be substantially equal to the fourth depth of compression. In aspects, the third depth of compression and/or the fourth depth of compression can be within one or more of the ranges discussed above for the first depth of compression and/or the second depth of compression. By providing a second portion comprising a glass-based and/or ceramic-based portion comprising a third depth of compression and/or a fourth depth of compression in a range from about 1% to about 30% of the substrate thickness, good impact and/or puncture resistance can be enabled.

In aspects, the third compressive stress region can comprise a maximum third compressive stress. In aspects, the fourth compressive stress region can comprise a maximum fourth compressive stress. In further aspects, the maximum third compressive stress and/or the maximum fourth compressive stress can be within one or more of the ranges discussed above for the maximum first compressive stress and/or the maximum second compressive stress. By providing a maximum third compressive stress and/or a maximum fourth compressive stress in a range from about 100 MPa to about 1,500 MPa, good impact and/or puncture resistance can be enabled.

In aspects, the second portion 231 can comprise a third depth of layer of one or more alkali-metal ions associated with the third compressive stress region and the third depth of compression. In aspects, the second portion 231 can comprise a fourth depth of layer of one or more alkali-metal ions associated with the fourth compressive stress region and the fourth depth of compression. In aspects, the one or more alkali ions of the third depth of layer of the one or more alkali ions and/or the fourth depth of layer of the one or more alkali ions comprises potassium. In aspects, the third depth of layer and/or the fourth depth of layer as a percentage of the substrate thickness 207 can be within one or more of the ranges discussed above for the first depth of layer and/or the second depth of layer as a percentage of the substrate thickness 207. In aspects, the third depth of layer of the one or more alkali-metal ions and/or the fourth depth of layer of the one or more alkali-metal ions can be the first depth of layer and/or the second depth of layer.

In aspects, the second portion 231 may comprise a second tensile stress region. In aspects, the second tensile stress region can be positioned between the third compressive stress region and the fourth compressive stress region. In aspects, the second tensile stress region can comprise a maximum second tensile stress. In further aspects, the maximum second tensile stress can be within one or more of the ranges discussed above for the maximum first tensile stress. In aspects, the maximum first tensile stress can be substantially equal to the maximum second tensile stress. Providing a maximum second tensile stress in a range from about 10 MPa to about 100 MPa can enable good impact and/or puncture resistance while providing low energy fractures, as discussed below.

In aspects, the first depth of compression can be substantially equal to the third depth of compression. In aspects, the second depth of compression can be substantially equal to the fourth depth of compression. In aspects, the maximum first compressive stress can be substantially equal to the maximum third compressive stress. In aspects, the maximum second compressive stress can be substantially equal to the maximum fourth compressive stress. In aspects, the first depth of layer of one or more alkali-metal ions can be substantially equal to the third depth of layer of one or more alkali-metal ions. In aspects, the second depth of layer of one or more alkali-metal ions can be substantially equal to the fourth depth of layer of one or more alkali-metal ions.

In aspects, the central portion 281 can comprise a first central compressive stress region at the first central surface area 213 that can extend to a first central depth of compression from the first central surface area 213. In aspects, the central portion 281 can comprise a second central compressive stress region at the second central surface area 243 that can extend to a second central depth of compression from the second central surface area 243. In further aspects, the first central compressive stress region and/or the second compressive stress region can be within the central region 248 of the central portion 281 (e.g., coextensive with the first central surface area 213 and/or the second central surface area 243). In further aspects, the first central depth of compression and/or the second central depth of compression as a percentage of the central thickness 209 can be within one or more of the ranges discussed above for the first depth of compression and/or the second depth of compression as a percentage of the substrate thickness 207. In further aspects, the first central depth of compression and/or the second central depth of compression as a percentage of the central thickness 209 can be about 1% or more, about 2% or more, about 5% or more, about 8% or more, about 10% or more, about 12% or more, about 20% or less, about 17% or less, about 15% or less, about 12% or less, about 10% or less, about 7% or less, or about 5% or less. For example, the first central depth of compression and/or the second central depth of compression as a percentage of the central thickness 209 can be in a range from about 1% to about 20%, from about 2% to about 17%, from about 5% to about 15%, from about 7% to about 10%, or any range or subrange therebetween. In further aspects, the first central depth of compression can be substantially equal to the second central depth of compression. In further aspects, the first central depth of compression and/or the second central depth of compression can be within one or more of the ranges discussed above for the first depth of compression and/or the second depth of compression. In further aspects, the first central depth of compression and/or the second central depth of compression can be about 1 μm or more about 2 μm or more, about 4 μm or more, about 6 μm or more, about 20 μm or less, about 15 μm or less, about 10 μm or less, or about 8 μm or less. For example, the first central depth of compression and/or the second central depth of compression can be in a range from about 1 μm to about 20 μm, from about 2 μm to about 15 μm, from about 4 μm to about 10 μm, from about 6 μm to about 8 μm, or any range or subrange therebetween. By providing a central portion comprising a glass-based and/or ceramic-based portion comprising a first central depth of compression and/or a second central depth of compression in a range from about 1% to about 30% (e.g., from about 1% to about 20%) of the central thickness, good impact and/or puncture resistance can be enabled.

In aspects, the first central compressive stress region can comprise a maximum first central compressive stress. In aspects, the second central compressive stress region can comprise a maximum second central compressive stress. In further aspects, the maximum first central compressive stress and/or the maximum second central compressive stress can be within one or more of the ranges discussed above for the maximum first compressive stress and/or the maximum second compressive stress. By providing a maximum first central compressive stress and/or a maximum second central compressive stress in a range from about 100 MPa to about 1,500 MPa, good impact and/or puncture resistance can be enabled.

In aspects, the central portion 281 can comprise a first central depth of layer of one or more alkali-metal ions associated with the first central compressive stress region and the first central depth of compression. In aspects, the central portion 281 can comprise a second central depth of layer of one or more alkali-metal ions associated with the second central compressive stress region and the second central depth of compression. In aspects, the one or more alkali ions of the first central depth of layer of the one or more alkali ions and/or the second central depth of layer of the one or more alkali ions comprises potassium. In aspects, the first central depth of layer and/or the second central depth of layer as a percentage of the central thickness 209 can be within one or more of the ranges discussed above for the first depth of layer and/or the second depth of layer as a percentage of the substrate thickness 207.

In aspects, the first central depth of layer and/or the second central depth of layer as a percentage of the central thickness 209 can be about 1% or more, about 2% or more, about 5% or more, about 8% or more, about 10% or more, about 12% or more, about 20% or less, about 17% or less, about 15% or less, about 12% or less, about 10% or less, about 7% or less, or about 5% or less. For example, the first central depth of layer and/or the second central depth of layer as a percentage of the central thickness 209 can be in a range from about 1% to about 20%, from about 2% to about 17%, from about 5% to about 15%, from about 7% to about 10%, or any range or subrange therebetween. In further aspects, the first central depth of layer can be substantially equal to the second central depth of layer. In further aspects, the first central depth of layer and/or the second central depth of layer can be within one or more of the ranges discussed above for the first depth of layer and/or the second depth of layer. In further aspects, the first central depth of layer and/or the second central depth of layer can be about 1 μm or more about 2 μm or more, about 4 μm or more, about 6 μm or more, about 20 μm or less, about 15 μm or less, about 10 μm or less, or about 8 μm or less. For example, the first central depth of layer and/or the second central depth of layer can be in a range from about 1 μm to about 20 μm, from about 2 μm to about 15 μm, from about 4 μm to about 10 μm, from about 6 μm to about 8 μm, or any range or subrange therebetween.

In aspects, the central portion 281 may comprise a central tensile stress region. In aspects, the central tensile stress region can be positioned between the first central compressive stress region and the second central compressive stress region. In aspects, the central tensile stress region can comprise a maximum central tensile stress. In further aspects, the maximum central tensile stress can be about 125 MPa or more, about 150 MPa or more, about 200 MPa or more, about 375 MPa or less, about 300 MPa or less, or about 250 MPa or less. In further aspects, the maximum central tensile stress can be in a range from about 125 MPa to about 375 MPa, from about 125 MPa to about 300 MPa, from about 125 MPa to about 250 MPa, from about 150 MPa to about 375 MPa, from about 150 MPa to about 300 MPa, from about 150 MPa to about 250 MPa, from about 200 MPa to about 375 MPa, from about 200 MPa to about 300 MPa, from about 200 MPa to about 250 MPa, or any range or subrange therebetween. Providing a maximum central tensile stress in a range from about 125 MPa to about 375 MPa can enable low minimum bend radii.

In aspects, a ratio of the first depth of compression to the substrate thickness is greater than a ratio of the first central depth of compression to the central thickness. In further aspects, the ratio of the first depth of compression to the substrate thickness is greater than the ratio of the first central depth of compression to the central thickness by about 0.01 or more, about 0.015 or more, about 0.02 or more, about 0.05 or more, about 0.07 or more, about 0.10 or more, about 0.20 or less, about 0.17 or less, about 0.15 or less, about 0.12 or less, about 0.11 or less, about 0.10 or less, or about 0.08 or less. In further aspects, the ratio of the first depth of compression to the substrate thickness is greater than the ratio of the first central depth of compression to the central thickness by from about 0.01 to about 0.20, from about 0.015 to about 0.17, from about 0.015 to about 0.15, from about 0.02 to about 0.12, from about 0.05 to about 0.11 or less, from about 0.05 to about 0.08, or any range or subrange therebetween. In further aspects, the ratio of the first depth of compression to the substrate thickness is greater than the ratio of the first central depth of compression to the central thickness by from about 0.05 to about 0.22, from about 0.07 to about 0.22, from about 0.10 to about 0.22, from about 0.12 to about 0.17, from about 0.12 to about 0.15, or any range or subrange therebetween. In aspects, a ratio of the third depth of compression to the substrate thickness, a ratio of the second depth of compression to the substrate thickness, and/or a ratio of the fourth depth of compression to the substrate thickness can be within one or more of the ranges discussed above. In further aspects, a ratio of the third depth of compression to the substrate thickness, a ratio of the second depth of compression to the substrate thickness, and/or a ratio of the fourth depth of compression to the substrate thickness can be substantially equal to the ratio of the first depth of compression to the substrate thickness.

In aspects, a ratio of the first depth of layer to the substrate thickness is greater than a ratio of the first central depth of layer to the central thickness. In further aspects, the ratio of the first depth of layer to the substrate thickness is greater than the ratio of the first central depth of layer to the central thickness by about 0.001 or more, about 0.01 or more, about 0.015 or more, about 0.02 or more, about 0.05 or more, about 0.07 or more, about 0.10 or more, about 0.20 or less, about 0.17 or less, about 0.15 or less, about 0.12 or less, about 0.11 or less, or about 0.10 or less. In further aspects, the ratio of the first depth of layer to the substrate thickness is greater than the ratio of the first central depth of layer to the central thickness from about 0.001 to about 0.20, from about 0.01 to about 0.20, from about 0.01 to about 0.17, from about 0.01 to about 0.15, from about 0.015 to about 0.15, from about 0.02 to about 0.12, from about 0.05 to about 0.11 or less, from about 0.07 to about 0.11, or any range or subrange therebetween. In further aspects, the ratio of the first depth of layer to the substrate thickness is greater than the ratio of the first central depth of layer to the central thickness by about 0.05 to about 0.22, from about 0.07 to about 0.22, from about 0.10 to about 0.22, from about 0.12 to about 0.17, from about 0.12 to about 0.15, or any range or subrange therebetween. In aspects, a ratio of the third depth of layer to the substrate thickness, a ratio of the second depth of layer to the substrate thickness, and/or a ratio of the fourth depth of layer to the substrate thickness can be within one or more of the ranges discussed above. In further aspects, a ratio of the third depth of layer to the substrate thickness, a ratio of the second depth of layer to the substrate thickness, and/or a ratio of the fourth depth of layer to the substrate thickness can be substantially equal to the ratio of the first depth of layer to the substrate thickness.

Throughout the disclosure, “frangibility limit” for a given substrate thickness is defined as a maximum amount of chemical strengthening (e.g., depth of compression, depth of layer) without fracturing into five (5) or more fragments with two or more branching points in the “frangibility test.” The “frangibility test” uses a 5 centimeter (cm) (2 inches) by 5 cm (2 inches) square of material comprising the substrate thickness and the degree of chemical strengthening to be tested, where a midpoint of the first major surface is impinged with a sharp probe using a minimal amount of force. As used herein, a branching point is a location with through-cracks (i.e., extending through the substrate thickness) extend in at least three (3) different directions, for example, a line comprising a through-crack impinging the branching point and at least one more through-crack impinging the branching point. In aspects, the ratio of the first depth of compression to the substrate thickness can be less than a frangibility limit in terms of a ratio of depth of compression to the substrate thickness by about 0.05 or less, about 0.03 or less, about 0.02 or less, about 0.005 or more, or about 0.01 or more. In aspects, the ratio of the first depth of compression to the substrate thickness can be less than a frangibility limit in terms of a ratio of depth of compression to the substrate thickness can range from about 0.005 to about 0.05 or less, from about 0.005 to about 0.03 or less, from about 0.001 to about 0.02 or less, or any range or subrange therebetween. In aspects, the ratio of the first depth of layer to the substrate thickness can be less than a frangibility limit in terms of a ratio of depth of layer to the substrate thickness by about 0.05 or less, about 0.03 or less, about 0.02 or less, about 0.005 or more, or about 0.01 or more. In aspects, the ratio of the first depth of layer to the substrate thickness can be less than a frangibility limit in terms of a ratio of depth of layer to the substrate thickness can range from about 0.005 to about 0.05 or less, from about 0.005 to about 0.03 or less, from about 0.001 to about 0.02 or less, or any range or subrange therebetween. Providing a ratio of the first depth of compression to the substrate thickness and/or a ratio of the first depth of layer to the substrate thickness less than the frangibility limit (e.g., within about 0.05 or less) can enable a large difference between the corresponding ratio of the first compressive stress region and the first central compressive stress region.

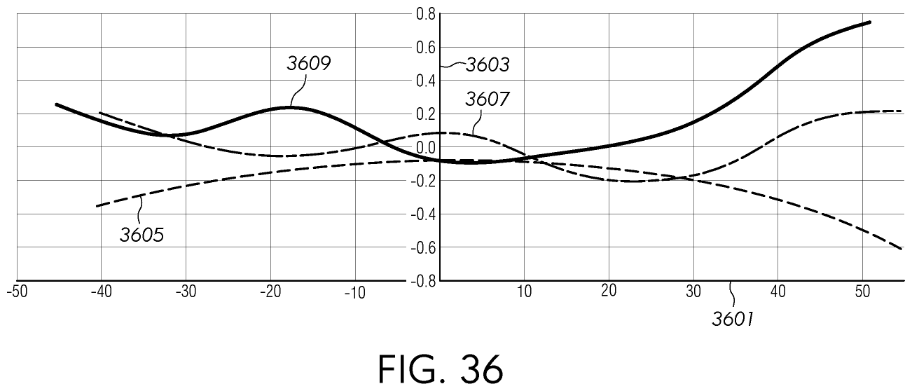

In aspects, the foldable apparatus 101, 301, 401, 501, 701, 801, and/or 901 and/or the foldable substrate 201 can be free from buckling in the central portion 281 and/or the central region 248. Throughout the disclosure, a foldable substrate and/or foldable apparatus comprises buckling when a deflectometer profile of the first central surface area taken along a centerline of the central portion equally spaced from the first portion and the second portion comprises non-parabolic shape. As used herein, the deflectometer profile is measured using a SpecGAGE3D available from Irsa Vision. For example, with reference to FIGS. 2 and 4, the fold plane 109 is shown as extending along the centerline of the central portion 281. FIG. 36 shows deflection in mm on a vertical axis 3603 as a function of distance along the centerline in mm on a horizontal axis 3601. As shown in FIG. 36, curve 3605 is substantially parabolic, which means that the foldable substrate corresponding to curve 3605 is free from buckling in the central portion. In contrast, curves 3607 and 3609 is a non-monotonic and non-parabolic since these curves change direction multiple times, which is an indication that the foldable substrates corresponding to these curves exhibit buckling.

Previously, for example, as discussed in WO 2022/046080, it was believed that if the central portion was not centered between the first major surface and the second major surface (e.g., symmetric about a plane comprising a midpoint in the substrate thickness and the central thickness), then the first central depth of compression as a percentage of the substrate thickness had to be closely matched (e.g., about 1% or less) to the first central depth of compression as a percentage of the central thickness (and/or similar relationship for the corresponding depths of layers differing by about 0.1% or less) to reduce an incidence of buckling by subjecting the central portion to less than a critical buckling strain (e.g., as a result of chemically strengthening induced expansion). Unexpectedly, as described herein, it has been determined that providing a ratio of the first depth of compression to the substrate thickness greater than a ratio of the first central depth of compression to the central thickness (even when differing by more than 0.01) can reduce an incidence of buckling whereas the same is not true for the opposite relationship. Unexpectedly, as described herein, it has been determined that providing a ratio of the first depth of layer to the substrate thickness greater than a ratio of the first central depth of layer to the central thickness (even when differing by more than 0.001) can reduce an incidence of buckling whereas the same is not true for the opposite relationship. Without wishing to be bound by theory, it is now believed that when the first portion and/or second portion undergoes a larger chemically strengthening induced expansion than the central portion, the greater linear expansion in the direction 104 (i.e. perpendicular to the cross-sections shown in FIGS. 2-4) of the first portion and/or second portion exerts a stabilizing force on the central portion (i.e., tension in the direction 104) that suppresses fluctuations in a surface profile that could otherwise lead to the onset of mechanical instabilities (e.g., buckling). As noted, it is observed that this stabilizing force can enable the central portion to withstand a critical buckling strain, where the critical buckling strain is calculated for samples comprising the material of the substrate with a uniform thickness. This is unexpected since, by definition, exceeding the critical buckling strain would be expected to lead to the onset of mechanical instabilities (e.g., buckling). Without wishing to be bound by theory, it is now believed that when the first portion and/or second portion undergoes a smaller chemically strengthening induced expansion than the central portion, the lesser linear expansion in the direction 104 of the first portion and/or second portion destabilizes the central portion by compressing the central portion (e.g., in the direction 104), which can amplify fluctuations in a surface profile that can lead to the onset of mechanical instabilities (e.g., buckling).

In aspects, the polymer-based portion 289 and/or 299 can be optically clear. The polymer-based portion 289 and/or 299 can comprise a first index of refraction. The first refractive index may be a function of a wavelength of light passing through the optically clear adhesive. For light of a first wavelength, a refractive index of a material is defined as the ratio between the speed of light in a vacuum and the speed of light in the corresponding material. Without wishing to be bound by theory, a refractive index of the optically clear adhesive can be determined using a ratio of a sine of a first angle to a sine of a second angle, where light of the first wavelength is incident from air on a surface of the optically clear adhesive at the first angle and refracts at the surface of the optically clear adhesive to propagate light within the optically clear adhesive at a second angle. The first angle and the second angle are both measured relative to a direction normal to a surface of the optically clear adhesive. As used herein, the refractive index is measured in accordance with ASTM E1967-19, where the first wavelength comprises 589 nm. In aspects, the first refractive index of the polymer-based portion 289 and/or 299 may be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, the first refractive index of the polymer-based portion 289 and/or 299 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween.

In aspects, the foldable substrate 201 can comprise a second index of refraction. In aspects, the second refractive index of the foldable substrate 201 may be about 1 or more, about 1.3 or more, about 1.4 or more, about 1.45 or more, about 1.49 or more, about 3 or less, about 2 or less, or about 1.7 or less, about 1.6 or less, or about 1.55 or less. In aspects, the second refractive index of the foldable substrate 201 can be in a range from about 1 to about 3, from about 1 to about 2 from about 1 to about 1.7, from about 1.3 to about 1.7, from about 1.4 to about 1.7, from about 1.4 to about 1.6, from about 1.45 to about 1.55, from about 1.49 to about 1.55, or any range or subrange therebetween. In aspects, a differential equal to the absolute value of the difference between the second index of refraction of the foldable substrate 201 and the first index of refraction of the polymer-based portion 289 and/or 299 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the second index of refraction of the foldable substrate 201 may be greater than the first index of refraction of the polymer-based portion 289 and/or 299. In aspects, the second index of refraction of the foldable substrate 201 may be less than the first index of refraction of the polymer-based portion 289 and/or 299.

In aspects, the adhesive layer 261 can comprise a third index of refraction. In aspects, the third index of refraction of the adhesive layer 261 can be within one or more of the ranges discussed above with regards to the first index of refraction of the polymer-based portion 289 and/or 299. In aspects, a differential equal to the absolute value of the difference between the third index of refraction of the adhesive layer 261 and the first index of refraction of the polymer-based portion 289 and/or 299 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the third index of refraction of the adhesive layer 261 may be greater than the first index of refraction of the polymer-based portion 289 and/or 299. In aspects, the third index of refraction of the adhesive layer 261 may be less than the first index of refraction of the polymer-based portion 289 and/or 299.

In aspects, a differential equal to the absolute value of the difference between the third index of refraction of the adhesive layer 261 and the second index of refraction of the foldable substrate 201 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the third index of refraction of the adhesive layer 261 may be greater than the second index of refraction of the foldable substrate 201. In aspects, the third index of refraction of the adhesive layer 261 may be less than the second index of refraction of the foldable substrate 201.

In aspects, the coating 251 can comprise a fourth index of refraction. In aspects, the fourth index of refraction of the coating 251 can be within one or more of the ranges discussed above with regards to the first index of refraction of the polymer-based portion 289 and/or 299. In aspects, a differential equal to the absolute value of the difference between the fourth index of refraction of the coating 251 and the first index of refraction of the polymer-based portion 289 and/or 299 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the fourth index of refraction of the coating 251 may be greater than the first index of refraction of the polymer-based portion 289 and/or 299. In aspects, the fourth index of refraction of the coating 251 may be less than the first index of refraction of the polymer-based portion 289 and/or 299.

In aspects, a differential equal to the absolute value of the difference between the fourth index of refraction of the coating 251 and the second index of refraction of the foldable substrate 201 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the fourth index of refraction of the coating 251 may be greater than the second index of refraction of the foldable substrate 201. In aspects, the fourth index of refraction of the coating 251 may be less than the second index of refraction of the foldable substrate 201.

In aspects, a differential equal to the absolute value of the difference between the fourth index of refraction of the coating 251 and the third index of refraction of the adhesive layer 261 can be about 0.1 or less, about 0.07 or less, about 0.05 or less, about 0.001 or more, about 0.01 or more, or about 0.02 or more. In aspects, the differential is in a range from about 0.001 to about 0.1, from about 0.001 to about 0.07, from about 0.001 to about 0.05, from about 0.01 to about 0.1, from about 0.01 to about 0.07, from about 0.01 to about 0.05, from about 0.02 to about 0.1, from about 0.02 to about 0.07, from about 0.02 to about 0.05, or any range or subrange therebetween. In aspects, the fourth index of refraction of the coating 251 may be greater than the third index of refraction of the adhesive layer 261. In aspects, the fourth index of refraction of the coating 251 may be less than the third index of refraction of the adhesive layer 261.

FIGS. 6-9 schematically illustrate aspects of a foldable apparatus 501, 701, 801, and/or 901 in accordance with aspects of the disclosure in a folded configuration. As shown in FIG. 6, the foldable apparatus 501 is folded such that the second major surface 205 of the foldable substrate 201 is on the inside of the folded foldable apparatus 501, for example, foldable apparatus 301 can be folded to form foldable apparatus 501. For example, a display could be located on the side of the second major surface 205, and a viewer would view the display from the side of the first major surface 203. Alternatively, a display could be located on the side of the first major surface 203, and a viewer would view the display from the side of the second major surface 205. As shown in FIG. 8, the foldable apparatus 801 is folded such that the second major surface 205 of the foldable substrate 201 is on the inside of the folded foldable apparatus 501. For example, a display could be located on the side of the second major surface 205, and a viewer would view the display from the side of the first major surface 203. Alternatively, a display could be located on the side of the first major surface 203, and a viewer would view the display from the side of the second major surface 205.

As shown in FIG. 7, the foldable apparatus 101 shown in FIG. 1 (modified as described in the Parallel Plate Test below) is folded to form folded foldable apparatus 701 such that the first major surface 203 of the foldable substrate 201 is on the inside of the folded foldable apparatus 701. In FIG. 7, a user would view a display device in place of the PET sheet 707 through the foldable substrate 201 and, thus, would be positioned on the side of the first major surface 203. In aspects, as shown in FIG. 7, the foldable apparatus 701 can comprise a coating 251 disposed over the foldable apparatus 701 (e.g., second major surface 205). In further aspects, a user would view a display device in place of the PET sheet 707 through the coating 251. In aspects, as shown in FIG. 7, the polymer-based portion 289 and/or 299 can be disposed over the foldable substrate 201. In further aspects, although not shown, an additional substrate (e.g., glass-based substrate and/or ceramic-based substrate in place of release liner 271 or PET sheet 707), and the additional substrate can be disposed over a display device. As shown in FIG. 9, the foldable apparatus 401 shown in FIG. 4 (modified as described in the Parallel Plate Test below) is folded to form folded foldable apparatus 901 such that the first major surface 203 of the foldable substrate 201 is on the inside of the folded foldable apparatus 901. In FIG. 9, a user would view a display device in place of the PET sheet 707 through the foldable substrate 201 and, thus, would be positioned on the side of the first major surface 203. In aspects, as shown in FIG. 9, the polymer-based portion 299 can be disposed over the foldable substrate 201 (e.g., in the first recess 211). In further aspects, although not shown, an additional substrate (e.g., glass-based substrate and/or ceramic-based substrate in place of release liner 271 or PET sheet 707), and the additional substrate can be disposed over a display device. It is to be understood that the foldable apparatus can be designed to fold such that the display device is on the inside of the bend, on the outside of the bend, or such that the foldable apparatus can be folded in either direction.

As used herein, “foldable” includes complete folding, partial folding, bending, flexing, or multiple capabilities. As used herein, the terms “fail,” “failure” and the like refer to breakage, destruction, delamination, or crack propagation. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85° C. and about 85% relative humidity.

As used herein, the “parallel plate distance” of a foldable apparatus and/or foldable substrate is measured with the following test configuration and process using a parallel plate apparatus 601 (see FIGS. 6-9) that comprises a pair of parallel rigid stainless-steel plates 603, 605 comprising a first rigid stainless-steel plate 603 and a second rigid stainless-steel plate 605. When measuring the “parallel plate distance” for the foldable substrate 201 (e.g., the foldable apparatus 301 shown in FIG. 3 consisting of foldable substrate 201), as shown in FIGS. 6 and 8, the foldable substrate 201 is placed between the pair of plates 603 and 605 such that the first major surface 203 is in contact with the pair of plates 603 and 605. When measuring the “parallel plate distance” for a foldable apparatus resembling the foldable apparatus 101 and 401 shown in FIGS. 2 and 4, respectively, the adhesive layer 261 is removed and is replaced by a test adhesive layer 709 comprises a thickness of 50 μm. Further, the test is conducted with a 100 μm thick sheet 707 of polyethylene terephthalate (PET) rather than with the release liner 271 of FIGS. 2 and 4. Thus, during the test to determine the “parallel plate distance” of a configuration of a foldable apparatus, the foldable apparatus 701 is produced by using the 100 μm thick sheet 707 of polyethylene terephthalate (PET) rather than with the release liner 271 of FIGS. 2 and 4.

When preparing the foldable apparatus 701, the 100 μm thick sheet 707 of polyethylene terephthalate (PET) is attached to the test adhesive layer 709 in an identical manner that the release liner 271 is attached to the second contact surface 265 of the adhesive layer 261 as shown in FIG. 2. To test the foldable apparatus 701 of FIG. 7, the test adhesive layer 709 and the PET sheet 707 can likewise be installed as shown in the configuration of FIG. 7 to conduct the test on the foldable apparatus 701. The foldable apparatus 701 is placed between the pair of parallel rigid stainless-steel plates 603 and 605 such that the foldable substrate 201 will be on the inside of the bend, similar to the configuration shown in FIG. 7. Similarly, when preparing the foldable apparatus 901, the foldable apparatus 401 shown in FIG. 4 is prepared for testing by replacing the adhesive layer 261 and the release liner 271 with the test adhesive layer 709 and the 100 μm thick sheet 707 of PET. For determining a “parallel plate distance”, the distance between the parallel plates is reduced at a rate of 50 μm/second until the parallel plate distance 611 or 711 is equal to the “parallel plate distance” to be tested. Then, the parallel plates are held at the “parallel plate distance” to be tested for 24 hours at about 85° C. and about 85% relative humidity. As used herein, the “minimum parallel plate distance” is the smallest parallel plate distance that the foldable apparatus can withstand without failure under the conditions and configuration described above.

In aspects, the foldable apparatus 101, 301, 401, 501, 701, 801, 901, 3801, and/or 3901 and/or foldable substrate 201 can achieve a parallel plate distance of 100 mm or less, 50 mm or less, 20 mm or less, 10 mm or less, 5 mm or less, or 3 mm or less. In further aspects, the foldable apparatus 101, 301, 401, 501, 701, 801, 901, 3801, and/or 3901 and/or foldable substrate 201 can achieve a parallel plate distance of 50 millimeters (mm), or 20 mm, or 10 mm, of 5 mm, or 3 mm. In aspects, the foldable apparatus 101, 301, 401, 501, 701, 801, 901, 3801, and/or 3901 and/or foldable substrate 201 can comprise a minimum parallel plate distance of about 40 mm or less, about 20 mm or less, about 10 mm or less, about 5 mm or less, about 3 mm or less, about 1 mm or less, about 1 mm or more, about 3 mm or more, about 5 mm or more, or about 10 mm or more. In aspects, the foldable apparatus 101, 301, 401, 501, 701, 801, 901, 3801, and/or 3901 and/or foldable substrate 201 can comprise a minimum parallel plate distance in a range from about 1 mm to about 40 mm, from about 1 mm to about 20 mm, from about 1 mm to about 10 mm, from about 1 mm to about 5 mm, from about 1 mm to about 3 mm. In aspects, the foldable apparatus 101, 301, 401, 501, 701, 801, 901, 3801, and/or 3901 and/or foldable substrate 201 can achieve a minimum parallel plate distance in a range from about 2 mm to about 40 mm, from about 2 mm to about 20 mm, from about 2 mm to about 10 mm, from about 3 mm to about 10 mm, from about 3 mm to about 5 mm, from about 5 mm to about 10 mm, or any range or subrange therebetween.

A central width 287 of the central portion 281 of the foldable substrate 201 is defined between the first portion 221 and the second portion 231 in the direction 106 of the length 105. In aspects, the central width 287 of the central portion 281 of the foldable substrate 201 can extend from the first portion 221 to the second portion 231. A width 210 of the first central surface area 213 and the second central surface area 243 of the foldable substrate 201 is defined between the first transition region 212 and the second transition region 218, for example, as the portion comprising the central thickness 209, in the direction 106 of the length 105. In aspects, the central width 287 of the central portion 281 of the foldable substrate 201 and/or the width 210 of the first central surface area 213 of the foldable substrate 201 can be about 1.4 times or more, about 1.6 times or more, about 2 times or more, about 2.2 times or more, about 3 times or less, or about 2.5 times or less the minimum parallel plate distance. In aspects, the central width 287 of the central portion 281 of the foldable substrate 201 and/or the width 210 of the first central surface area 213 of the foldable substrate 201 as a multiple of the minimum parallel plate distance can be in a range from about 1.4 times to about 3 times, from about 1.6 times to about 3 times, from about 1.6 times to about 2.5 times, from about 2 times to about 2.5 times, from about 2.2 times to about 2.5 times, from about 2.2 times to about 3 times, or any range or subrange therebetween. Without wishing to be bound by theory, the length of a bent portion in a circular configuration between parallel plates can be about 1.6 times the parallel plate distance 611 or 711. Without wishing to be bound by theory, the length of a bend portion in an elliptical configuration between parallel plates can be about 2.2 times the parallel plate distance 611 or 711. In aspects, the central width 287 of the central portion 281 of the foldable substrate 201 and/or the width 210 of the first central surface area 213 of the foldable substrate 201 can be about 1 mm or more, about 3 mm or more, about 5 mm or more, about 8 mm or more, about 10 mm or more, about 15 mm or more, about 20 mm or more, about 100 mm or less, about 60 mm or less, about 50 mm or less, about 40 mm or less, about 35 mm or less, about 30 mm or less, or about 25 mm or less. In aspects, the central width 287 of the central portion 281 of the foldable substrate 201 and/or the width 210 of the first central surface area 213 of the foldable substrate 201 can be in a range from about 1 mm to about 100 mm, from about 3 mm to about 100 mm, from about 3 mm to about 60 mm, from about 5 mm to about 60 mm, from about 5 mm to about 50 mm, from about 8 mm to about 50 mm, from about 8 mm to about 40 mm, from about 10 mm to about 40 mm, from about 10 mm to about 35 mm, from about 15 mm to about 35 mm, from about 15 mm to about 30 mm, from about 20 mm to about 30 mm, from about 20 mm to about 25 mm, or any range of subrange therebetween. In aspects, the central width 287 of the central portion 281 of the foldable substrate 201 and/or the width 210 of the first central surface area 213 of the foldable substrate 201 can be about 2.8 mm or more, about 6 mm or more, about 9 mm or more, about 60 mm or less, about 40 mm, or less, or about 24 mm or less. In aspects, the central width 287 of the central portion 281 of the foldable substrate 201 and/or the width 210 of the first central surface area 213 of the foldable substrate 201 can be in a range from about 2.8 mm to about 60 mm, from about 2.8 mm to about 40 mm, from about 2.8 mm to about 24 mm, from about 6 mm to about 60 mm, from about 6 mm to about 40 mm, from about 6 mm to about 24 mm, from about 9 mm to about 60 mm, from about 9 mm to about 40 mm, from about 9 mm to about 24 mm, or any range of subrange therebetween. In aspects, the first central surface area 213, the central portion 281 (e.g., centerline of the central portion 281), and/or the fold plane 109 can correspond to a midpoint between opposing ends of the foldable substrate and/or the foldable apparatus in the direction 106 of the length 105. By providing a width within the above-noted ranges for the central portion (e.g., between the first portion and the second portion), folding of the foldable apparatus without failure can be facilitated.

In aspects, the central width 287 of the central portion 281 and/or the width 210 of the first central surface area 213 as a percentage of the length 105 of the foldable apparatus can be about 30% or more, about 35% or more, about 40% or more, about 45% or more, about 70% or less, about 60% or less, about 55% or less, or about 50% or less. In aspects, the central width 287 of the central portion 281 and/or the width 210 of the first central surface area 213 as a percentage of the length 105 of the foldable apparatus can range from about 30% to about 70%, from about 35% to about 60%, from about 40% to about 55%, from about 45% to about 50%, or any range or subrange therebetween. In aspects, the central width 287 of the central portion 281 and/or the width 210 of the first central surface area 213 can be about 30 mm or more, about 35 mm or more, about 40 mm or more, about 45 mm or more, about 50 mm or more, about 100 mm or less, about 80 mm or less, about 70 mm or less, or about 60 mm or less. In aspects, the central width 287 of the central portion 281 and/or the width 210 of the first central surface area 213 can range from about 30 mm to about 100 mm, from about 35 mm to about 80 mm, from about 40 mm to about 70 mm, from about 45 mm to about 60 mm, from about 50 mm to about 60 mm, or any range or subrange therebetween. In aspects, a centerline of the central portion 281 can be displaced from a midpoint between opposing ends of the foldable substrate and/or the foldable apparatus in the direction 106 of the length 105, as a percentage of the length 105, by about 5% or more, about 10% or more, about 15% or less, about 20% or more, about 40% or less, about 35% or less, or about 30% or less, for example, in a range from about 5% to about 40%, from about 10% to about 40%, from about 15% to about 35%, from about 20% to about 35, from about 20% to about 30%, or any range or subrange therebetween. Alternatively, in aspects, the first central surface area 213, the central portion 281 (e.g., centerline of the central portion 281), and/or the fold plane 109 can correspond to a midpoint between opposing ends of the foldable substrate and/or the foldable apparatus in the direction 106 of the length 105. Alternatively, in aspects, In aspects, the first central surface area 213, the central portion 281, and/or the fold plane 109 can correspond to a midpoint between opposing ends of the foldable substrate and/or the foldable apparatus in the direction 106 of the length 105.

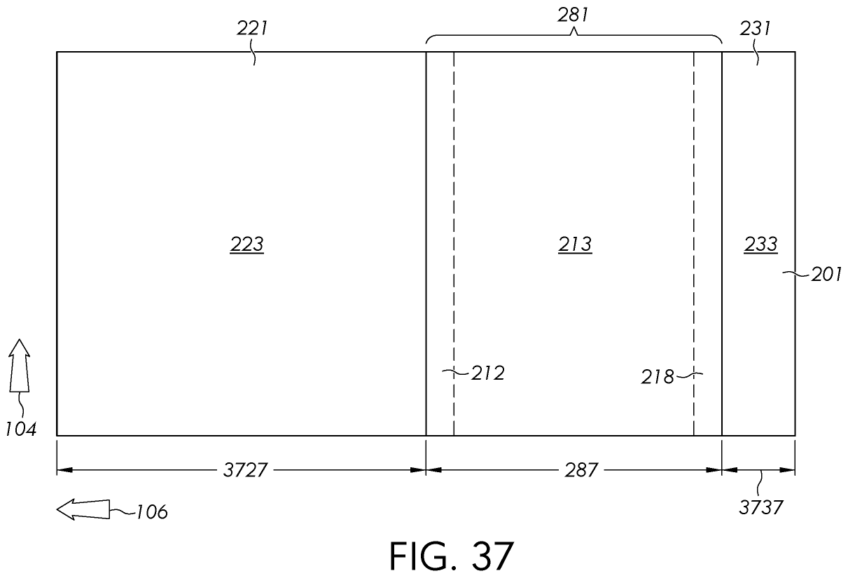

In aspects, the foldable substrate and/or the foldable apparatus can be rollable. As used herein, a foldable substrate or a foldable apparatus is “rollable” if it can achieve a threshold parallel plate distance over a length of the corresponding foldable substrate and/or foldable apparatus that is the greater of 10 mm or 10% of the length of the corresponding foldable substrate and/or foldable apparatus. For example, as shown in FIG. 37, the foldable substrate 201 is considered “rollable” when the central width 287 of the central portion 281 is greater than 10% of the length 105 (see FIG. 1) extending in the direction 106 of the length 105. In aspects, as shown in FIG. 37, the foldable substrate 201 can comprise a first width 3727, the central width 287, and a second width 3737 in the direction 106 of the length 105. A sum of the first width 3727, the central width 287, and the second width 3737 can be substantially equal to and/or equal to the length of the foldable substrate 201 (e.g., length 105 of the foldable apparatus 101 shown in FIG. 1).

In further aspects, the second width 3737, as a percentage of the length of the foldable substrate 201 and/or the foldable apparatus 101, can be about 15% or less, about 12% or less, about 10% or less, about 8% or less, about 6% or less, about 5% or less, about 4.5% or less, about 4% or less, about 1% or more, about 1.5% or more, about 2% or more, about 2.5% or more, about 3% or more, or about 3.5% or more. In further aspects, the second width 3737, as a percentage of the length of the foldable substrate 201 and/or the foldable apparatus 101, can range from about 1% to about 15%, from about 1% to about 12%, from about 1.5% to about 10%, from about 1.5% to about 8%, from about 2% to about 6%, from about 2.5% to about 5%, from about 3% to about 4.5%, from about 3.5% to about 4%, or any range or subrange therebetween. In further aspects, the second width 3737 can be about 15 mm or less, about 12 mm or less, about 10 mm or less, about 8 mm or less, about 6 mm or less, about 5 mm or less, about 4.5 mm or less, about 4 mm or less, about 1 mm or more, about 1.5 mm or more, about 2 mm or more, about 2.5 mm or more, about 3 mm or more, or about 3.5 mm or more. In further aspects, the second width 3737 can range from about 1 mm to about 15 mm, from about 1 mm to about 12 mm, from about 1.5 mm to about 10 mm, from about 1.5 mm to about 8 mm, from about 2 mm to about 6 mm, from about 2.5 mm to about 5 mm, from about 3 mm to about 4.5 mm, from about 3.5 mm to about 4 mm, or any range or subrange therebetween. Providing the second width within one or more of the ranges mentioned above in this paragraph can provide sufficient width to handling the ends of the foldable substrate during processing, to secure the foldable substrate and/or foldable apparatus as part of an electronic device, and/or to maximize an amount of the foldable substrate and/or foldable apparatus that can be part of a display portion visible to the user (e.g., as discussed below with reference to FIGS. 38-39). As used herein, a “display portion” refers to a portion of the foldable apparatus corresponding to where an image can be displayed by a display device and viewed by a viewer through the foldable substrate (e.g., rollable substrate).

In further aspects, the first width 3727, as a percentage of the length of the foldable substrate 201 and/or the foldable apparatus 101, can be 35% or more, about 40% or more, about 45% or more, about 50% or more, about 75% or less, about 70% or less, about 65% or less, about 60% or less, or about 55% or less. In further aspects, the first width 3727, as a percentage of the length of the foldable substrate 201 and/or the foldable apparatus 101, can range from about 35% to about 75%, from about 40% to about 70%, from about 45% to about 65%, from about 50% to about 60%, from about 50% to about 55%, or any range or subrange therebetween. In further aspects, the first width 3727 can be about 35 mm or more, about 40 mm or more, about 45 mm or more, about 50 mm or more, about 75 mm or less, about 70 mm or less, about 65 mm or less, about 60 mm or less, or about 55 or less. In aspects, the first width 3727 can range from about 35 mm to about 75 mm, from about 40 mm to about 70 mm, from about 45 mm to about 65 mm, from about 50 mm to about 60 mm, from about 50 mm to about 55 mm, or any range or subrange therebetween. Providing the first width within one or more of the ranges mentioned above in this paragraph can provide a large display portion visible to the user while ensuring that substantially all of the rest of the foldable substrate (e.g., central portion and second portion) can be within a footprint of the first portion (e.g., other than a portion around a roller as discussed below with reference to FIGS. 38-39).

Additionally or alternatively, the central width 287 can be greater than the second width 3737. In aspects, the central width 287, as a percentage of the length of the foldable substrate 201 and/or the foldable apparatus 101, can be about 15% or more, about 20% or more, about 25% or more, about 30% or more, about 35% or more, about 40% or more, about 42% or more, about 44% or more, about 45% or more, about 50% or less, about 49% or less, about 48% or less, about 47% or less, about 46% or less, about 45% or less, about 38% or less, or about 32% or less. In aspects, the central width 287, as a percentage of the length of the foldable substrate 201 and/or the foldable apparatus 101, can range from about 15% to about 50%, from about 20% to about 50%, from about 25% to about 49%, from about 30% to about 49%, from about 35% to about 48%, from about 40% to about 48%, from about 42% to about 47%, from about 43% to about 46%, from about 44% to about 45%, or any range or subrange therebetween. Providing a central width within one or more of the ranges mentioned above in this paragraph can enable a display portion of the foldable apparatus to be adjust as a portion of the rollable substrate is moved into and/or out of view of a user without unnecessarily expanding a size of the corresponding apparatus when in a fully rolled configuration.

FIGS. 38-39 show foldable apparatus 3801 and 3901 configured as rollable apparatus including the foldable substrate 201 as a rollable substrate. As shown, the foldable substrate 201 (e.g., rollable substrate) is configured to be rolled around roller 3805 (e.g., corresponding to a fold axis with the rollable substrate configured to be folded a range of axes corresponding to the roller as the rollable substrate is moved in a direction 3821 or in a direction opposite direction 3821). For example, the foldable substrate 201 (e.g., rollable substrate) can be rolled in the direction 3821 to expand a display portion of the foldable apparatus 3801 and 3901. Similarly, the foldable substrate 201 (e.g., rollable substrate) can be rolled in the direction opposite of the direction 3821 to decrease a display portion of the foldable apparatus 3801 and 3901. The foldable apparatus 3801 and 3901 can be configured to a have a dimension of the display portion adjust from substantially equal to the first width 3727 (e.g., with the central portion and the second portion 231 either within a footprint of the first portion 221 or around the roller) to about the sum of the first width 3727 and the central width 287 minus from about 1.6 to 3 times a diameter 3807 of the roller 3805. In aspects, the diameter 3807 of the roller 3805 can be about 1 mm or more, about 1.5 mm or more, about 2 mm or more, about 2.5 mm or more, about 3 mm or more, about 4 mm or more, about 5 mm or more, about 6 mm or more, about 7 mm or more, about 8 mm or more, about 9 mm or more, about 10 mm or more, about 50 mm or less, about 30 mm or less, about 20 mm or less, about 18 mm or less, about 16 mm or less, about 14 mm or less, about 12 mm or less, about 10 mm or less, about 8 mm or less, about 6 mm or less, about 5 mm or less, or about 4 mm or less. In aspects, the diameter 3807 of the roller 3805 can range from about 1 mm to about 50 mm, from about 1.5 mm to about 30 mm, from about 2 mm to about 20 mm, from about 2.5 mm to about 18 mm, from about 3 mm to about 16 mm, from about 4 mm to about 14 mm, from about 5 mm to about 12 mm, from about 6 mm to about 10 mm, from about 6 mm to about 8 mm, or any range or subrange therebetween. In aspects, the diameter 3807 of the roller 3805 can be about 6 mm or less, for example, from about 1 mm to about 6 mm, from about 1.5 mm to about 5 mm, from about 2 mm to about 4 mm, from about 2.5 mm to about 4 mm, from about 3 mm to about 4 mm, or any range or subrange therebetween.

As shown in FIGS. 38-39, the foldable substrate 201 (e.g., rollable substrate) can comprise one or more recess(es). For example, the foldable substrate 201 (e.g., rollable substrate) shown in FIG. 38 can comprise a single recess while the foldable substrate 201 (e.g., rollable substrate) shown in FIG. 39 can comprise two recesses. In aspects, a polymer-based portion (e.g., second polymer-based portion 299) and/or the adhesive layer 261 can be positioned in the first recess (e.g., defined by the first central surface area 213 in FIG. 38), the second recess (e.g., defined by the second central surface area 243 in FIG. 39), and/or between the corresponding central surface area and a display device 3811. For example, the region between the first central surface area 213 and a sixth surface area 3815 of the display device 3811 can correspond to the arrangement shown in FIG. 4 between the first central surface area 213 and the first major surface 273 of the release liner 271 with the second polymer-based portion 299 positioned in the first recess 211 and the adhesive layer 261 disposed thereon, although the adhesive layer 261 could extend into the recess, the second polymer-based portion 299 can extend beyond the recess, the corresponding region may not include the adhesive layer 261, or the corresponding region may not include the second polymer-based portion 299 in further aspects. For the configuration shown in FIG. 38, the fifth surface area 3813 of the display device 3811 (opposite the sixth surface area 3815) can be configured to contact and/or move along an outer periphery of the roller 3805; and/or a viewer can be positioned on the side of the second major surface 205 of the foldable substrate 201 (e.g., rollable substrate) to view an image through the foldable substrate 201 emitted from the display device 3811. In aspect, the display device 3811 can comprise a liquid crystal display (LCD), an electrophoretic displays (EPD), an organic light emitting diode (OLED) display, or a plasma display panel (PDP). It is to be understood that a coating (e.g., coating 251) can be disposed on the second major surface 205 of the foldable substrate 201 shown in FIG. 38.

As shown in FIG. 39, the region between the second central surface area 243 and the sixth surface area 3815 of the display device 3811 can correspond to the arrangement shown in FIG. 2 between the second central surface area 243 and the first major surface 273 of the release liner 271 with the first polymer-based portion 289 (instead of the second polymer-based portion 299) positioned in the second recess 241 and the adhesive layer 261 disposed thereon or the arrangement shown in FIG. 2 between the first central surface area 213 and the coating 251 with the second polymer-based portion 299 positioned in the first recess 211, although the adhesive layer 261 could extend into the recess, the second polymer-based portion 299 can extend beyond the recess, the corresponding region may not include the adhesive layer 261, or the corresponding region may not include the second polymer-based portion 299 in further aspects. In aspects, as shown in FIG. 39, the materials disposed on the first central surface area 213 can include the first polymer-based portion 289 and the coating 251, although another adhesive layer (e.g., similar to or identical to the adhesive layer 261) can be positioned therebetween or instead of the first polymer-based portion in further aspects. For the configuration shown in FIG. 39, the fifth surface area 3813 of the display device 3811 (opposite the sixth surface area 3815) can be configured to contact and/or move along an outer periphery of the roller 3805; and/or a viewer can be positioned on the side of the second major surface 205 of the foldable substrate 201 (e.g., rollable substrate) and/or the third major surface 253 of the coating 251 to view an image through the foldable substrate 201 emitted from the display device 3811.

The foldable apparatus 101, 301, 401, 501, 701, 801, 901, 3801, and/or 3901 may have an impact resistance defined by the capability of a region of the foldable apparatus (e.g., a region comprising the first portion 221, a region comprising the second portion 231, a region comprising the polymer-based portion 289 and/or 299 and/or central portion 281) to avoid failure at a pen drop height (e.g., 5 centimeters (cm) or more, 10 centimeters or more, 20 cm or more), when measured according to the “Pen Drop Test.” As used herein, the “Pen Drop Test” is conducted such that samples of foldable apparatus are tested with the load (i.e., from a pen dropped from a certain height) imparted to an outer major surface (e.g., first major surface 203 of the foldable substrate 201 for foldable apparatus 101 or 301 shown in FIGS. 2-3, second major surface 205 of the foldable substrate 201 for foldable apparatus 301 or 401 shown in FIGS. 3-4) with the foldable apparatus configured as in the parallel plate test with 100 μm thick sheet 707 of PET attached to the test adhesive layer 709 having a thickness of 50 μm instead of the release liner 271 shown in FIG. 2. As such, the PET layer in the Pen Drop Test is meant to simulate a foldable electronic display device (e.g., an OLED device). During testing, the foldable apparatus bonded to the PET layer is placed on an aluminum plate (6063 aluminum alloy, as polished to a surface roughness with 400 grit paper) with the PET layer in contact with the aluminum plate. No tape is used on the side of the sample resting on the aluminum plate.

A tube is used for the Pen Drop Test to guide a pen to an outer surface of the foldable apparatus. For the foldable apparatus 101, 301, 401, 501, 701, 801, 901, 3801, and/or 3901 in FIGS. 2-4, 6-9, 38-39, the pen is guided to the outer major surface (e.g., first major surface 203 of the foldable substrate 201 for foldable apparatus 101 or 301 shown in FIGS. 2-3, second major surface 205 of the foldable substrate 201 for foldable apparatus 301 or 401 shown in FIGS. 3-4), and the tube is placed in contact with the second major surface 205 of the foldable substrate 201 so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (ABS) shim is employed to hold the pen at a predetermined height for each test. After each drop, the tube is relocated relative to the sample to guide the pen to a different impact location on the sample. The pen employed in Pen Drop Test is a BIC Easy Glide Pen, Fine, having a tungsten carbide ballpoint tip of 0.7 mm (0.68 mm) diameter, and a weight of 5.73 grams (g) including the cap.

For the Pen Drop Test, the pen is dropped with the cap attached to the top end (i.e., the end opposite the tip) so that the ballpoint can interact with the test sample. In a drop sequence according to the Pen Drop Test, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. Using the Pen Drop Test, multiple samples can be tested according to the same drop sequence to generate a population with improved statistical accuracy. For the Pen Drop Test, the pen is to be changed to a new pen after every 5 drops, and for each new sample tested. In addition, all pen drops are conducted at random locations on the sample at or near the center of the sample, with no pen drops near or on the edge of the samples.

For purposes of the Pen Drop Test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of a laminate. The crack may extend through all or a portion of the foldable substrate 201 and/or coating. A visible mechanical defect has a minimum dimension of 0.2 mm or more.

In aspects, the foldable apparatus can resist failure for a pen drop in a region comprising the first portion 221 or the second portion 231 at a pen drop height of 10 centimeters (cm), 12 cm, 14 cm, 16 cm, or 20 cm. In aspects, a maximum pen drop height that the foldable apparatus can withstand without failure over a region comprising the first portion 221 or the second portion 231 may be about 10 cm or more, about 12 cm or more, about 14 cm or more, about 16 cm or more, about 40 cm or less, or about 30 cm or less, about 20 cm or less, about 18 cm or less. In aspects, a maximum pen drop height that the foldable apparatus can withstand without failure over a region comprising the first portion 221 or the second portion 231 can be in a range from about 10 cm to about 40 cm, from about 12 cm to about 40 cm, from about 12 cm to about 30 cm, from about 14 cm to about 30 cm, from about 14 cm to about 20 cm, from about 16 cm to about 20 cm, from about 18 cm to about 20 cm, or any range or subrange therebetween.

In aspects, the foldable apparatus can resist failure for a pen drop in a region (e.g., central portion 281) comprising the polymer-based portion 289 and/or 299 between the first portion 221 and the second portion 231 at a pen drop height of 1 cm, 2 cm, 3 cm, 4 cm, 5 cm, or more. In aspects, a maximum pen drop height that the foldable apparatus can withstand without failure over a region comprising the polymer-based portion 289 and/or 299 between the first portion 221 and the second portion 231 may be about 1 cm or more, about 2 cm or more, about 3 cm or more, about 4 cm or more, about 20 cm or less, about 10 cm or less, about 8 cm or less, or about 6 cm or less. In aspects, a maximum pen drop height that the foldable apparatus can withstand without failure over a region comprising the polymer-based portion 289 and/or 299 between the first portion 221 and the second portion 231 can be in a range from about 1 cm to about 20 cm, from about 2 cm to about 20 cm, from about 2 cm to about 10 cm, from about 3 cm to about 10 cm, from about 3 cm to about 8 cm, from about 4 cm to about 8 cm, from about 4 cm to about 6 cm, or any range or subrange therebetween. In aspects, a maximum pen drop height that the foldable apparatus can withstand without failure of a region comprising the polymer-based portion 289 and/or 299 between the first portion 221 and the second portion 231 can be in a range from about 1 cm to about 10 cm, from about 1 cm to about 8 cm, from about 1 cm to about 5 cm, from about 2 cm to about 5 cm, from about 3 cm to about 5 cm, from about 4 cm to about 5 cm, or any range or subrange therebetween.

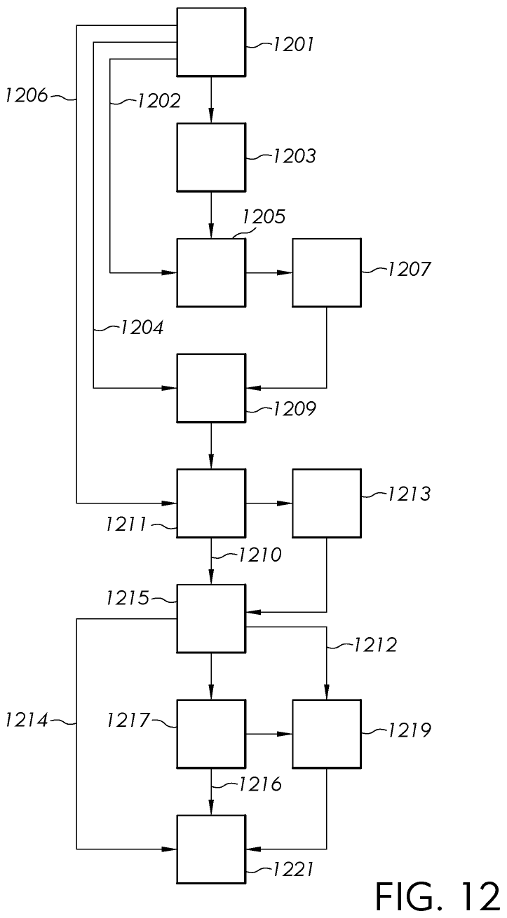

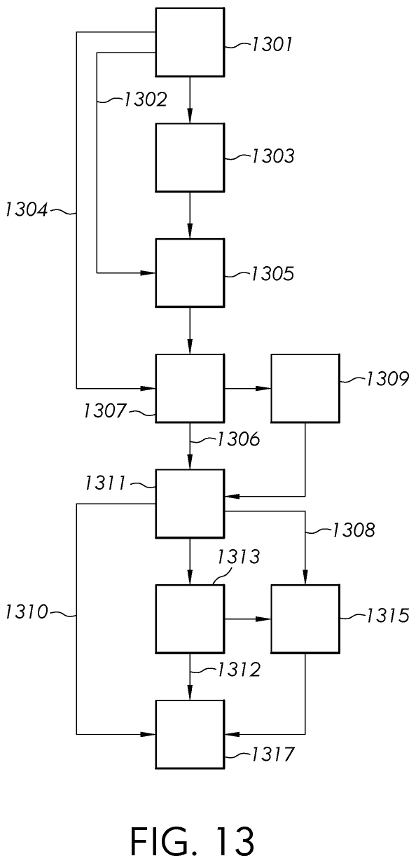

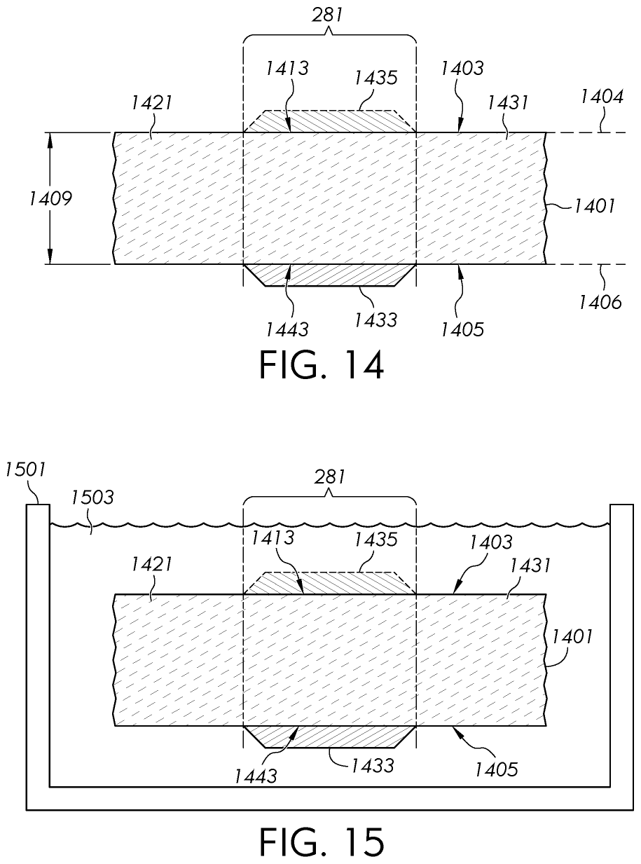

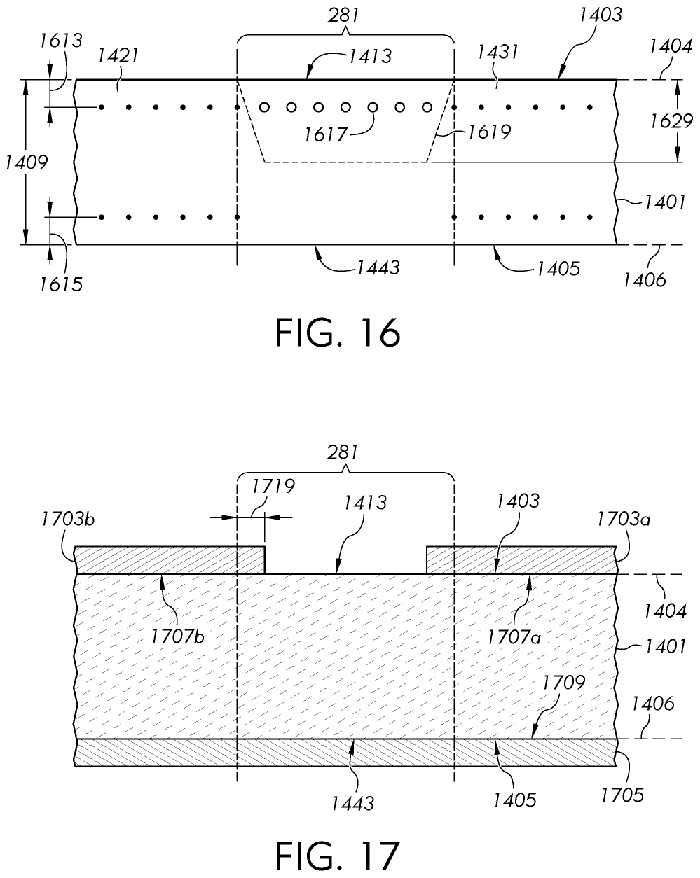

Aspects of methods of making the foldable apparatus and/or foldable substrate in accordance with aspects of the disclosure will be discussed with reference to the flow chart in FIGS. 12-13 and example method steps illustrated in FIGS. 14-15, 17-18, 20, 22-26, 28-30, and 32-35 and cross-sectional views illustrated in FIGS. 16, 19, 21, 27, and 31.

Example aspects of making the foldable apparatus 401, 801, and/or 901 and/or foldable substrate 201 illustrated in FIGS. 4 and 8-9 will now be discussed with reference to FIGS. 14-25 and the flow chart in FIG. 12. In a first step 1201 of methods of the disclosure, methods can start with obtaining a foldable substrate 1401 (see FIGS. 14-15). In aspects, the foldable substrate 1401 may be provided by purchase or otherwise obtaining a substrate or by forming the foldable substrate. In aspects, the foldable substrate 1401 can comprise a glass-based substrate and/or a ceramic-based substrate. In further aspects, glass-based substrates and/or ceramic-based substrates can be provided by forming them with a variety of ribbon forming processes, for example, slot draw, down-draw, fusion down-draw, up-draw, press roll, redraw, or float. In further aspects, ceramic-based substrates can be provided by heating a glass-based substrate to crystallize one or more ceramic crystals. The foldable substrate 1401 may comprise an existing first major surface 1403 that can extend along a first plane 1404. The foldable substrate 1401 may comprise an existing second major surface 1405 that can extend along a second plane 1406. The existing second major surface 1405 can be opposite the existing first major surface 1403, and/or the first plane 1404 can be parallel to the second plane 1406. In aspects, as shown in FIG. 14, in step 1201, the foldable substrate 1401 can comprise an existing first central surface area 1413 that is coplanar with the existing first major surface 1403, for example, the existing first major surface 1403 comprising the existing first central surface area 1413. In aspects, as shown in FIG. 14, in step 1201, the foldable substrate 1401 can comprise an existing second central surface area 1443 that is coplanar with the existing second major surface 1405, for example, the existing second major surface 1405 comprising the existing second central surface area 1443. A central portion 281 comprises the existing first central surface area 1413 and the existing second central surface area 1443.

After step 1201, as shown in FIG. 14, methods can proceed to step 1203 comprising masking the existing second central surface area 1443, for example, by disposing a second barrier layer 1433 on the existing second central surface area 1443. In aspects, as shown, the second barrier layer 1433 can be disposed on and cover the entire existing second central surface area 1443. In aspects, as shown in FIG. 16, step 1203 can optionally comprise disposing a first barrier layer 1435 on the existing first central surface area 1413. In further aspects, as shown, the first barrier layer 1435 can be disposed on and cover the entire existing first central surface area 1413. In aspects, the first barrier layer 1435 and/or the second barrier layer 1433 can reduce the diffusion of alkali metal ions therethrough during chemical strengthening in step 1205 (discussed below). In further aspects, the first barrier layer 1435 and/or the second barrier layer 1433 can prevent the diffusion of alkali metal ions therethrough during chemical strengthening in step 1205 (discussed below). In further aspects, the first barrier layer 1435 and/or the second barrier layer 1433 can comprise a covalent solid, as compared with an ionic solid. Without wishing to be bound by theory, a covalent solid can reduce (e.g., prevent, block) the diffusion of alkali metal ions therethrough. In further aspects, the first barrier layer 1435 and/or the second barrier layer 1433 can comprise one aluminum nitride (AlN), aluminum oxynitride (AlON, as described above), sputtered silicon nitride (Si₃N₄), or combinations thereof. In aspects, the second barrier layer 1433 can comprise the same material as the first barrier layer 1435. In aspects, disposing the first barrier layer 1435 and/or the second barrier layer 1433 can comprise sputtering, chemical vapor deposition, thermal evaporation, or electron-beam deposition. An exemplary aspect of disposing the first barrier layer 1435 and/or the second barrier layer 1433 comprises sputtering. In aspects, the first barrier layer 1435 and/or the second barrier layer 1433 can comprise an average thickness of about 5 nanometers (nm) or more, about 10 nm or more, about 20 nm or more, about 50 nm or more, about 100 nm or more, about 10 μm or less, about 2 μm or less, about 1 μm or less, about 500 nm or less, or about 200 nm or less. In aspects, the first barrier layer 1435 and/or the second barrier layer 1433 can comprise an average thickness in a range from about 5 nm to about 10 μm, from about 5 nm to about 2 μm, from about 10 nm to about 2 μm, from about 10 nm to about 1 μm, from about 20 nm to about 1 μm, from about 20 nm to about 500 nm, from about 50 nm to about 500 nm, from about 50 nm to about 200 nm, from about 100 nm to about 200 nm, or any range or subrange therebetween.

After step 1201 or 1203, as shown in FIG. 15, methods can proceed to step 1205 comprising initially chemically strengthening the foldable substrate 1401. In aspects, the foldable substrate 1401 can be substantially unstrengthened before the chemically strengthening of step 1205. As used herein, substantially unstrengthened refers to a substrate comprising either no depth of layer, no depth of compression, a depth of layer in a range from 0% to about 5% of the substrate thickness, or a depth of compression in a range from 0% to about 5% of the substrate thickness. In aspects, as shown in FIG. 15, chemically strengthening the foldable substrate 1401 can comprise contacting at least a portion of a foldable substrate 1401 comprising lithium cations and/or sodium cations with a salt bath 1501 comprising salt solution 1503. Chemically strengthening a foldable substrate 1401 (e.g., glass-based substrate, ceramic-based substrate) by ion exchange can occur when a first cation within a depth of a surface of a foldable substrate 1401 is exchanged with a second cation within a molten salt or salt solution 1503 that has a larger radius than the first cation. For example, a lithium cation within the depth of the surface of the foldable substrate 1401 can be exchanged with a sodium cation or potassium cation within a salt solution 1503. Consequently, the surface of the foldable substrate 1401 is placed in compression and thereby chemically strengthened by the ion exchange process since the lithium cation has a smaller radius than the radius of the exchanged sodium cation or potassium cation within the salt solution 1503. Chemically strengthening the foldable substrate 1401 can comprise contacting at least a portion of a foldable substrate 1401 comprising lithium cations and/or sodium cations with a salt bath 1501 comprising salt solution 1503 comprising potassium nitrate, potassium phosphate, potassium chloride, potassium sulfate, sodium chloride, sodium sulfate, sodium nitrate, and/or sodium phosphate, whereby lithium cations and/or sodium cations diffuse from the foldable substrate 1401 to the salt solution 1503 contained in the salt bath 1501. In aspects, the temperature of the salt solution 1503 can be about 300° C. or more, about 360° C. or more, about 400° C. or more, about 500° C. or less, about 460° C. or less, or about 420° C. or less. In aspects, the temperature of the salt solution 1503 can be in a range from about 300° C. to about 500° C., from about 360° C. to about 460° C., from about 400° C. to about 420° C., or any range or subrange therebetween. In aspects, the foldable substrate 1401 can be in contact with the salt solution 1503 for about 30 minutes or more, about 45 minutes or more, about 1 hour or more, about 8 hours or less, about 4 hours or less, about 2 hours or less, or about 1.5 hours or less. In aspects, the foldable substrate 1401 can be in contact with the salt solution 1503 for a time in a range from about 30 minutes to about 8 hours, from about 45 minutes to about 4 hours, from about 1 hour to about 2 hours, from about 1 hour to about 1.5 hours, or any range or subrange therebetween.

In aspects, as shown in FIG. 16, initially chemically strengthening the foldable substrate 1401 in step 1205 can comprise chemically strengthening the existing first major surface 1403 in the first portion 1421 and the second portion 1431 to form an initial first compressive stress region extending to an initial first depth 1613 (e.g., depth of compression, depth of layer) from the existing first major surface 1403. In aspects, as shown in FIG. 16, chemically strengthening the foldable substrate 1401 in step 1205 can comprise chemically strengthening the existing second major surface 1405 in the first portion 1421 and the second portion 1431 to form an initial second compressive stress region extending to an initial second depth 1615 (e.g., depth of compression, depth of layer) from the existing second major surface 1405. In aspects, as indicated by the lack of dots (or the open circles 1617) in FIG. 16, the central portion 281 may not be chemically strengthened as a result of step 1205. In aspects, as indicated by the open circles 1617 in FIG. 16, when the first barrier layer 1435 is not present during step 1205, the existing first central surface area 1413 can be chemically strengthened during step 1205 without chemically strengthening the existing second central surface area 1443. As indicated in FIG. 16, any chemical strengthening at the existing first central surface area 1413 will be removed in forming the first recess (indicated by the dashed lines 1619) in step 1211 (discussed below) since a first distance 1629 of the recess will be greater than the initial first depth 1613. In aspects, the initial first depth 1613 and/or the initial second depth 1615, as a percentage of an initial substrate thickness 1409, can be about 10% or more, about 11% or more, about 12% or more, about 13% or more, about 20% or less, about 18% or less, about 16% or less, or about 14% or less. In aspects, the initial first depth 1613 and/or the initial second depth 1615, as a percentage of an initial substrate thickness 1409, can be in a range from about 10% to about 20%, from about 11% to about 18%, from about 12% to about 16%, from about 13% to about 14%, or any range or subrange therebetween.

After step 1205, as shown in FIGS. 16, methods can proceed to step 1207 comprising removing the first barrier layer 1435, if present, and/or the second barrier layer 1433. In aspects, step 1207 can comprise contacting the first barrier layer 1435, if present, and/or the second barrier layer 1433 with an alkaline solution. In further aspects, the alkaline solution can comprise a temperature of about 20° C. or more, about 30° C. or more, about 40° C. or more, about 50° C. or more, about 60° C. or more, about 70° C. or more, about 120° C. or less, about 100° C. or less, about 90° C. or less, or about 80° C. or less. In further aspects, the alkaline solution can comprise a temperature in a range from about 20° C. to about 120° C., from about 20° C. to about 100° C., from about 30° C. to about 100° C., from about 40° C. to about 100° C., from about 40° C. to about 90° C., from about 50° C. to about 90° C., from about 50° C. to about 80° C., from about 60° C. to about 80° C., from about 70° C. to about 80° C., or any range or subrange therebetween. In further aspects, the alkaline solution can comprise an alkaline detergent solution, for example, with a concentration of the alkaline detergent from about 1 wt % to about 4 wt % or from about 2 wt % to about 3 wt %. An exemplary aspect of the alkaline detergent solution is Semiclean KG available from Yokohama Oils & Fats Industry Co., Ltd.

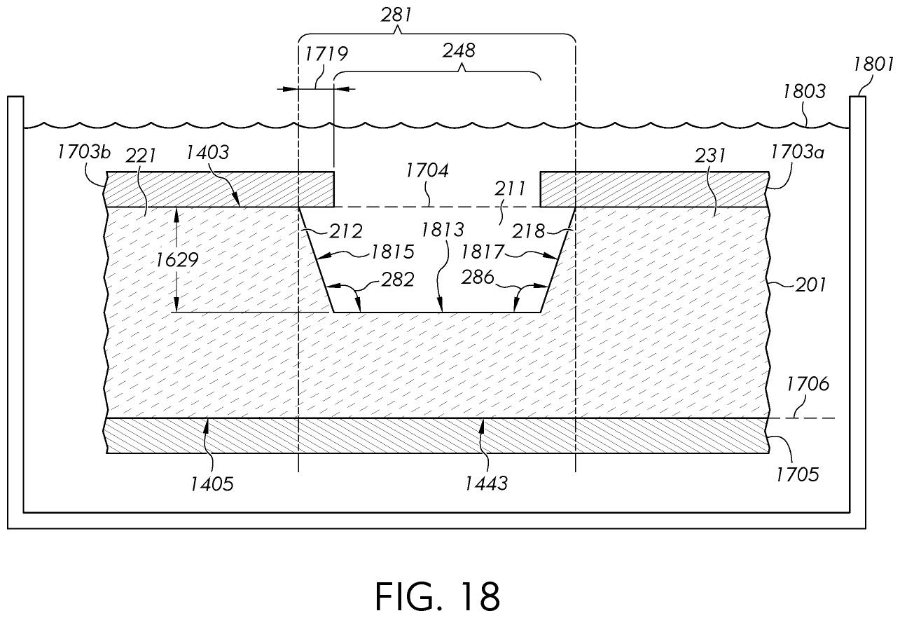

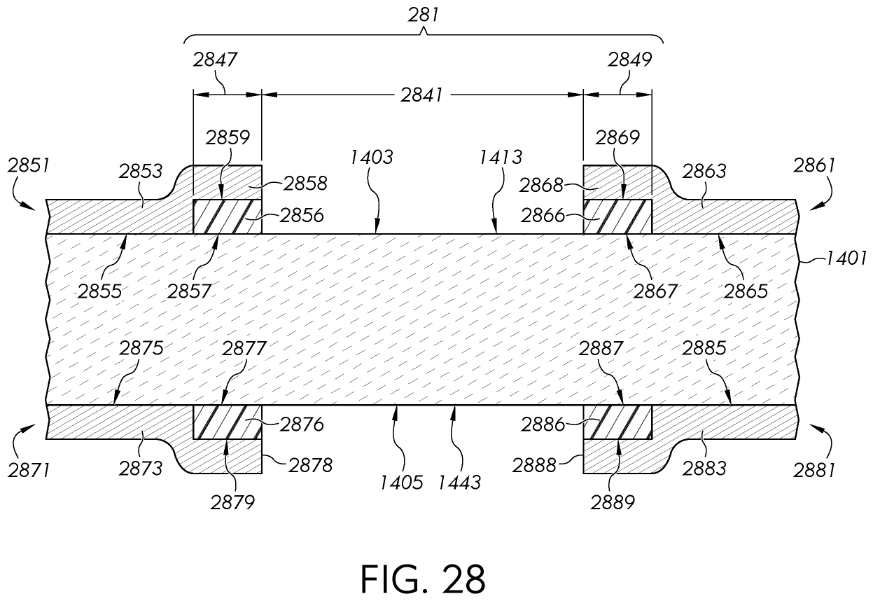

After step 1201 or 1207, as shown in FIGS. 17-18, methods can proceed to step 1209 comprising disposing an etch mask on the foldable substrate 1401 without covering the entire existing first central surface area 1413. In aspects, as shown in FIG. 18, a first portion 1703b can be disposed on the first portion 221 (e.g., first surface area 1707b of the first portion 1703b can contact the existing first major surface 1403 in the first portion 221). In further aspects, as shown in FIGS. 17-18, the second portion 1703a can extend for a length 1719 into the central portion 281 (relative to the dimensions of the resulting foldable substrate), which can allow for the predetermined dimension of the resulting foldable substrate, for example, by accounting for undercutting during step 1211. In aspects, as shown in FIG. 18, a second portion 1703a can be disposed on the second portion 231 (e.g., second surface area 1707a of the second portion 1703a can contact the existing first major surface 1403 in the second portion 231). In further aspects, as shown in FIGS. 17-18, the second portion 1703a can extend into the central portion 281, for example, for a length equal to the length 1719. In aspects, as shown in FIGS. 17-18, a third portion 1705 can be disposed on the existing second major surface 1405 (e.g., including the existing second central surface area 1443) (e.g., third surface area 1709 of the third portion 1705 contacting the existing second major surface 1405), for example, covering the entire existing second major surface 1405. In aspects, the etch mask (e.g., first portion 1703b, second portion 1703a, third portion 1705) can comprise a polymer (e.g., acid-resistant polymer), or an inorganic material. Exemplary aspects of polymers include a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene). Exemplary aspects of inorganic materials for the etch mask include titanium dioxide (TiO₂), zirconia (ZrO₂), tin oxide (SnO₂), alumina (Al₂O₃), silica (SiO₂), silicon nitride (Si₃N₄), and/or combinations thereof, although other materials for masks can be used in other aspects. In aspects the etch mask can be disposed by curing a precursor dispensed from a container onto the foldable substrate or by attaching a tape comprising the acid-resistant polymer and an adhesive. Alternatively, another method (e.g., chemical vapor deposition (CVD) (e.g., low-pressure CVD, plasma-enhanced CVD), physical vapor deposition (PVD) (e.g., evaporation, molecular beam epitaxy, ion plating), atomic layer deposition (ALD), sputtering, spray pyrolysis, chemical bath deposition, sol-gel deposition) may be used to form the etch mask. Alternatively, as shown in FIG. 28 and discussed below with reference to step 1307, the etch mask can resemble the etch mask (e.g., first portion 2851) comprising a polymer layer (e.g., first polymer layer 2856) and a barrier layer (e.g., first barrier layer 2853) disposed on the polymer layer and the existing first major surface 1403.

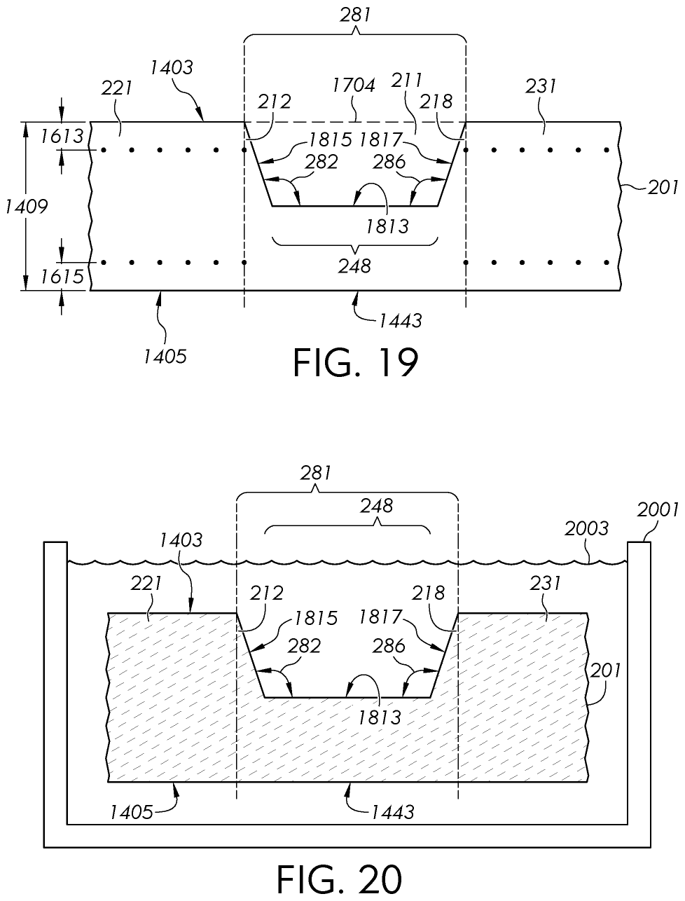

After step 1201 or 1209, as shown by comparing FIGS. 16-17 with FIG. 18, methods can proceed to step 1211 comprising etching the existing first central surface area 1413 (see FIGS. 16-17) to form a first central surface area 1813. In aspects, as shown, step 1211 can comprise contacting at least the existing first central surface area 1413 with an etchant 1803, for example, by immersing the foldable substrate 201 in a etchant bath 1801 containing the etchant 1803. In further aspects, the etchant 1803 can comprise one or more acids (e.g., HCl, HF, H₂SO₄, HNO₃). In aspects, the etchant 1803 can undercut the first portion 1703b and/or the second portion 1703a of the etch mask, for example by the length 1719. Step 1211 can form the first central surface area 1813 that can be recessed from the first plane 1704 by the first distance 1629, which can be substantially equal to a difference between the substrate thickness 207 and the central thickness 209 (see FIG. 4). In aspects, as shown in FIGS. 18-19, step 1211 can further form the first transition region 212 comprising the first transition surface area 1815 and/or the second transition region 218 comprising the third transition surface area 1817. In further aspects, as shown, an angle between the first transition surface area 1815 and the first central surface area 1813 can be substantially equal to the first average angle 282, and/or an angle between the third transition surface area 1817 and the first central surface area 1813 can be substantially equal to the third average angle 286.

After step 1211, as shown in FIG. 19, methods can proceed to step 1213 comprising removing the one or more etch masks. In aspects, step 1213 can comprise removing the etch mask using a tool (e.g., grinding, sweeping, scraping, pushing, etc.), washing the foldable substrate (e.g., using a detergent solution, using an alkaline solution), or a combination thereof.

After step 1211 or 1213, as shown in FIG. 20, methods can proceed to step 1215 comprising further chemically strengthening the foldable substrate 201. In aspects, as shown, step 1215 can comprise contacting the foldable substrate 201 with a salt solution 2003 for a second period of time. In further aspects, as shown, step 1215 can comprise immersing the foldable substrate 201 in a salt bath 2001 containing the salt solution 2003. In aspects, the salt solution 2003 can be the same as the salt solution 1503 in step 1205, although the salt solutions can be different in other aspects. In further aspects, the salt solution 2003 can comprise potassium ions. In aspects, the salt solution 2003 can be maintained at a temperature within one or more of the ranges discussed above for the temperature of the salt solution 1503. In aspects, the second period of time that the salt solution 2003 contacts the foldable substrate 201 can be less than the first period of time. In further aspects, the second period of time, as a percentage of the first period of time, can be about 2% or more, about 5% or more, about 8% or more, about 10% or more, about 20% or less, about 18% or less, about 15% or less, or about 12% or less. In further aspects, the second period of time, as a percentage of the first period of time, can be in a range from about 2% to about 20%, from about 5% to about 18%, from about 8% to about 15%, from about 10% to about 12%, or any range or subrange therebetween. In aspects, the second period of time can be about 1 minute or more, about 2 minutes or more, about 4 minutes or more, about 10 minutes or less, about 8 minutes or less, or about 6 minutes or less. In aspects, the second period of time can be in a range from about 1 minute to about 10 minutes, from about 2 minutes to about 8 minutes, from about 4 minutes to about 6 minutes, or any range or subrange therebetween. In aspects, a square root of a ratio of the second period of time to the first period of time can be less than the central thickness divided by the difference between the substrate thickness and the central thickness, which can provide the above-mentioned relationships between the ratio of the first depth of compression to substrate thickness to the ratio of the first central depth of compression to the central thickness and/or between the ratio of the first depth of layer to substrate thickness to the ratio of the first central depth of layer to the central thickness.

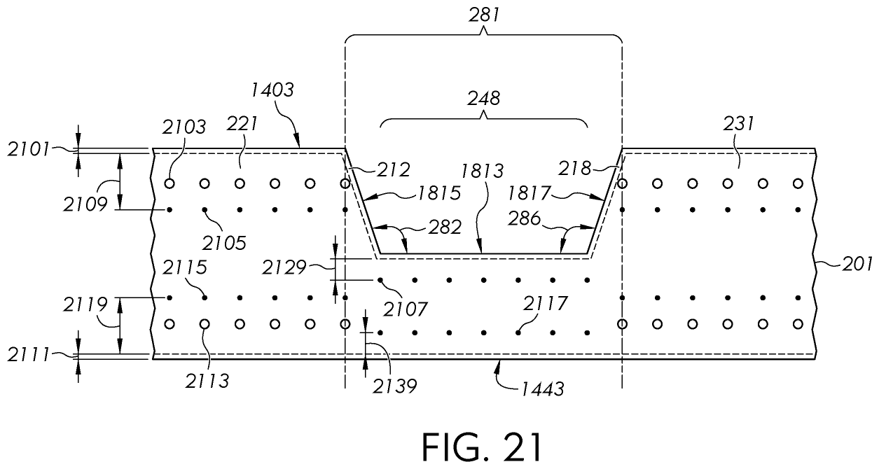

At the end of step 1215, as shown in FIG. 21, the compressive stress region(s) extending from the existing first major surface 1403 can be increased from the initial first depth (as indicated by open circles 2103) to about the first depth 2109 (as indicated by solid dots 2105). At the end of step 1215 or at the end of step 1217 (discussed below), the first compressive stress region in the first portion 221 can extend to the first depth 2109 (e.g., first depth of compression, first depth of layer) and/or the third compressive stress region in the second portion 231 can extend to the first depth 2109 (e.g., third depth of compression, third depth of layer). At the end of step 1215, as shown in FIG. 21, the compressive stress region(s) extending from the existing second major surface 1405 can be increased from the initial second depth (as indicated by open circles 2113) to the second depth 2119 (as indicated by solid dots 2115). At the end of step 1215 or at the end of step 1217 (discussed below), the second compressive stress region in the first portion 221 can extend to the second depth 2119 (e.g., second depth of compression, second depth of layer) and/or the fourth compressive stress region in the second portion 231 can extend to the second depth 2119 (e.g., fourth depth of compression, fourth depth of layer). At the end of step 1215, as shown in FIG. 21, a first central compressive stress region (as indicated by solid dots 2107) in the central portion 281 extending from the first central surface area 1813 can extend to the first central depth 2129 (e.g., first central depth of compression, first central depth of layer), and/or a second central compressive stress region (as indicated by solid dots 2117) in the central portion 281 extending from the second central surface area 1843 can extend to the second central depth 2139 (e.g., second central depth of compression, second central depth of layer). The relationship between these depths of compression and/or depth of layer can correspond to those described above (e.g., an amount that a ratio of the first depth of compression to the substrate thickness is greater than a ratio of the first central depth of compression to the central thickness).

As shown in FIG. 21, a first surface layer 2101 and/or a second surface layer 2111 can be removed in step 1217 (discussed below). In aspects, the first surface layer 2101 can be substantially uniform across the existing first major surface 1403, the first transition surface area 1815, the third transition surface area 1817, and/or the first central surface area 1813. In aspects, the second surface layer 2111 can be substantially uniform across the existing second major surface 1405 (e.g., including the existing second central surface area 1443). In further aspects, the second surface layer 2111 can be substantially equal to the first surface layer 2101. After step 1217, the foldable substrate can correspond to the foldable substrate shown in FIG. 4.

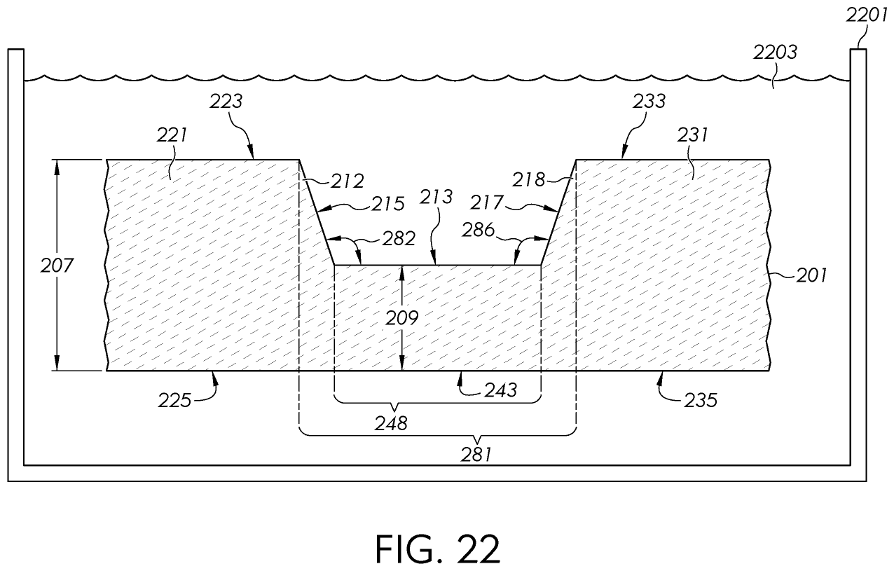

After step 1215, as shown in FIG. 22, methods can proceed to step 1217 comprising etching a uniform thickness substantially uniformly from the foldable substrate 201. In aspects, as shown, step 1217 can comprise contacting the foldable substrate 201 with an etchant 2203. In further aspects, as shown, step 1217 can comprise immersing the foldable substrate 201 in an etchant bath 2201 containing the etchant 2203. In aspects, the etchant 2203 can be the same as the etchant 1803 discussed above with reference to step 1211. In aspects, the etchant 2203 can comprise a lower concentration (e.g., molarity) than the etchant 1803. In aspects, the thickness removed substantially uniformly from the foldable substrate 201 in step 1217 can be about 0.1 μm or more, about 0.2 μm or more, about 0.5 μm or more, about 5 μm or less, about 2 μm or less, about 1 μm or less, or about 0.8 μm or less. In aspects, the thickness removed substantially uniformly from the foldable substrate 201 in step 1217 can be in a range from about 0.1 μm to about 5 μm, from about 0.1 μm to about 2 μm, from about 0.2 μm to about 1 μm, from about 0.5 μm to about 0.8 μm, or any range or subrange therebetween. Etching the substrate in step 1217 (after the further chemically strengthening the foldable substrate in step 1215) can remove flaws near or at the surface of the foldable substrate 201, which can increase a strength (e.g., pen drop height) and/or flexibility (e.g., ability to achieve a particular parallel plate distance) of the foldable substrate 201. In aspects, as shown, at the end of step 1217, the etching can produce a foldable substrate with the substrate thickness 207 and the central thickness 209. In aspects, as shown, at the end of step 1217, the etching can form the first surface area 223, the second surface area 225, the third surface area 233, the fourth surface area 235, the first central surface area 213, and/or the second central surface area 243 with the properties discussed above with reference to FIG. 4.

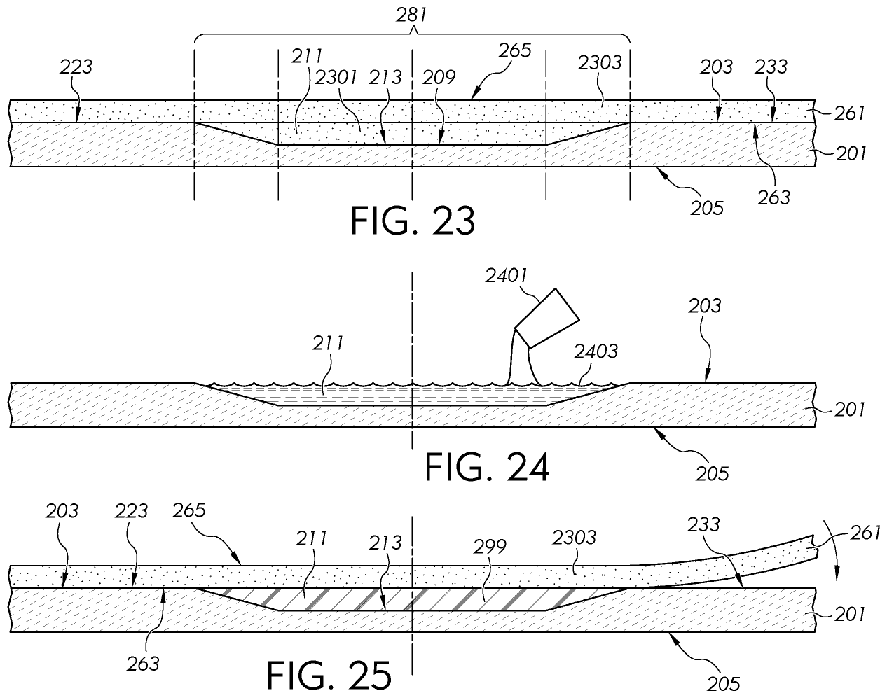

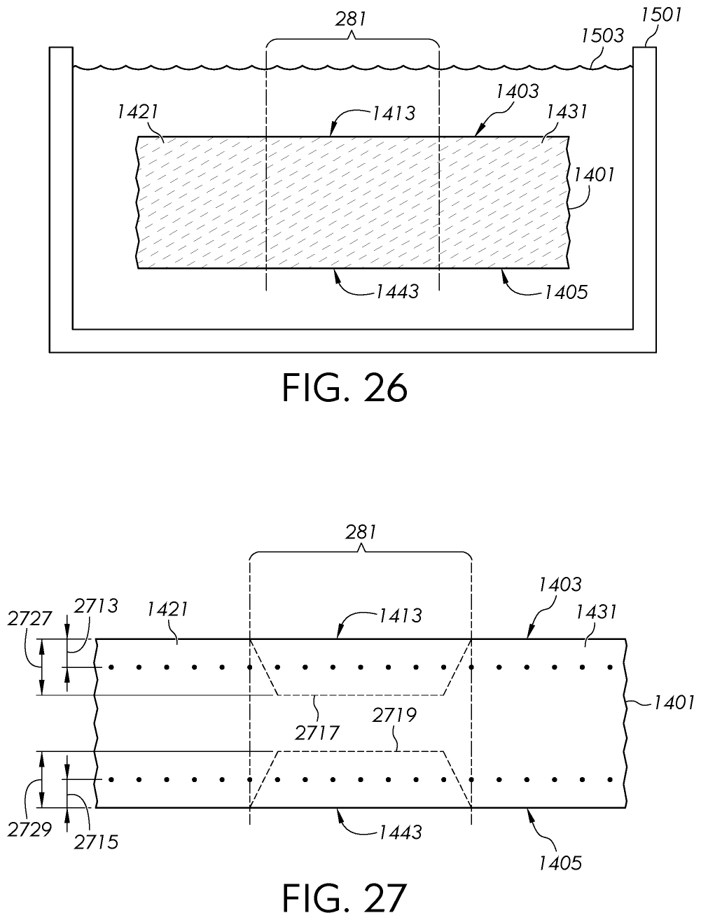

After step 1215 or 1217, as shown in FIGS. 23-25, methods can proceed to step 1219 comprising assembling a foldable apparatus from the foldable substrate 201. For example, step 1219 can comprise disposing one or more adhesive layers, disposing one or more polymer based portions, disposing one or more coatings, disposing a release liner or a display device over the foldable substrate, and/or combinations thereof. In aspects, one or more materials can at least partially fill the first recess 211, although not shown, the recess may not be totally filled, for example, to leave room for electronic devices and/or mechanical devices. In aspects, as shown in FIG. 23, one or more layers 2301 of adhesive can be at least partially disposed in the first recess 211. In further aspects, as shown, a first layer 2301 can be disposed in the first recess 211 (e.g., contacting the first central surface area 213) and a second layer 2303 can be disposed thereon and/or contacting the first major surface 203 (e.g., first surface area 223, third surface area 233). As shown, the one or more layers 2301 can form the adhesive layer 261 comprising a first contact surface 263 facing and/or contacting the first major surface 203 (e.g., first surface area 223, third surface area 233) and/or the first central surface area 213. Alternatively, although not shown, the adhesive layer could be formed by dispensing a precursor liquid that is cured to from the adhesive layer 261 (e.g., similar to the method discussed in the next sentence for forming the polymer-based portion). In aspects, as shown in FIG. 24, a precursor liquid 2403 can be dispensed from a container 2401 (e.g., conduit, flexible tube, micropipette, or syringe) to at least partially fill the first recess 211. The precursor liquid 2403 can be cured (e.g., heating, irradiating, and/or waiting) to form the polymer-based portion 299 shown in FIG. 25. In further aspects, as shown in FIG. 26, an adhesive layer 261 (e.g., one or more layers, as discussed above) can be disposed on the polymer-based portion 299 and/or the first major surface 203 (e.g., with the first contact surface 263 contacting the polymer-based portion and the first major surface 203). In further aspects, a release liner 271 can be disposed on the second contact surface 265 of the adhesive layer 261 to form the foldable apparatus 401 shown in FIG. 4. In aspects, the foldable substrate 201 can be a rollable substrate and/or the foldable substrate 201 can be assembled into a foldable apparatus similar to or identical to the foldable apparatus 3801 shown in FIG. 38, for example, with the display device 3811 instead of the release liner 271 shown in FIG. 4.

After step 1215, 1217, or 1219, methods can proceed to step 1221, where methods of making the foldable substrate and/or the foldable apparatus can be complete. In aspects, methods of making a foldable substrate and/or a foldable apparatus in accordance with aspects of the disclosure can proceed along steps 1201, 1203, 1205, 1207, 1209, 1211, 1213, 1215, 1217, and 1219 of the flow chart in FIG. 12 sequentially, as discussed above. In aspects, methods can follow arrow 1202 from step 1201 to step 1205, for example, if a barrier layer is already disposed on the foldable substrate at the end of step 1201. In aspects, methods can follow arrow 1204 from step 1201 to step 1204, for example, if the foldable substrate already comprises the initial compressive stress region(s) at the end of step 1201. In aspects, methods can follow arrow 1206 from step 1201 to step 1211, for example, if the foldable substrate already comprises the initial compressive stress region(s) and has the etch mask(s) disposed thereon at the end of step 1201. In aspects, methods can follow arrow 1210 from step 1211 to step 1215, for example, if the etch mask is permeable to the ions in the salt solution, will be removed by the salt solution, or was already removed by the end of step 1211. In aspects, methods can follow arrow 1212 from step 1215 to step 1217, for example, if the foldable substrate is not to be uniformly etched before being assembled in a foldable apparatus. In aspects, methods can follow arrow 1214 from step 1215 to step 1221, for example, if methods are complete at the end of step 1215. In aspects, methods can follow arrow 1216 from step 1217 to step 1221, for example, if methods are complete at the end of step 1217. Any of the above options may be combined to make a foldable apparatus in accordance with the embodiments of the disclosure.

Example aspects of making the foldable apparatus 101, 301, 501, and/or 701 and/or foldable substrate 201 illustrated in FIGS. 2-3 and 6-7 will now be discussed with reference to FIGS. 26-35 and the flow chart in FIG. 13. In a first step 1301 of methods of the disclosure, methods can start with obtaining a foldable substrate 1401 (see FIG. 26). Step 1301 can comprise any (one or more) of the aspects discussed above with reference to step 1201.

After step 1301, as shown in FIG. 26, methods can proceed to step 1303 comprising initially chemically strengthening the foldable substrate 1401. In aspects, the foldable substrate 1401 can be substantially unstrengthened before the chemically strengthening of step 1303. In aspects, as shown in FIG. 26, chemically strengthening the foldable substrate 1401 can comprise contacting at least a portion of a foldable substrate 1401 comprising lithium cations and/or sodium cations with a salt bath 1501 comprising salt solution 1503. The salt solution 1503 can comprise any one or more of the materials discussed above with reference to step 1205. The salt solution 1503 can be maintained at a temperature within one or more of the corresponding ranges discussed above with reference to step 1205. The foldable substrate 1401 can be in contact with the salt solution 1503 for a first period of time, which can be within one or more of the ranges discussed above for the corresponding range with reference to step 1205.

As shown in FIG. 27, initially chemically strengthening the foldable substrate 1401 in step 1303 can comprise chemically strengthening the existing first major surface 1403 in the first portion 1421, and the second portion 1431, and/or the central portion 281 to form an initial first compressive stress region extending to an initial first depth 2713 (e.g., depth of compression, depth of layer) from the existing first major surface 1403. In aspects, as shown in FIG. 27, chemically strengthening the foldable substrate 1401 in step 1303 can comprise chemically strengthening the existing second major surface 1405 in the first portion 1421, the second portion 1431, and/or the central portion 281 to form an initial second compressive stress region extending to an initial second depth 2715 (e.g., depth of compression, depth of layer) from the existing second major surface 1405. The initial first depth 2713 and/or the initial second depth 2715, as a percentage of the initial substrate thickness, can be within one or more of the ranges discussed above for the corresponding range with reference to FIG. 16. While the central portion is initially chemically strengthened at the end of step 1303, the chemical strengthening at the existing first central surface area 1413 will be removed in forming the first recess (as indicated by the dashed lines 2717) in step 1307 (discussed below) since a first distance 2727 of the first recess will be greater than the initial first depth 2713, and the chemical strengthening at the existing second central surface area 1443 will be removed in forming the second recess (as indicated by the dashed lines 2719) in step 1307 (discussed below) since a second distance 2729 of the second recess will be greater than the initial second depth 2715.

After step 1303, as shown in FIG. 28, methods can proceed to step 1305 comprising disposing an etch mask on the foldable substrate. In aspects, the etch mask can resemble and/or comprise any (one or more of the aspects) discussed above for the portions 1703a, 1703b, and/or 1705 discussed above with reference to step 1209, but with space between portions of the etch mask corresponding to a portion of the first central surface area and a portion of the second central surface area. Alternatively, in aspects, as shown in FIG. 28, the etch mask can comprise a first portion 2851 comprising a first barrier layer 2853 disposed on a first polymer layer 2856, and/or the etch mask can comprise a second portion 2861 comprising a second barrier layer 2863 disposed on a second polymer layer 2866. In further aspects, the first polymer layer 2856 can be disposed on the first barrier layer 2853 before the first portion 2851 is disposed on the foldable substrate 1401. Alternatively, in further aspects, the first polymer layer 2856 can be disposed on the foldable substrate 1401 before the first barrier layer 2853 is disposed on the first polymer layer 2856. In further aspects, as shown, the first portion 2851 and/or the second portion 2861 can be disposed on and/or at least partially adhered to (e.g., by an adhesive layer not shown) the existing first major surface 1403, for example with a first contact surface 2855 of the first barrier layer 2853 and/or a second contact surface 2865 of the second barrier layer 2863 disposed on and/or at least partially adhered to the existing first major surface 1403. As used herein, a first layer is partially adhered to a second layer if a portion of the first layer is adhered to the second layer but an entire surface of the first layer is not necessarily adhered to the second layer. In even further aspects, as shown, the first contact surface 2855 of the first barrier layer 2853 can be disposed on and/or attached to a sixth contact surface 2859 of the first polymer layer 2856 and/or the second contact surface 2865 of the second barrier layer 2863 can be disposed on and/or attached to an eighth contact surface 2869 of the second polymer layer 2866. In even further aspects, as shown, a fifth contact surface 2857 of the first polymer layer 2856 can be disposed on (e.g., without being directly bonded to) the existing first major surface 1403 and/or a seventh contact surface 2867 of the second polymer layer 2866 can be disposed on (e.g., without being directly bonded to) the existing first major surface 1403.

In aspects, as shown in FIG. 28, the first polymer layer 2856 can comprise a first width 2847 and/or the second polymer layer 2866 can comprise a second width 2849. In further aspects, the first width 2847 and/or the second width 2849 can be about 100 μm or more, about 150 μm more, about 200 μm or more, about 300 μm or more, about 400 μm or more, about 3 mm or less, about 1 mm or less, about 700 μm or less, or about 500 μm or less. In further aspects, the first width 2847 and/or the second width 2849 can be in a range from about 100 μm to about 3 mm, from about 150 μm to about 1 mm, from about 200 μm to about 700 μm, from about 300 μm to about 500 μm, or any range or subrange therebetween. The resulting first transition width 214 of the first transition region 212 can be greater than the first width 2847 and/or the resulting second transition width 216 of the second transition region 218 can be greater than the second width 2849. Providing the first polymer layer 2856 and/or the second polymer layer 2866 can enable longer widths of transition regions than otherwise achievable.

In aspects, as shown in FIG. 28, the first polymer layer 2856 can be positioned at a first inner peripheral portion 2858 of the first portion 2851 (e.g., flush with the first barrier layer 2853) and/or the second polymer layer 2866 can be positioned at a second inner peripheral portion 2868 of the second portion 2861 (e.g., flush with the second barrier layer 2863). In aspects, as shown in FIG. 28, a minimum distance 2841 can be defined between the first inner peripheral portion 2858 and the second inner peripheral portion 2868. In further aspects, the minimum distance 2841 can be about 1 mm or more, about 2 mm or more, about 5 mm or more, about 10 mm or more, about 50 mm or less, about 40 mm or less, about 30 mm or less, or about 20 mm or less. In further aspects, the minimum distance 2841 can be in a range from about 1 mm to about 50 mm, from about 1 mm to about 40 mm, from about 2 mm to about 40 mm, from about 5 mm to about 30 mm, from about 10 mm to about 20 mm, or any range or subrange therebetween. In further aspects, the minimum distance 2841 can be within one or more of the ranges discussed above for the width 287 of the central portion 281, for example, in terms of absolute distance and/or as a multiple of the minimum parallel plate distance. In further aspects, the minimum distance 2841 can be less than the width 287 of the central portion 281 of the resulting foldable apparatus (see FIGS. 2 and 4). In further aspects, the minimum distance 2841 can be substantially equal to the width 210 of the first central surface area 213 (e.g., central region 248).

In aspects, the first polymer layer 2856 and/or the second polymer layer 2866 can comprise one or more of a polyolefin, a polyamide, a halide-containing polymer (e.g., polyvinylchloride or a fluorine-containing polymer), an elastomer, a urethane, phenolic resin, parylene, polyethylene terephthalate (PET), and polyether ether ketone (PEEK). Example aspects of polyolefins include low molecular weight polyethylene (LDPE), high molecular weight polyethylene (HDPE), ultrahigh molecular weight polyethylene (UHMWPE), and polypropylene (PP). Example aspects of fluorine-containing polymers include polytetrafluoroethylene (PTFE), polyvinylfluoride (PVF), polyvinylidene fluoride (PVDF), perfluoropolyether (PFPE), perfluorosulfonic acid (PFSA), a perfluoroalkoxy (PFA), fluorinated ethylene propylene (FEP) polymers, and ethylene tetrafluoro ethylene (ETFE) polymers. Example aspects of elastomers include rubbers (e.g., polybutadiene, polyisoprene, chloroprene rubber, butyl rubber, nitrile rubber) and block copolymers (e.g., styrene-butadiene, high-impact polystyrene, poly(dichlorophosphazene). An exemplary aspect of a polymer for the first polymer layer 2856 and/or the second polymer layer 2866 is poly(ethylene terephthalate). In aspects, there may not be an adhesive layer of the first polymer layer 2856 and/or the second polymer layer 2866 contacting the existing first major surface 1403 of the foldable substrate 1401.

In aspects, the first barrier layer 2853 and/or the second barrier layer 2863 can comprise a polymeric tape, for example, comprising a polymeric film and an adhesive film. In further aspects, the polymeric film can comprise one or more of the materials discussed above for the first polymer layer 2856. An exemplary aspect of the polymeric film is polyimide. In further aspects, the adhesive film can comprise a pressure-sensitive adhesive. In further aspects, the adhesive film can comprise a silicone-based polymer, an acrylate-based polymer, an epoxy-based polymer, a polyimide-based material, or a polyurethane. In even further aspects, the adhesive film can comprise an ethylene acid copolymer. An exemplary aspect of an ethylene acid copolymer includes SURLYN available from Dow (e.g., Surlyn PC-2000, Surlyn 8940, Surlyn 8150). Examples of epoxies include bisphenol-based epoxy resins, novolac-based epoxies, cycloaliphatic-based epoxies, and glycidylamine-based epoxies. An exemplary aspect of the adhesive film is a silicone-based polymer (e.g., silicone). Consequently, an exemplary aspect of the first barrier layer 2853 and/or the second barrier layer 2863 is a polymeric tape comprising a polymeric film comprising a polyimide and an adhesive film comprises a silicone. The first barrier layer 2853 and the second barrier layer 2863 is resistant to an etchant (e.g., acid) that can be used to etch the foldable substrate. In aspects, although not shown, the barrier layers (e.g., first barrier layer 2853, second barrier layer 2863) can be adhered to the foldable substrate 1401 (e.g., existing first major surface 1403) through an adhesive layer of the corresponding barrier layer. In aspects, although not shown, the barrier layers (e.g., first barrier layer 2853, second barrier layer 2863) can be adhered to the corresponding polymer layer (e.g., first polymer layer 2856, second polymer layer 2866) by an adhesive layer of the corresponding barrier layer and/or an adhesive layer of the corresponding polymer layer, for example, Maxi 689BL-003 (Maxi Adhesive Products, Inc.) or JVCC EGPF-01 (J.V. Converting Company, Inc.).

In aspects, as shown in FIG. 28, the etch mask can further comprise a third portion 2871 comprising a third barrier layer 2873 disposed on a third polymer layer 2876, and/or the etch mask can further comprise a fourth portion 2881 comprising a fourth barrier layer 2883 disposed on a fourth polymer layer 2886. In further aspects, the third polymer layer 2876 can be disposed on the third barrier layer 2873 before the third portion 2871 is disposed on the foldable substrate 1401. Alternatively, in further aspects, the third polymer layer 2876 can be disposed on the foldable substrate 1401 before the third barrier layer 2873 is disposed on the third polymer layer 2876. In further aspects, as shown, the third portion 2871 and/or the fourth portion 2881 can be disposed on and/or at least partially adhered to (e.g., by an adhesive layer not shown) the existing second major surface 1405, for example with a third contact surface 2875 of the third barrier layer 2873 and/or a fourth contact surface 2885 of the fourth barrier layer 2883 disposed on and/or at least partially adhered to the existing second major surface 1405. In even further aspects, as shown, the third contact surface 2875 of the third barrier layer 2873 can be disposed on and/or attached to a tenth contact surface 2879 of the third polymer layer 2876 and/or the fourth contact surface 2885 of the fourth barrier layer 2883 can be disposed on and/or attached to a twelfth contact surface 2889 of the fourth polymer layer 2886. In even further aspects, as shown, a ninth contact surface 2877 of the third polymer layer 2876 can be disposed on (e.g., without being directly bonded to) the existing second major surface 1405 and/or an eleventh contact surface 2887 of the fourth polymer layer 2886 can be disposed on (e.g., without being directly bonded to) the existing second major surface 1405. In aspects, the third polymer layer 2876 can comprise a third width that can be substantially equal to the first width 2847, and/or the fourth polymer layer 2886 can comprise a fourth width that can be substantially equal to the second width 2849. In aspects, as shown in FIG. 28, the third polymer layer 2876 can be positioned at a third inner peripheral portion 2878 of the third portion 2871 (e.g., flush with the third barrier layer 2873) and/or the fourth polymer layer 2886 can be positioned at a fourth inner peripheral portion 2888 of the fourth portion 2881 (e.g., flush with the fourth barrier layer 2883). In aspects, as shown in FIG. 28, a minimum distance between the third inner peripheral portion 2878 and the fourth inner peripheral portion 2888 can be substantially equal to the minimum distance 2841.

In aspects, step 1305 can further comprise deairing the etch mask by placing the foldable substrate in a vacuum. As used herein, vacuum refers to an absolute pressure of 1,000 Pascals or less. Placing the etch masking in the vacuum can dissipate air bubbles between the barrier layers and the foldable substrate and/or increase an adhesion between the barrier layers and the foldable substrate to increase, which can increase a uniformity of the resulting foldable substrate. In further aspects, the etch mask can be deaired in the vacuum for about 1 minute or more, about 2 minutes or more, about 5 minutes or more, about 15 minutes or less, about 12 minutes or less, or about 10 minutes or less. In further aspects, the etch mask can be deaired in the vacuum for from about 1 minute to about 15 minutes, from about 2 minutes to about 12 minutes, from about 5 minutes to about 10 minutes, or any range or subrange therebetween.

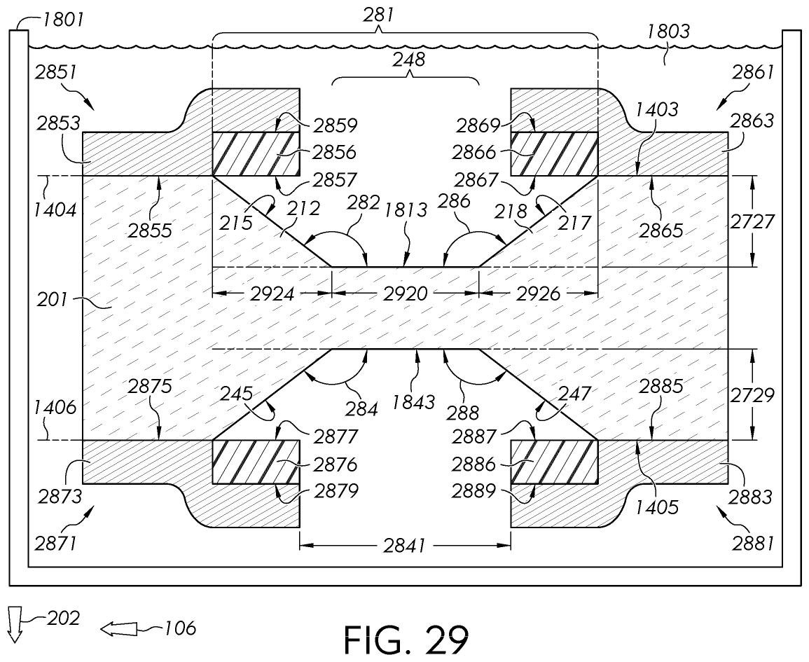

After step 1301 or 1305, as shown in FIG. 29, methods can proceed to step 1307 comprising etching the existing first central surface area 1413 (see FIGS. 27-28) to form a first central surface area 1813, and/or etching the existing second central surface area 1443 (e.g., see FIGS. 27-28) to form a second central surface area 1843. In aspects, as shown, step 1307 can comprise contacting at least the existing first central surface area 1413 and/or the existing second central surface area 1443 with an etchant 1803, for example, by immersing the foldable substrate 201 in a etchant bath 1801 containing the etchant 1803. In further aspects, the etchant 1803 can comprise one or more acids (e.g., HCl, HF, H₂SO₄, HNO₃). In aspects, the etchant 1803 can undercut the first polymer layer 2856, the second polymer layer 2866, the third polymer layer 2876, and/or the fourth polymer layer 2886, for example by the corresponding width of the polymer layer(s). Step 1307 can form the first central surface area 1813 that can be recessed from the existing first major surface 1403 by the first distance 2727. Step 1307 can form the second central surface area 1843 that can be recessed from the existing second major surface 1405 by the second distance 2729. The central region 248 comprising the first central surface area 1813 and the second central surface area 1843 can comprise a width 2920 that can be substantially equal to the width 210. Step 1307 can form the first transition surface area 215 and/or the second transition surface area 245 of the first transition region 212 comprising a width 2924, which can be substantially equal to the first transition width 214. Step 1309 can form the third transition surface area 217 and/or the fourth transition surface area 247 of the second transition region 218 comprising a width 2926 that can be substantially equal to the second transition width 216. In aspects, as shown, an angle between the first transition surface area 215 and the first central surface area 1813 can be substantially equal to the first average angle 282, an angle between the second transition surface area 245 and the second central surface area 1843 can be substantially equal to the second average angle 284, an angle between the third transition surface area 217 and the first central surface area 1813 can be substantially equal to the third average angle 286, and/or an angle between the fourth transition surface area 247 and the second central surface area 1843 can be substantially equal to the fourth average angle 288.

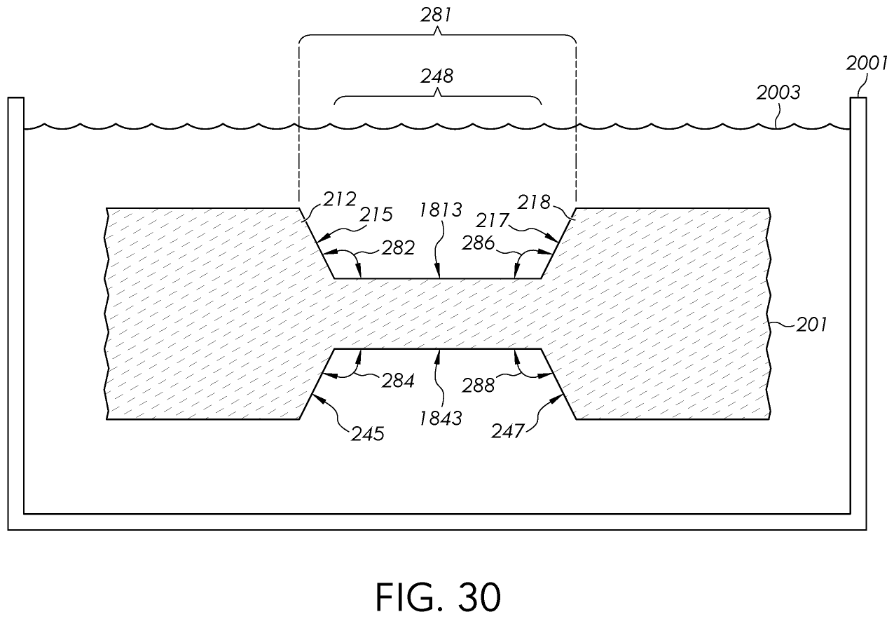

After step 1301 or 1307, as shown in FIG. 30, methods can proceed to step 1309 comprising removing the etch mask. Step 1309 can comprise any (one or more) of the aspects discussed above with reference to step 1213.

After step 1307 or 1309, as shown in FIG. 30, methods can proceed to step 1311 comprising further chemically strengthening the foldable substrate. Step 1311 can comprise any one or more of the aspects discussed above with reference to step 1215.

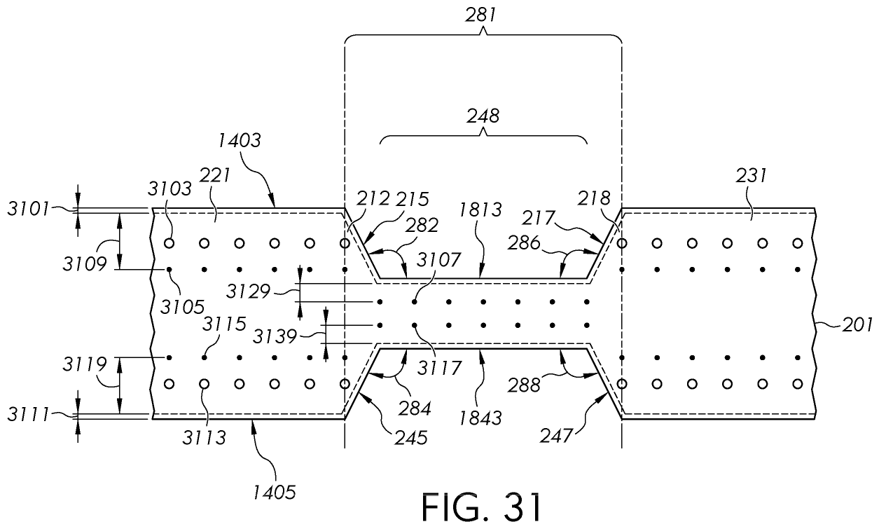

At the end of step 1311, as shown in FIG. 31, the compressive stress region(s) extending from the existing first major surface 1403 can be increased from the initial first depth (as indicated by open circles 3103) to about the first depth 3109 (as indicated by solid dots 3105). At the end of step 1311 or at the end of step 1313 (discussed below), the first compressive stress region in the first portion 221 can extend to the first depth 3109 (e.g., first depth of compression, first depth of layer) and/or the third compressive stress region in the second portion 231 can extend to the first depth 3109 (e.g., third depth of compression, third depth of layer). At the end of step 1311, as shown in FIG. 31, the compressive stress region(s) extending from the existing second major surface 1405 can be increased from the initial second depth (as indicated by open circles 3113) to the second depth 3119 (as indicated by solid dots 3115). At the end of step 1311 or at the end of step 1313 (discussed below), the second compressive stress region in the first portion 221 can extend to the second depth 3119 (e.g., second depth of compression, second depth of layer) and/or the fourth compressive stress region in the second portion 231 can extend to the second depth 3119 (e.g., fourth depth of compression, fourth depth of layer). At the end of step 1311, as shown in FIG. 21, a first central compressive stress region (as indicated by solid dots 3107) in the central portion 281 extending from the first central surface area 1813 can extend to the first central depth 3129 (e.g., first central depth of compression, first central depth of layer), and/or a second central compressive stress region (as indicated by solid dots 3117) in the central portion 281 extending from the second central surface area 1843 can extend to the second central depth 3139 (e.g., second central depth of compression, second central depth of layer). The relationship between these depths of compression and/or depth of layer can correspond to those described above (e.g., an amount that a ratio of the first depth of compression to the substrate thickness is greater than a ratio of the first central depth of compression to the central thickness).

As shown in FIG. 31, a first surface layer 3101 and/or a second surface layer 3111 can be removed in step 1313 (discussed below). In aspects, the first surface layer 3101 can be substantially uniform across the existing first major surface 1403, the first transition surface area 215, the third transition surface area 217, and/or the first central surface area 1813. In aspects, the second surface layer 3111 can be substantially uniform across the existing second major surface 1405, the second transition surface area 245, the fourth transition surface area 247, and/or the second central surface area 1843. In further aspects, the second surface layer 3111 can be substantially equal to the first surface layer 3101. After step 1315, the foldable substrate can correspond to the foldable substrate shown in FIGS. 2-3.

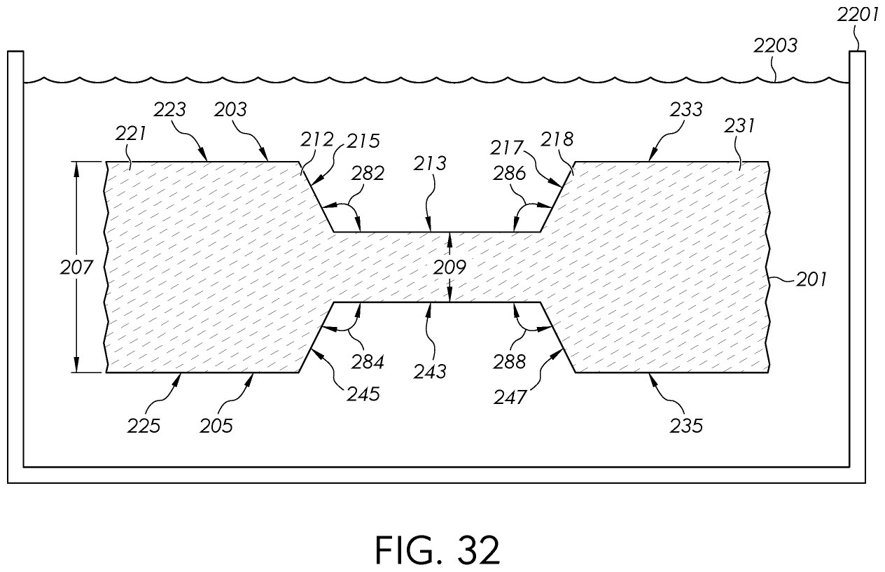

After step 1311, as shown in FIG. 32, methods can proceed to step 1313 comprising etching a uniform thickness substantially uniformly from the foldable substrate 201. In aspects, as shown, step 1313 can comprise contacting the foldable substrate 201 with an etchant 2203. In further aspects, as shown, step 1313 can comprise immersing the foldable substrate 201 in an etchant bath 2201 containing the etchant 2203. In aspects, the etchant 2203 can be the same as the etchant 1803 discussed above with reference to step 1211 and 1307. In aspects, the etchant 2203 can comprise a lower concentration (e.g., molarity) than the etchant 1803. In aspects, the thickness removed substantially uniformly from the foldable substrate 201 in step 1313 can be about 0.1 μm or more, about 0.2 μm or more, about 0.5 μm or more, about 5 μm or less, about 2 μm or less, about 1 μm or less, or about 0.8 μm or less. In aspects, the thickness removed substantially uniformly from the foldable substrate 201 in step 1313 can be in a range from about 0.1 μm to about 5 μm, from about 0.1 μm to about 2 μm, from about 0.2 μm to about 1 μm, from about 0.5 μm to about 0.8 μm, or any range or subrange therebetween. Etching the substrate in step 1313 (after the further chemically strengthening the foldable substrate in step 1311) can remove flaws near or at the surface of the foldable substrate 201, which can increase a strength (e.g., pen drop height) and/or flexibility (e.g., ability to achieve a particular parallel plate distance) of the foldable substrate 201. In aspects, as shown, at the end of step 1217, the etching can produce a foldable substrate with the substrate thickness 207 and the central thickness 209. In aspects, as shown, at the end of step 1313, the etching can form the first surface area 223, the second surface area 225, the third surface area 233, the fourth surface area 235, the first central surface area 213, and/or the second central surface area 243 with the properties discussed above with reference to FIGS. 2-3.

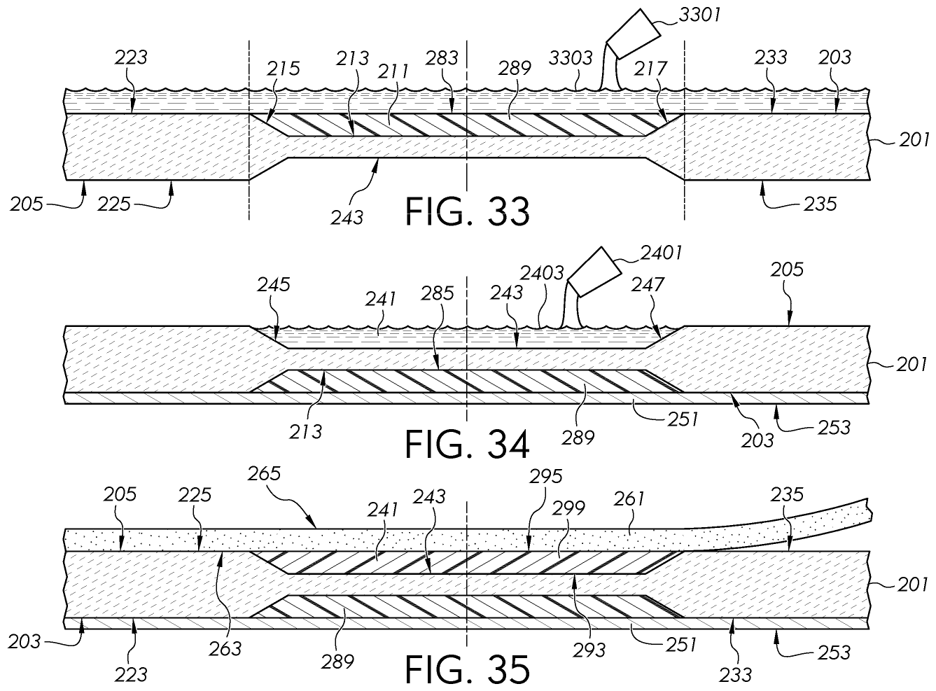

After step 1311 or 1315, as shown in FIGS. 33-35, methods can proceed to step 1315 comprising assembling a foldable apparatus comprising the foldable substrate. In aspects, as shown in FIGS. 33-35, step 1317 can comprise assembling the foldable apparatus by disposing a polymer-based portion (e.g., first polymer-based portion 289, second polymer-based portion 299), an adhesive layer 261, and/or a coating 251 over the foldable substrate 201. In further aspects, as shown in FIG. 33, a first polymer-based portion 289 can be disposed in the first recess 211 and/or over the first central surface area 213. In further aspects, as shown in FIGS. 33-34, a coating 251 can be disposed over the first major surface 203 (e.g., first surface area 223 and third surface area 233), for example, by dispensing a first liquid 3303 from a container 3301 (e.g., conduit, flexible tube, micropipette, or syringe) over the first major surface 203 that can be cured to form the coating 251. In even further aspects, the first liquid 3303 may comprise a coating precursor, a solvent, particles, nanoparticles, and/or fibers. In still further aspects, the coating precursor can comprise, without limitation, one or more of a monomer, an accelerator, a curing agent, an epoxy, and/or an acrylate. Curing the first liquid 3303 can comprise heating the first liquid 3303, irradiating the first liquid 3303 with ultraviolet (UV) radiation, and/or waiting a predetermined amount of time (e.g., from about 30 minutes to 24 hours, from about 1 hour to about 8 hours). In aspects, although not shown, the coating 251 can be disposed in the first recess 211 (e.g., fill the first recess 211) without contacting the first major surface 203 (e.g., first surface area 223, third surface area 233), for example, in place of the first polymer-based portion 289 in FIGS. 33-35. In further aspects, as shown in FIGS. 33-35, a second polymer-based portion 299 can be disposed in the second recess 241, for example, by dispensing a second liquid 2403 from a container 2401 (e.g., conduit, flexible tube, micropipette, or syringe) over the second central surface area 243 that can be cured to form the second polymer-based portion 299. Curing the second liquid 2403 can comprise heating the second liquid 2403, irradiating the second liquid 2403 with ultraviolet (UV) radiation, and/or waiting a predetermined amount of time (e.g., from about 30 minutes to 24 hours, from about 1 hour to about 8 hours). In further aspects, as shown in FIG. 35, an adhesive layer 261 can contact the second major surface 205 (e.g., the second surface area 225 and the fourth surface area 235). For example, the adhesive layer 261 can comprise one or more sheets of an adhesive material. In aspects, there can be an integral interface between the one or more sheets comprising the adhesive layer 261, which can reduce (e.g., avoid) optical diffraction and/or optical discontinuities as light travels between the sheets since the one or more sheets can include substantially the same index of refraction. In aspects, although not shown, at least a portion of the adhesive layer can be disposed in the second recess. In aspects, a release liner (e.g., see release liner 271 in FIG. 2) or a display device may be disposed on the adhesive layer 261 (e.g., second contact surface 265). In aspects, the foldable substrate 201 can be a rollable substrate and/or the foldable substrate 201 can be assembled into a foldable apparatus similar to or identical to the foldable apparatus 3901 shown in FIG. 39, for example, with the display device 3811 instead of the release liner 271 shown in FIG. 2.

After step 1311, 1313, or 1315, methods can proceed to step 1317, where methods of making the foldable substrate and/or the foldable apparatus can be complete. In aspects, methods of making a foldable substrate and/or a foldable apparatus in accordance with aspects of the disclosure can proceed along steps 1301, 1303, 1305, 1307, 1309, 1311, 1313, 1315, and 1317 of the flow chart in FIG. 13 sequentially, as discussed above. In aspects, methods can follow arrow 1302 from step 1301 to step 1305, for example, if the foldable substrate already comprises the initial compressive stress region(s) at the end of step 1301. In aspects, methods can follow arrow 1301 to step 1304, for example, if the foldable substrate already comprises the initial compressive stress region(s) at the end of step 1301 and has the etch mask(s) disposed thereon at the end of step 1301. In aspects, methods can follow arrow 1306 from step 1307 to step 1311, for example if the etch mask is permeable to the ions in the salt solution, will be removed by the salt solution, or was already removed by the end of step 1307. In aspects, methods can follow arrow 1308 from step 1311 to step 1315, for example, if the foldable substrate is not to be uniformly etched before being assembled in a foldable apparatus. In aspects, methods can follow arrow 1310 from step 1311 to step 1317, for example, if methods are complete at the end of step 1311. In aspects, methods can follow arrow 1312 from step 1313 to step 1317, for example, if methods are complete at the end of step 1313. Any of the above options may be combined to make a foldable apparatus in accordance with the embodiments of the disclosure.

### Examples

Various aspects will be further clarified by the following examples. Examples A-G and AA-BB comprise a glass-based substrate (Composition 1 having a nominal composition in mol % of: 63.6 SiO₂; 15.7 Al₂O₃; 10.8 Na₂O; 6.2 Li₂O; 1.16 ZnO; 0.04 SnO₂; and 2.5P₂O₅) with dimensions of 100 mm by 160 mm in a direction perpendicular to the substrate thickness. Examples A-G and AA-BB were processed in accordance with the methods discussed above with reference to the flow chart in FIG. 13 to form a foldable substrate resembling the foldable substrate 201 shown in FIG. 3. Unless otherwise stated, the properties reported in Table 1 are based on at least 5 samples for each Example.

Table 1 presents the treatment conditions and properties of Examples A-G and AA-BB. Monolithic substrates (comprising substantially the substrate thickness stated in Table 1) were initially chemically strengthened for the time stated in Table 1 (IOX #1) in a salt solution comprising 100 wt % KNO₃ maintained at 410° C. Then, the monolithic substrates were masked and etched to form the first recess and the second recess with a distance therebetween substantially equal to the central thickness stated in Table 1. Then, the etch substrates were further chemically strengthened for the time stated in Table 1 (IOX #2) in a salt solution comprising 100 wt % KNO₃ maintained at 410° C. Example B was then etched to remove about 0.5 μm from a thickness of the foldable substrate (i.e., about 0.25 μm from each surface) to form the substrate thickness and central thickness stated in Table 1. Examples A, C-G, and AA-BB were not subjected to etching after the foldable substrate was further chemically strengthened. Examples A-G and AA-BB comprised the first depth of compression (as a ratio to the substrate thickness) (1^{st} DOC) and the first central depth of compression (as a ratio to the central thickness) (1^{st} Central DOC).

Examples A and AA comprised the central width of the central portion stated in Table 1, which was centered in the foldable substrate (at a midpoint of the foldable substrate) (e.g., about 73 mm on each side of the central portion). The substrate thickness and central thickness in Examples A and AA were 102 μm and 32 μm, respectively. Examples A and AA comprised a transition width of 0.3 mm. The first central depth of compression (in μm and as a ratio to the central thickness) was 5.4 μm (0.169) in Examples A and AA. Example A comprised a first depth of compression of 19.3 μm corresponding to a ratio of the first depth of compression to the substrate thickness of 0.189. As such, the ratio of the first depth of compression to the substrate thickness is greater than the first central depth of compression to the central thickness by 0.02. As shown in Table 1, none of the samples for Example A buckled.

In contrast, Example AA comprised a first depth of compression of 17.2 μm corresponding to a ratio of the first depth of compression to the substrate thickness of 0.169. As such, the ratio of the first depth of compression to the substrate thickness is equal to (i.e., not greater than) the first central depth of compression to the central thickness. As shown in Table 1, 20% of the samples for Example AA buckled. Additionally, 20% of the samples for Example AA exhibited waviness. Comparing Example A to Example AA, the ratio of the first depth of compression to the substrate thickness is greater than the first central depth of compression to the central thickness can decrease an incidence of buckling (or other mechanical instabilities). As discussed above, this result is unexpected since the condition of Example A would be expected to exceed the critical buckling strain for the central portion (calculated for samples comprising the material of the substrate with a uniform thickness), which would be expected to lead to the onset of mechanical instabilities (e.g., buckling).

Example B comprised the central width stated in Table 1, which was offset from a midpoint of the foldable substrate by 30 μm (18.7% of the substrate thickness) (e.g., with 73 mm on one side of the central portion and 10 mm on the other side of the central portion). As shown in Table 1, the substrate thickness was 150 μm and the central thickness was 56 μm. Examples A and AA comprised a transition width of 0.3 mm. The first depth of compression was 18 μm, and a ratio of the first depth of compression to the substrate thickness was 0.12. The first central depth of compression was 5.5 μm, and a ratio of the first central depth of compression to the central thickness was 0.10. Like for Example A, in Example B, the ratio of the first depth of compression to the substrate thickness is greater than the first central depth of compression to the central thickness by 0.02. As shown in Table 1, none of the samples for Example B buckled. Examples A and B demonstrate that this principle is applicable to foldable substrates where the central portion is centered at a midpoint of the foldable substrate as well as when the central portion is displaced from the midpoint of the foldable substrate.

Examples C was the same as Example AA except that the second chemical strengthening step was 10 minutes longer for Example C. The first central depth of compression (in μm and as a ratio to the central thickness) was 6.75 μm (0.21) in Example C and a first depth of compression of 17.2 μm corresponding to a ratio of the first depth of compression to the substrate thickness of 0.169. As such, the ratio of the first depth of compression to the substrate thickness is greater than the first central depth of compression to the central thickness by 0.04. As shown in Table 1, none of the samples for Example C buckled.

TABLE 1
Properties of Examples A-G and AA-BB

| | | | Substrate | Central | | 1^{st} | Central | |
|---|---|---|---|---|---|---|---|---|
| | IOX #1 | IOX #2 | thickness | thickness | 1^{st} | Central | Width | % |
| Ex. | (min) | (min) | (μm) | (μm) | DOC | DOC | (mm) | Buckle |
| A | 64 | 4 | 102 | 32 | 19.3 μm | 5.4 μm | 14 | 0 |
| | | | | | (0.189) | (0.169) | | |
| AA | 55 | 4 | 102 | 32 | 17.2 μm | 5.4 μm | 14 | 20 |
| | | | | | (0.169) | (0.169) | | |
| B | 58 | 5 | 150 | 56 | 18 μm | 5.5 μm | 50 | 0 |
| | | | | | (0.12) | (0.10) | | |
| C | 55 | 14 | 102 | 32 | 17.2 μm | 6.75 μm | 14 | 0 |
| | | | | | (0.169) | (0.21) | | |
| BB | 55 | 5 | 102 | 32 | 17.2 μm | 5.4 μm | 20 | 94 |
| | | | | | (0.169) | (0.169) | | |
| D | 64 | 5 | 102 | 32 | 19.3 μm | 5.4 μm | 20 | 73 |
| | | | | | (0.189) | (0.169) | | |
| E | 64 | 4 | 102 | 32 | 19.3 μm | 5.0 μm | 20 | 57 |
| | | | | | (0.189) | (0.156) | | |
| F | 64 | 3 | 102 | 32 | 19.3 μm | 4.0 μm | 20 | 0 |
| | | | | | (0.189) | (0.125) | | |
| G | 64 | 2 | 102 | 32 | 19.3 μm | 3.0 μm | 20 | 0 |
| | | | | | (0.189) | (0.094) | | |

Examples D-G and BB comprised the central width of the central portion stated in Table 1, which was centered in the foldable substrate (at a midpoint of the foldable substrate) (e.g., about 73 mm on each side of the central portion). The substrate thickness and central thickness in Examples D-G and BB were 102 μm and 32 μm, respectively. Examples A and AA comprised a transition width of 1.0 mm.

For Example BB, the first central depth of compression (in μm and as a ratio to the central thickness) was 5.45 μm (0.169) and a first depth of compression of 17.2 μm (0.169). The ratio of the first depth of compression to the substrate thickness was designed to be equal to the first central depth of compression to the central thickness. As shown in Table 1, 94% of the samples buckled for Example BB. Compared to Example AA, the increased central width (and associated increase in transition width) makes Example CC more susceptible to buckling (when the difference in the ratio of the DOC to the corresponding thickness is 0). The greater central width increases how much of the foldable substrate has a lower critical buckling strain (associated with the central thickness).

Example D comprised the same dimensions as Example BB, but the first depth of compression is increased to 19.3 μm (0.189) from 17.2 μm (0.169). As such, the ratio of the first depth of compression to the substrate thickness was designed to be greater than the first central depth of compression to the central thickness by 0.02 in Example D (instead of 0 in Example BB). As shown in Table 1, 73% of the samples buckled for Example D. Compared to Example BB, the increased ratio of the ratio of the first depth of compression to the substrate thickness relative to the ratio of the first central depth of compression to the central thickness in Example D decreases the fraction of samples that buckled. Compared to Example B, the increased central thickness of Example B increased the critical buckling strain that samples can withstand without buckling, which (in addition to the smaller central width) explains the lower fraction of samples that buckled for Example B compared to Example D.

Example E comprised the same dimensions as Example D, but the first central depth of compression is decreased to 5.0 μm (0.156) from 5.4 μm (0.169). As such, the ratio of the first depth of compression to the substrate thickness was designed to be greater than the first central depth of compression to the central thickness by 0.033 in Example E (instead of 0.02 in Example D). As shown in Table 1, 57% of the samples buckled for Example E. Compared to Example D, the increased ratio of the ratio of the first depth of compression to the substrate thickness relative to the ratio of the first central depth of compression to the central thickness in Example E decreases the fraction of samples that buckled. This continues the trend noted above from Example BB to Example D.

Example F comprised the same dimensions as Examples D-E, but the first central depth of compression is decreased to 4.0 μm (0.125) (from 5.4 μm (0.169) in Example D and 5.0 μm (0.156) in Example E). As such, the ratio of the first depth of compression to the substrate thickness was designed to be greater than the first central depth of compression to the central thickness by 0.064 in Example F (instead of 0.02 in Example D and 0.033 in Example E). As shown in Table 1, 0% of the samples buckled for Example F. Compared to Examples D-E, the increased ratio of the ratio of the first depth of compression to the substrate thickness relative to the ratio of the first central depth of compression to the central thickness in Example E decreases the fraction of samples that buckled (to 0%).

Example G comprised the same dimensions as Examples D-F, but the first central depth of compression is decreased to 3.0 μm (0.094) (from 5.4 μm (0.169) in Example D, 5.0 μm (0.156) in Example E, and 4.0 μm (0.125) in Example F). As such, the ratio of the first depth of compression to the substrate thickness was designed to be greater than the first central depth of compression to the central thickness by 0.095 in Example G (instead of 0.02 in Example D, 0.033 in Example E, and 0.064 in Example F). As shown in Table 1, 0% of the samples buckled for Example G.

Table 2 presents the distribution of the difference between the ratio of the first central DOC to the central thickness and the ratio of the first DOC to the substrate thickness for Examples A, C-G, and BB. As shown, a majority of the samples for Example A had a difference in DOC ratios from 0.02 to 0.03, which is in line with the average value of Example A of about 0.02. From 10% to 20% of the samples in Example A had a difference in DOC ratios from 0.01 to 0.02 as well as from 0.03 to 0.04. A smaller fraction of the samples for Example A had a difference in DOC ratios from 0 to 0.01. Example C had about 30% of samples with a difference in DOC ratios from 0.03 to 0.04 as well as from 0.04 to 0.05, which is in line with the average difference in DOC ratios for Example C of about 0.04. The distribution for Example C is skewed to the right (higher values) while the distribution for Example A is relatively symmetric. Given the natural variation of the difference in DOC ratios corresponding to the distributions shown in Table 2, providing a difference in DOC ratios from 0.01 to 0.20 (e.g., from 0.02 to 0.12) can reduce an incidence of buckling.

TABLE 2
Distribution of Examples A, C-G, and BB

| Central DOC/central thickness - | Ex. A | Ex. C | Ex. BB | Ex. D | Ex. E | Ex. F | Ex. G |
|---|---|---|---|---|---|---|---|
| 1^{st} DOC/substrate thickness | (%) | (%) | (%) | (%) | (%) | (%) | (%) |
| 0 to 0.01 | 6 | 0 | 53 | 33 | 0 | 0 | 0 |
| 0.01 to 0.02 | 12.5 | 0 | 35 | 20 | 22 | 0 | 0 |
| 0.02 to 0.03 | 62.5 | 6 | 12 | 40 | 50 | 0 | 0 |
| 0.03 to 0.04 | 19 | 29.5 | 0 | 0 | 14 | 0 | 0 |
| 0.04 to 0.05 | 0 | 29.5 | 0 | 7 | 14 | 29 | 0 |
| 0.05 to 0.08 | 0 | 35 | 0 | 0 | 0 | 71 | 100 |

The majority of the samples for Example BB comprised a difference in DOC ratios less than 0.01. The distribution of difference in DOC ratios for Example D was spread from 0 to 0.03. A majority of the samples for Example E comprised a difference in DOC ratios from 0.02 to 0.03. In Examples F-G, the majority of samples comprised a difference in DOC ratio greater than 0.05, and (as noted above for Table 1) Examples F-G did not have any samples buckle.

Examples BB and D-G comprised a larger central width (20 mm) than Examples A and C (14 mm). As discussed above with reference to Table 1, the larger central width is associated with higher rates of buckling at comparable differences in DOC ratios (e.g., compare Example AA to Example BB, or compare Example A to D). Indeed, samples of Example A with a difference in DOC ratios from 0.01 to 0.02 (along with higher differences in DOC ratios) did not buckle. In contrast, all of the samples of Examples D-E with a difference in DOC ratios from 0.01 to 0.02 buckled. For Example E, some (not all) of the samples with a DOC ratios from 0.02 to 0.03 buckled while other samples in the same DOC ratios did not. For Examples D-G, all of the samples with a DOC ratios greater than 0.03 (e.g., from 0.03 to 0.04, from 0.04 to 0.05, and from 0.05 to 0.08) did not buckle.

The above observations can be combined to provide foldable substrate comprising a low minimum parallel plate distance, high impact resistance, increased durability, reduced fatigue, and reduced incidence of mechanical instabilities. The substrate and/or the portions can comprise glass-based and/or ceramic-based portions, which can provide good dimensional stability, reduced incidence of mechanical instabilities, good impact resistance, and/or good puncture resistance. The portions can comprise glass-based and/or ceramic-based portions comprising one or more compressive stress regions, which can further provide increased impact resistance and/or increased puncture resistance. By providing a substrate comprising a glass-based and/or ceramic-based substrate, the substrate can also provide increased impact resistance and/or puncture resistance while simultaneously facilitating good folding performance. In aspects, the substrate thickness can be sufficiently large (e.g., from about 50 micrometers (microns or μm) to about 2 millimeters) to further enhance impact resistance and puncture resistance. Providing foldable substrates comprising a central portion comprising a central thickness that is less than a substrate thickness (e.g., first thickness of the first portion and/or second thickness of the second portion) (e.g., by about 10 μm or more) can enable a small parallel plate distance (e.g., about 10 millimeters or less) based on the reduced thickness in the central portion, which can enable the foldability and/or rollability of the foldable substrate and/or foldable apparatus.

In aspects, the foldable apparatus and/or foldable substrates can comprise one or more recesses, for example, a first central surface area recessed from a first major surface by a first distance and/or a second central surface area recessed from a second major surface by a second distance. Providing a first recess opposite a second recess can provide the central thickness that is less than a substrate thickness. Further, providing a first recess opposite a second recess can reduce a maximum bend-induced strain of the foldable apparatus, for example, between a central portion and a first portion and/or second portion since the central portion comprising the central thickness can be closer to a neutral axis of the foldable apparatus and/or foldable substrates than if only a single recess was provided. Additionally, providing the first distance substantially equal to the second distance can reduce the incidence of mechanical instabilities in the central portion, for example, because the foldable substrate is symmetric about a plane comprising a midpoint in the substrate thickness and the central thickness. Moreover, providing a first recess opposite a second recess can reduce a bend-induced strain of a material positioned in the first recess and/or second recess compared to a single recess with a surface recessed by the sum of the first distance and the second distance. Providing a reduced bend-induced strain of a material positioned in the first recess and/or the second recess can enable the use of a wider range of materials because of the reduced strain requirements for the material. For example, stiffer and/or more rigid materials can be positioned in the first recess, which can improve impact resistance, puncture resistance, abrasion resistance, and/or scratch resistance of the foldable apparatus. Additionally, controlling properties of a first material positioned in a first recess and a second material positioned in a second recess can control the position of a neutral axis of the foldable apparatus and/or foldable substrates, which can reduce (e.g., mitigate, eliminate) the incidence of mechanical instabilities, apparatus fatigue, and/or apparatus failure.

In aspects, the foldable apparatus and/or foldable substrates can comprise a first transition region attaching the central portion to the first portion and/or a second transition region attaching the central portion to the second portion. Providing transition regions with smoothly and/or monotonically decreasing (e.g., continuously decreasing) thicknesses can reduce stress concentration in the transition regions and/or avoid optical distortions. Providing a sufficient length of the transition region(s) (e.g., about 0.15 mm or more or about 0.3 mm or more) can avoid optical distortions that may otherwise exist from a sharp change in thickness of the foldable substrate. Providing an average transition angle of a first transition surface area of the first transition region relative to the first central surface area that is sufficiently large (e.g., about 167° or more or about 170° or more) can avoid optical distortions and/or reduce visibility of the transition region. Providing a sufficiently small average transition angle (e.g., about 179° or less or about 176° or less) can reduce the amount of the foldable apparatus and/or the foldable substrates having an intermediate thickness that may have reduced impact resistance and/or reduced puncture resistance.

As discussed above, it was unexpectedly discovered that providing a ratio of the first depth of compression to the substrate thickness greater than a ratio of the first central depth of compression to the central thickness (even when differing by more than 0.01) can reduce an incidence of buckling whereas the same is not true for the opposite relationship (i.e., the relationship in which the ratio of the first central depth of compression to the central thickness is larger than the ratio of the first depth of compression to the substrate thickness). Unexpectedly, as described below, it has been determined that providing a ratio of the first depth of layer to the substrate thickness greater than a ratio of the first central depth of layer to the central thickness (even when differing by more than 0.001) can reduce an incidence of buckling whereas the same is not true for the opposite relationship (i.e., the relationship in which the ratio of the first central depth of layer to the central thickness is larger than the ratio of the first depth of layer to the substrate thickness). These configurations can exert a stabilizing force on the central portion that suppresses fluctuations in a surface profile that could otherwise lead to the onset of mechanical instabilities (e.g., buckling), which can enable the central portion to withstand a critical buckling strain, where the critical buckling strain is calculated for samples comprising the material of the substrate with a uniform thickness. This is unexpected since, by definition, exceeding the critical buckling strain would be expected to lead to the onset of mechanical instabilities (e.g., buckling). Further, providing the configurations can increase a manufacturing yield since a larger portion of the foldable substrates will be free of mechanical instabilities (e.g., buckling) (e.g., compared to where a ratio of the first depth of compression or the first depth of layer to the substrate thickness is less than or equal to a ratio of the first central depth of compression or the first central depth of layer to the central thickness).

The foldable substrate can function as a rollable substrate with a central width greater than a second width. Providing a second width of the second portion of about 15 mm or less (e.g., from about 2 mm to about 6 mm) and/or about 15% or less (e.g., from about 2% to about 6%) of the length of the foldable substrate can provide sufficient width to handling the ends of the foldable substrate during processing, to secure the foldable substrate and/or foldable apparatus as part of an electronic device, and/or to maximize an amount of the foldable substrate and/or foldable apparatus that can be part of a display portion visible to the user. Providing a central portion from about 15% to about 50% (e.g., from about 40% to about 48%) of the length of the foldable substrate can enable a display portion of the foldable apparatus to be adjust as a portion of the rollable substrate is moved into and/or out of view of a user without unnecessarily expanding a size of the corresponding apparatus when in a fully rolled configuration. Providing a first width of the first portion of about 35% or more (e.g., from about 40% to about 70%) of the length of the foldable substrate can provide a large display portion visible to the user while ensuring that substantially all of the rest of the foldable substrate (e.g., central portion and second portion) can be within a footprint of the first portion.

Methods of the aspects of the disclosure can make foldable substrates and/or foldable apparatus comprising a central thickness less than a substrate thickness (e.g., by about 10 μm or more) using an etch mask and an etchant. In aspects, using a barrier layer when initially chemically strengthening the foldable substrate before etching the foldable substrate to form the first recess can enable a ratio of the first depth of compression or the first depth of layer to the substrate thickness greater than a ratio of the first central depth of compression or the first depth of layer to the central thickness. In aspects, initially chemically strengthening the foldable substrate before etching the foldable substrate to form the first recess and the second recess can enable a ratio of the first depth of compression or the first depth of layer to the substrate thickness greater than a ratio of the first central depth of compression or the first depth of layer to the central thickness. In aspects, the design of an etch mask can tune a first transition width and/or a second transition width. Placing the etch masking in the vacuum can dissipate air bubbles between the barrier layers and the foldable substrate and/or increase an adhesion between the barrier layers and the foldable substrate to increase, which can increase a uniformity of the resulting foldable substrate.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

1. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein the foldable substrate comprises a glass-based material or a ceramic based material, the first central surface area is recessed from the first major surface by a first distance, and a ratio of the first depth of compression to the substrate thickness is greater than a ratio of the first central depth of compression to the central thickness.

2. The foldable substrate of claim 1, the ratio of the first depth of compression to the substrate thickness is greater than the ratio of the first central depth of compression to the central thickness by from about 0.01 to about 0.2.

3. The foldable substrate of claim 1, wherein the ratio of the first depth of compression to the substrate thickness is greater than the ratio of the first central depth of compression to the central thickness by from about 0.015 to about 0.15.

4. The foldable substrate of claim 1, wherein the ratio of the first depth of compression to the substrate thickness is greater than the ratio of the first central depth of compression to the central thickness by from about 0.02 to about 0.12.

5. The foldable substrate of claim 1, wherein:
the first portion further comprises: a first depth of layer of one or more alkali metal ions associated with the first depth of compression, and a second depth of layer of one or more alkali metal ions associated with the second depth of compression;
the second portion further comprises: a third depth of layer of one or more alkali metal ions associated with the third depth of compression, and a fourth depth of layer of one or more alkali metal ions associated with the fourth depth of compression,
the central portion further comprises: a first central depth of layer of one or more alkali metal ions associated with the first central depth of compression, a second central depth of layer of the one or more alkali metal ions associated with the second central depth of compression, and
a ratio of the first depth of layer to the substrate thickness is greater than a ratio of the first central depth of layer to the central thickness.

6. The foldable substrate of claim 1, wherein a width of the second portion is about 15 millimeters or less, a width of the first portion is greater than a width of the central portion, a width of the central portion is greater than the width of the second portion, and a sum of the width of the first portion, the width of the central portion, and the width of the second portion corresponds to a dimension of the foldable substrate.

7. The foldable substrate of claim 6, wherein the width of the second portion is from about 2 millimeters to about 6 millimeters.

8. A foldable substrate comprising:
a substrate thickness defined between a first major surface and a second major surface opposite the first major surface;
a first portion comprising the substrate thickness, a first compressive stress region extending to a first depth of compression from the first major surface, a second compressive stress region extending to a second depth of compression from the second major surface;
a second portion comprising the substrate thickness, a third compressive stress region extending to a third depth of compression from the first major surface, a fourth compressive stress region extending to a fourth depth of compression from the second major surface; and
a central portion positioned between the first portion and the second portion, the central portion comprising a central thickness defined between a first central surface area and a second central surface area opposite the first central surface area, a first central compressive stress region extending to a first central depth of compression from the first central surface area, a second central compressive stress region extending to a second central depth of compression from the second central surface area, and the central thickness is less than the substrate thickness,
wherein the foldable substrate comprises a glass-based material or a ceramic based material, the first central surface area is recessed from the first major surface by a first distance, and a width of the first portion, a width of the central portion, and a width of the second portion are measured in a direction corresponding to a dimension of the foldable substrate, the width of the second portion as a percentage of the dimension of the foldable substrate is less than 15%, and the width of the first portion as a percentage of the dimension of the foldable substrate is about 35% or more.

9. The foldable substrate of claim 1, wherein a width of the first portion, a width of the central portion, and a width of the second portion are measured in a direction corresponding to a dimension of the foldable substrate, the width of the second portion as a percentage of the dimension of the foldable substrate is less than 15%, and the width of the first portion as a percentage of the dimension of the foldable substrate is about 35% or more.

10. The foldable substrate of claim 9, wherein the width of the second portion as a percentage of the dimension of the foldable substrate is from about 2% to about 6%.

11. The foldable substrate of claim 10, wherein the width of the first portion as a percentage of the foldable substrate is from about 40% to about 70%.

12. The foldable substrate of claim 11, wherein the width of the central portion as a percentage of the foldable substrate is from about 15% to about 50%.

13. The foldable substrate of claim 1, wherein the second central surface area is recessed from the second major surface by a second distance.

14. The foldable substrate of claim 1, wherein the second major surface comprises the second central surface area.

15. The foldable substrate of claim 1, wherein the first distance is about 20% to about 45% of the substrate thickness.

16. The foldable substrate of claim 1, wherein the first compressive stress region comprises a first maximum compressive stress of about 400 MegaPascals or more, the second compressive stress region comprises a second maximum compressive stress, the third compressive stress region comprises a third maximum compressive stress of about 400 MegaPascals or more, the fourth compressive stress region comprises a fourth maximum compressive stress, the first central compressive stress region comprises a first central maximum compressive stress of about 400 MegaPascals or more, and the second central compressive stress region comprises a second central maximum compressive stress.

17. The foldable substrate of claim 1, wherein the substrate thickness is in a range from about 50 micrometers to about 2 millimeters.

18. The foldable substrate of claim 1, wherein the central thickness in a range from about 25 micrometers to about 120 micrometers.

19. The foldable substrate of claim 1, wherein the foldable substrate achieves a parallel plate distance from 1 millimeter to 10 millimeters.

20. The foldable substrate of claim 1, wherein the foldable substrate achieves a parallel plate distance of 5 millimeters.
